(19) United States
(12) Patent Application Publication
(10) Pub. No.: US 2026/0096283 A1
(43) Pub. Date: Apr. 2, 2026

(54) ACTIVE-MATRIX ORGANIC ELECTROLUMINESCENT DISPLAY

(71) Applicant: BEIJING SUMMER SPROUT TECHNOLOGY CO., LTD., Beijing (CN)

(72) Inventors: Zhihao Cui, Beijing (CN); Renjie Zheng, Beijing (CN); Xingxing Chai, Beijing (CN); Lei Zhao, Beijing (CN); Wantian XU, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 19/340,012

(22) Filed: Sep. 25, 2025

(30) Foreign Application Priority Data
Sep. 27, 2024 (CN) 202411363119.5
Sep. 2, 2025 (CN) 202511242864.9

(51) Int. Cl. H10K 50/15; H10K 50/17; H10K 59/12; H10K 85/30; H10K 85/40; H10K 85/60; H10K 101/30; H10K 102/00

(52) U.S. Cl. CPC H10K 50/15; H10K 50/17; H10K 59/12; H10K 85/342; H10K 85/40; H10K 85/626; H10K 85/633; H10K 85/636; H10K 85/654; H10K 85/656; H10K 85/6572; H10K 85/6574; H10K 85/6576; H10K 85/658; H10K 2101/30; H10K 2102/351

(57) ABSTRACT

Provided is an active-matrix organic electroluminescent display comprising a plurality of pixels; wherein each pixel at least comprises one organic electroluminescent device; at least two pixels share a common first organic layer which at least comprises a first organic material and a second organic material that satisfy a specific energy level relationship; the common first organic layer has a specifically high doping proportion and a specifically low lateral conductivity per unit doping. By optimizing the energy level difference, doping proportion, and lateral conductivity per unit doping of the materials in the common first organic layer, the device is enabled to maintain comprehensive advantages of low voltage and high efficiency. Furthermore, due to the low lateral conductivity per unit doping of the common first organic layer, the lateral migration of holes within the common first organic layer remains at a low level, thereby significantly suppressing lateral crosstalk between pixels in the display.

### CROSS-REFERENCE TO RELATED APPLICATION(S)

This application claims priority to Chinese Patent Application No. 202411363119.5 filed on Sep. 27, 2024, and Chinese Patent Application No. 202511242864.9 filed on Sep. 2, 2025, the disclosure of which are incorporated herein by reference in its entireties.

### TECHNICAL FIELD

The present disclosure relates to an active-matrix organic electroluminescent display and specifically, to an active-matrix organic electroluminescent display comprising a specific device structure.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well-defined structure. Dendrimers with well-defined structures are considered as small molecules. Polymer OLEDs include conjugated polymers and non-conjugated polymers with pendant emitting groups. Small molecule OLED can become the polymer OLED if post-polymerization occurs during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

In an active-matrix organic electroluminescent display, different pixels typically share one or more common layers, such as a common hole injection layer or a common hole transport layer. Crosstalk between pixels is primarily caused by the use of a p-type conductive dopant in the common hole injection layer. Theoretically, increasing the doping ratio of the p-type conductive dopant is more conducive to enhancing device performance. However, an excessively high doping ratio of the p-type conductive dopant leads to the presence of a large number of holes in the common hole injection layer. Once a significant number of holes migrate laterally from one pixel to adjacent pixels through the common hole injection layer, pixel or color crosstalk occurs. As a result, when a specific pixel is displayed, one or more surrounding pixels may unintentionally be illuminated, thereby leading to undesirable crosstalk that adversely affects the display performance of the display. Therefore, how to suppress or even eliminate lateral crosstalk between pixels while ensuring that each pixel maintains excellent performance, such as low voltage and high efficiency, has been a significant and ongoing focus of research and development in the industry.

### SUMMARY

The present disclosure aims to disclose an active-matrix organic electroluminescent display to solve at least part of the above problems. The display comprises a plurality of pixels. Each pixel comprises at least one organic electroluminescent device. At least two pixels share a common first organic layer. The common first organic layer comprises at least a first organic material and a second organic material that satisfy a specific energy level relationship. The common first organic layer has a specifically high doping ratio and a specifically low lateral conductivity per unit doping. In the present disclosure, by optimizing the energy level difference, the doping ratio, and the lateral conductivity per unit doping of the materials in the common first organic layer, the device is enabled to maintain comprehensive advantages of low voltage and high efficiency. Furthermore, due to the low lateral conductivity per unit doping of the common first organic layer, the lateral migration of holes within the common first organic layer remains at a low level, thereby significantly suppressing lateral crosstalk between pixels in the display and providing distinct advantages for commercial applications.

According to an embodiment of the present disclosure, an active-matrix organic electroluminescent display is disclosed, which comprises a plurality of pixels;
wherein each pixel among the plurality of pixels comprises at least one organic electroluminescent device;
the organic electroluminescent device comprises an anode, a cathode, and an organic layer disposed between the anode and the cathode;
the organic layer comprises at least a common first organic layer, and the common first organic layer is shared by at least two pixels;
the common first organic layer comprises at least a first organic material and a second organic material;
the lowest unoccupied molecular orbital (LUMO) energy level of the first organic material is denoted as LUMO_{first_organic_material}, the highest occupied molecular orbital (HOMO) energy level of the second organic material is denoted as HOMO_{second_organic_material}, and −0.1 eV<LUMO_{first_organic_material}−HOMO_{second_organic_material}<0.25 eV;
the mass doping ratio of the first organic material in the common first organic layer is A %, and 5≤A≤15;
the lateral conductivity of the common first organic layer is B_{A}, the lateral conductivity per unit doping of the common first organic layer is σ_{A}, wherein σ_{A}=B_{A}/A, and at least one σ_{A} satisfies 0.05×10⁻⁴ S/m≤σ_{A}≤1×10⁻⁴ S/m.

According to an embodiment of the present disclosure, an electronic device is further disclosed, which comprises the active-matrix organic electroluminescent display described in the preceding embodiment.

The present disclosure discloses an active-matrix organic electroluminescent display comprising a specific device structure. Since the common first organic layer of the active-matrix organic electroluminescent display comprises a first organic material and a second organic material that have a specific energy level difference and specifically high doping ratios, the display can be improved in terms of voltage and efficiency and maintain excellent comprehensive performance. Furthermore, due to a low lateral conductivity per unit doping of the common first organic layer, the lateral migration of holes within the organic layer remains at a low level, thereby significantly suppressing lateral crosstalk between pixels in the display and providing distinct advantages for commercial applications.

### BRIEF DESCRIPTION OF DRAWINGS

FIG. 1 is a structural diagram of an organic light-emitting device 100.

FIG. 2 is a structural diagram of another organic light-emitting device 200.

FIG. 3 is a structural diagram of an active-matrix organic electroluminescent display according to the present disclosure.

FIG. 4 is a schematic diagram of the device structure of a crosstalk test device.

### DETAILED DESCRIPTION

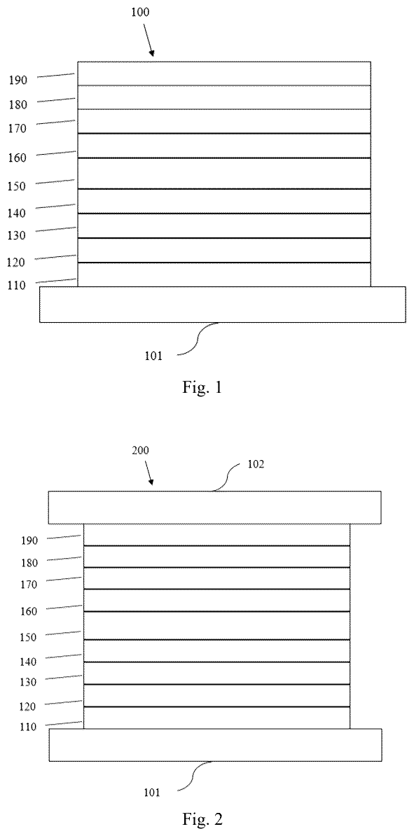

OLEDs can be fabricated on various types of substrates such as glass, plastic, and metal foil. FIG. 1 schematically shows an organic light-emitting device 100 without limitation. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. The figures are not necessarily drawn to scale. Some of the layers in the figures can also be omitted as needed. For example, the hole blocking layer 160 can be omitted as needed. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. “Barrier layer” may be a thin film encapsulation with a thickness of less than 100 micrometers, which includes one or more thin films disposed directly on the device or may be a cover glass adhered to the substrate. Any material that can provide the barrier function can be used as the barrier layer such as glass or organic-inorganic hybrid layers. The barrier layer should be placed directly or indirectly outside of the OLED device. Multilayer thin-film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

As used herein, “independently driven” means two or more OLED devices being separately controlled using active-matrix driving technology. Each pixel is controlled by an independent thin-film transistor (TFT), and the active-matrix organic electroluminescent display can individually control the illumination of each pixel to allow pixels to emit light independently, thereby forming a desired image.

As used herein, all “HOMO energy levels” and “LUMO energy levels” are expressed as negative values. The smaller the numerical value (i.e., the larger its absolute value) is, the deeper the energy level is. Herein, the expression that the energy level is greater than a certain number means that the numerical value of the energy level is larger than that number, i.e., the absolute value of the energy level is smaller. For example, the expression that −5.30 eV≤LUMO_{first_organic_material}≤−4.80 eV means that the LUMO energy level of the first organic material is numerically equal to −5.30 eV or greater than −5.30 eV and numerically equal to −4.80 eV or more negative than −4.80 eV. For example, the LUMO energy level of the first organic material is −5.01 eV. Herein, the expression that the energy level is less than a certain number means that the numerical value of the energy level is less than that number, that is, the energy level has a more negative numerical value.

As used herein, the energy level difference between the LUMO energy level of the first organic material and the HOMO energy level of the second organic material is defined as LUMO_{first_organic_material}−HOMO_{second_organic_material}.

As used herein, the term “mass doping ratio of the first organic material in the common first organic layer” refers to the percentage of the mass of the first organic material in the common first organic layer relative to the total mass of the common first organic layer. For example, if the mass of the first organic material included in the common first organic layer is 10 mg and the total mass of the common first organic layer is 100 mg, the mass doping ratio of the first organic material in the common first organic layer is 10%.

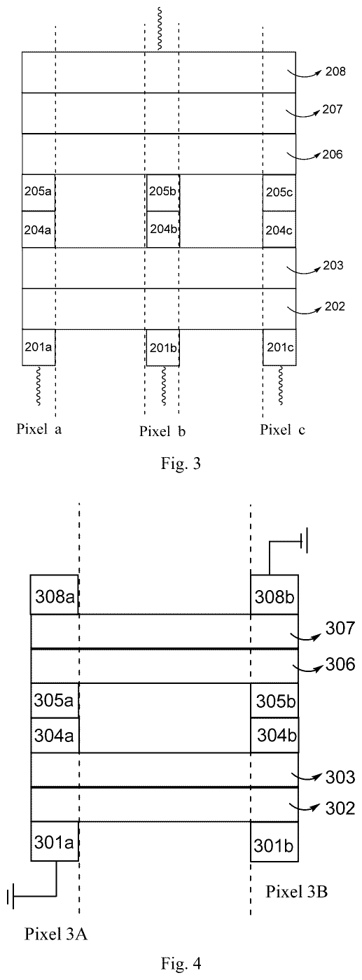

As used herein, the term “common first organic layer” refers to the common first organic layer being shared by at least two pixels in the active-matrix organic electroluminescent display, such as the hole injection layer 202 shown in FIG. 3.

As used herein, the term “lateral conductivity per unit doping of the common first organic layer” means that when the mass doping ratio of the first organic material in the common first organic layer is A % and the lateral conductivity of the common first organic layer is B_{A}, the lateral conductivity per unit doping σ_{A} of the common first organic layer is σ_{A}=B_{A}/A. For example, when the mass doping ratio of the first organic material in the common first organic layer is 6% and the lateral conductivity of the common first organic layer is B₆, then the lateral conductivity per unit doping 0% of the common first organic layer is σ₆=B₆/6.

As used herein, the term “single-layer device” refers to a device having one light-emitting layer (or multiple consecutive light-emitting layers) and a corresponding set of hole transport layer and electron transport layer sandwiched between a pair of anode and cathode. That is, such a device having a single light-emitting layer (or multiple consecutive light-emitting layers) and matched transport layers thereof is the “single-layer device”.

As used herein, the term “p-type conductive doping material” refers to a dopant having an oxidation ability, characterized by a strong electron-withdrawing capability and functioning as an electron acceptor.

The materials herein are “the same” or “different”. The materials being “the same as” means that two or more materials have the same chemical structural formula or differ only in that hydrogens in the chemical structural formula are partially or fully substituted with deuterium. Conversely, the materials being “different” means that the organic materials used have different chemical structural formulas (i.e., the differences in chemical structural formulas extend beyond merely partial or full substitution of hydrogens with deuterium in the molecular formula).

FIG. 3 schematically and non-restrictively illustrates the structural diagram of the active-matrix organic electroluminescent display according to the present disclosure. As differentiated by the dashed lines in FIG. 3, the display includes a pixel a, a pixel b, and a pixel c. 201a, 201b, and 201c are the anodes of the pixel a, the pixel b, and the pixel c, respectively. 202 is a hole injection layer. In the present disclosure, the hole injection layer 202 is a common layer, that is, the layer is continuous across multiple pixels without segmentation. For example, the pixel a, the pixel b, and the pixel c share the hole injection layer 202. 203 is a hole transport layer. 204a, 204b, and 204c are the emissive auxiliary layers (prime layers, also known as electron blocking layers) of the pixel a, the pixel b, and the pixel c, respectively. In the display of the present disclosure, the common first organic layer shared by multiple pixels may be the hole injection layer 202 or the hole transport layer 203. When the common first organic layer is the hole transport layer 203, the hole transport layer 203 is a p-doped organic layer (p-doped HTL). Optionally, a second hole transport layer (not shown in the figure) may be further included between the hole transport layer 203 and the prime layer 204a, between the hole transport layer 203 and the prime layer 204b, and between the hole transport layer 203 and the prime layer 204c, respectively. 205a, 205b, and 205c are the light-emitting layers of the pixel a, the pixel b, and the pixel c, respectively. 206 is a hole blocking layer. 207 is an electron injection layer. 208 is a cathode. The hole blocking layer 206, the electron injection layer 207, and the cathode 208 may be shared or independent of each other. A driving device applies independent driving currents through the anodes 201a, 201b, and 201c, respectively, causing each pixel to operate independently. For example, when a current is applied to the pixel a while no current is applied to the pixels b and c, only the pixel a is lit up. However, since the hole injection layer is a common layer, if the lateral conductivity per unit doping of the hole injection layer 202 is too high, the current may flow from the pixel a through the hole injection layer 202 to the pixel b, causing the pixel b to emit light and resulting in color crosstalk between pixels.

In the present disclosure, multiple pixels share the common first organic layer. Since the common first organic layer is uniform and continuous, the mass doping ratio of the first organic material in the common first organic layer is the same as the mass doping ratio of the first organic material in the first organic layer of a single OLED device, and the lateral conductivity per unit doping of the common first organic layer is also the same as the lateral conductivity per unit doping of the first organic layer in the single OLED device.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e., P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AEs-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small AEs-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

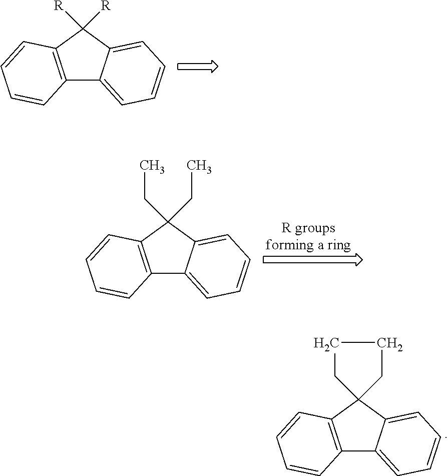

The expression that adjacent substituents can be optionally joined to form a ring is also intended to mean that two substituents bonded to carbon atoms which are directly bonded to each other are joined to each other via a chemical bond to form a ring, which can be exemplified by the following formula:

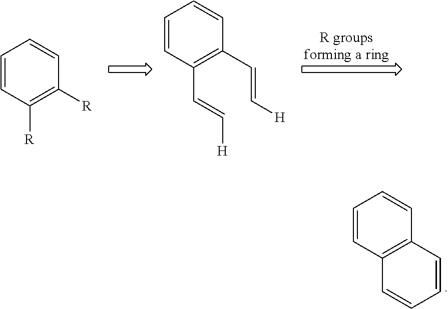

The expression that adjacent substituents can be optionally joined to form a ring is also intended to mean that two substituents bonded to further distant carbon atoms are joined to each other via a chemical bond to form a ring, which can be exemplified by the following formula:

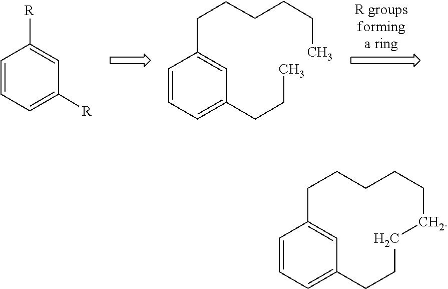

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

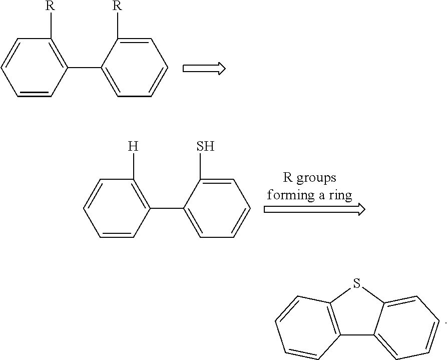

According to an embodiment of the present disclosure, an active-matrix organic electroluminescent display is disclosed, which comprises a plurality of pixels;
wherein each pixel among the plurality of pixels comprises at least one organic electroluminescent device;
the organic electroluminescent device comprises an anode, a cathode, and an organic layer disposed between the anode and the cathode;
the organic layer comprises at least a common first organic layer, and the common first organic layer is shared by at least two pixels;
the common first organic layer comprises at least a first organic material and a second organic material;
the LUMO energy level of the first organic material is denoted as LUMO_{first_organic_material}, the HOMO energy level of the second organic material is denoted as HOMO_{second_organic_material}, and −0.1 eV<LUMO_{first_organic_material}−HOMO_{second_organic_material}<0.25 eV;
the mass doping ratio of the first organic material in the common first organic layer is A %, and 5≤A≤15;
the lateral conductivity of the common first organic layer is B_{A}, the lateral conductivity per unit doping of the common first organic layer is σ_{A}, wherein σ_{A}=B_{A}/A, and at least one σ_{A} satisfies 0.05×10⁻⁴ S/m≤σ_{A}≤1×10⁻⁴ S/m.

According to an embodiment of the present disclosure, the organic electroluminescent device is a single-layer device having a device voltage less than or equal to 5.0 V at a constant current density of 10 mA/cm².

According to an embodiment of the present disclosure, the organic electroluminescent device is a single-layer device having a device voltage less than or equal to 4.5 V at a constant current density of 10 mA/cm².

According to an embodiment of the present disclosure, the organic electroluminescent device is a single-layer device having a device voltage less than or equal to 4.4 V at a constant current density of 10 mA/cm².

According to an embodiment of the present disclosure, the organic electroluminescent device is a single-layer device having a device voltage less than or equal to 4.3 V at a constant current density of 10 mA/cm².

According to an embodiment of the present disclosure, the organic electroluminescent device is a single-layer device having a device voltage less than or equal to 4.2 V at a constant current density of 10 mA/cm².

According to an embodiment of the present disclosure, the organic electroluminescent device is a single-layer device having a device voltage less than or equal to 4.1 V at a constant current density of 10 mA/cm².

According to an embodiment of the present disclosure, the organic electroluminescent device is a single-layer device having a device voltage less than or equal to 4.0 V at a constant current density of 10 mA/cm².

According to an embodiment of the present disclosure, the common first organic layer is shared by all pixels.

According to an embodiment of the present disclosure, the common first organic layer is a hole injection layer or a hole transport layer.

According to an embodiment of the present disclosure, the common first organic layer is the hole injection layer.

According to an embodiment of the present disclosure, the first organic material is a p-type conductive doping material, and the second organic material is a hole transport material.

According to an embodiment of the present disclosure, −0.05 eV<LUMO_{first_organic_material}−HOMO_{second_organic_material}<0.25 eV.

According to an embodiment of the present disclosure, 0 eV≤LUMO_{first_organic_material}-HOMO_{second_organic_material}<0.25 eV.

According to an embodiment of the present disclosure, 0 eV≤LUMO_{first_organic_material}-HOMO_{second_organic_material}≤0.23 eV.

According to an embodiment of the present disclosure, 0 eV≤LUMO_{first_organic_material}-HOMO_{second_organic_material}≤0.21 eV.

According to an embodiment of the present disclosure, 0 eV≤LUMO_{first_organic_material}-HOMO_{second_organic_material}≤0.19 eV.

According to an embodiment of the present disclosure, 0 eV≤LUMO_{first_organic_material}-HOMO_{second_organic_material}≤0.17 eV.

According to an embodiment of the present disclosure, 0 eV≤LUMO_{first_organic_material}-HOMO_{second_organic_material}≤0.15 eV.

According to an embodiment of the present disclosure, the mass doping ratio of the first organic material in the common first organic layer is A %, and 6≤A≤15.

According to an embodiment of the present disclosure, the mass doping ratio of the first organic material in the common first organic layer is A %, and 6≤A≤14.

According to an embodiment of the present disclosure, the mass doping ratio of the first organic material in the common first organic layer is A %, and 6≤A≤13.

According to an embodiment of the present disclosure, the mass doping ratio of the first organic material in the common first organic layer is A %, and 6≤A≤12.

According to an embodiment of the present disclosure, the mass doping ratio of the first organic material in the common first organic layer is A %, and 6≤A≤11.

According to an embodiment of the present disclosure, the mass doping ratio of the first organic material in the common first organic layer is A %, and 6≤A≤10.

According to an embodiment of the present disclosure, the mass doping ratio of the first organic material in the common first organic layer is A %, and 5≤A≤10.

According to an embodiment of the present disclosure, the mass doping ratio of the first organic material in the common first organic layer is A %, and 5≤A≤9.

According to an embodiment of the present disclosure, the mass doping ratio of the first organic material in the common first organic layer is A %, and 5≤A≤8.

According to an embodiment of the present disclosure, the lateral conductivity per unit doping of the common first organic layer is σ_{A}, wherein σ_{A}=B_{A}/A, and at least one σ_{A} satisfies 0.06×10⁻⁴ S/m≤σ_{A}<1×10⁻⁴ S/m.

According to an embodiment of the present disclosure, the lateral conductivity per unit doping of the common first organic layer is σ_{A}, wherein σ_{A}=B_{A}/A, and at least one σ_{A} satisfies 0.07×10⁻⁴ S/m≤σ_{A}<1×10⁻⁴ S/m.

According to an embodiment of the present disclosure, the lateral conductivity per unit doping of the common first organic layer is σ_{A}, wherein σ_{A}=B_{A}/A, and at least one σ_{A} satisfies 0.08×10⁻⁴ S/m≤σ_{A}<1×10⁻⁴ S/m.

According to an embodiment of the present disclosure, the lateral conductivity per unit doping of the common first organic layer is σ_{A}, wherein σ_{A}=B_{A}/A, and at least one σ_{A} satisfies 0.09×10⁻⁴ S/m≤σ_{A}<1×10⁻⁴ S/m.

According to an embodiment of the present disclosure, the lateral conductivity per unit doping of the common first organic layer is σ_{A}, wherein σ_{A}=B_{A}/A, and at least one σ_{A} satisfies 0.1×10⁻⁴ S/m≤σ_{A}<1×10⁻⁴ S/m.

According to an embodiment of the present disclosure, the lateral conductivity per unit doping of the common first organic layer is σ_{A}, wherein σ_{A}=B_{A}/A, and at least one σ_{A} satisfies 0.15×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least one σ_{A} satisfies 0.16×10⁻⁴ S/m≤σ_{A}≤0.7×10⁻⁴ S/m.

According to an embodiment of the present disclosure, the lateral conductivity per unit doping of the common first organic layer is σ_{A}, wherein σ_{A}=B_{A}/A, and at least two σ_{A} satisfies 0.05×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least two σ_{A} satisfy 0.06×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least two σ_{A} satisfy 0.07×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least two σ_{A} satisfy 0.08×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least two σ_{A} satisfy 0.09×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least two σ_{A} satisfy 0.1×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least three σ_{A} satisfy 0.05×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least three σ_{A} satisfy 0.06×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least three σ_{A} satisfy 0.07×10⁻⁴ S/m≤σ_{A}≤1×10⁻⁴ S/m.

According to an embodiment of the present disclosure, the lateral conductivity per unit doping of the common first organic layer is JA, wherein σ_{A}=B_{A}/A, and at least three σ_{A} satisfy 0.08×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least three σ_{A} satisfy 0.09×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least three σ_{A} satisfy 0.1×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least σ₆, σ₈ and σ₁₀ all satisfy 0.05×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least σ₆, σ₈ and σ₁₀ all satisfy 0.08×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least σ₆, σ₈ and σ₁₀ all satisfy 0.1×10⁻⁴ S/m σ_{A}≤1×10⁻⁴ S/m.

According to an embodiment of the present disclosure, the lateral conductivity per unit doping of the common first organic layer is σ_{A}, wherein σ_{A}=B_{A}/A, and at least σ₆, σ₈ and σ₁₀ all satisfy 0.15×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least σ₆, σ₈ and σ₁₀ all satisfy 0.05×10⁻⁴ S/m≤σ_{A}≤0.9×10⁻⁴ S/m.

According to an embodiment of the present disclosure, the lateral conductivity per unit doping of the common first organic layer is σ_{A}, wherein σ_{A}=B_{A}/A, and at least σ₆, σ₈ and σ₁₀ all satisfy 0.05×10⁻⁴ S/m≤σ_{A}≤0.8×10⁻⁴ S/m.

According to an embodiment of the present disclosure, the lateral conductivity per unit doping of the common first organic layer is σ_{A}, wherein σ_{A}=B_{A}/A, and at least σ₆, σ₈ and σ₁₀ all satisfy 0.05×10⁻⁴ S/m≤σ_{A}≤0.7×10⁻⁴ S/m.

According to an embodiment of the present disclosure, the lateral conductivity per unit doping of the common first organic layer is σ_{A}, wherein σ_{A}=B_{A}/A, and at least σ₆, σ₈ and σ₁₀ all satisfy 0.16×10⁻⁴ S/m≤σ_{A}≤0.7×10⁻⁴ S/m.

According to an embodiment of the present disclosure, the lateral conductivity per unit doping of the common first organic layer is σ_{A}, wherein σ_{A}=B_{A}/A, and at least six σ_{A} satisfy 0.05×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least six σ_{A} satisfy 0.06×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least six σ_{A} satisfy 0.07×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least six σ_{A} satisfy 0.08×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least six σ_{A} satisfy 0.09×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least six σ_{A} satisfy 0.1×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least σ₅, σ₆, σ₇, σ₈ σ₉ and σ₁₀ all satisfy 0.05×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least σ₅, σ₆, σ₇, σ₈ σ₉ and σ₁₀ all satisfy 0.08×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least σ₅, σ₆, σ₇, σ₈ σ₉ and σ₁₀ all satisfy 0.1×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and at least σ₅, σ₆, σ₇, σ₈ σ₉ and σ₁₀ all satisfy 0.15×10⁻⁴ S/m≤σ_{A}<1×10⁻⁴ S/m.

According to an embodiment of the present disclosure, the lateral conductivity per unit doping of the common first organic layer is σ_{A}, wherein σ_{A}=B_{A}/A, and at least σ₅, σ₆, σ₇, σ₈ σ₉ and σ₁₀ all satisfy 0.15×10⁻⁴ S/m≤σ_{A}<0.9×10⁻⁴ S/m.

According to an embodiment of the present disclosure, the lateral conductivity per unit doping of the common first organic layer is σ_{A}, wherein σ_{A}=B_{A}/A, and at least σ₅, σ₆, σ₇, σ₈ σ₉ and σ₁₀ all satisfy 0.05×10⁻⁴ S/m≤σ_{A}≤0.9×10⁻⁴ S/m.

According to an embodiment of the present disclosure, the lateral conductivity per unit doping of the common first organic layer is σ_{A}, wherein σ_{A}=B_{A}/A, and at least σ₅, σ₆, σ₇, σ₈ σ₉ and σ₁₀ all satisfy 0.05×10⁻⁴ S/m≤σ_{A}≤0.8×10⁻⁴ S/m.

According to an embodiment of the present disclosure, the lateral conductivity per unit doping of the common first organic layer is σ_{A}, wherein σ_{A}=B_{A}/A, and at least σ₅, σ₆, σ₇, σ₈ σ₉ and σ₁₀ all satisfy 0.05×10⁻⁴ S/m≤σ_{A}≤0.7×10⁻⁴ S/m.

According to an embodiment of the present disclosure, the lateral conductivity per unit doping of the common first organic layer is σ_{A}, wherein σ_{A}=B_{A}/A, and at least σ₅, σ₆, σ₇, σ₈ σ₉ and σ₁₀ all satisfy 0.16×10⁻⁴ S/m≤σ_{A}≤0.7×10⁻⁴ S/m.

According to an embodiment of the present disclosure, the lateral conductivity per unit doping of the common first organic layer is σ_{A}, wherein σ_{A}=B_{A}/A, and at least σ₅, σ₆, σ₇, σ₈ σ₉ and σ₁₀ all satisfy 0.17×10⁻⁴ S/m≤σ_{A}≤1×10⁻⁴ S/m.

According to an embodiment of the present disclosure, the lateral conductivity per unit doping of the common first organic layer is JA, wherein σ_{A}=B_{A}/A, and at least σ₅, σ₆, σ₇, σ₈ σ₉ and σ₁₀ all satisfy 0.17×10⁻⁴ S/m≤σ_{A}≤0.9×10⁻⁴ S/m.

According to an embodiment of the present disclosure, the lateral conductivity per unit doping of the common first organic layer is σ_{A}, wherein σ_{A}=B_{A}/A, and all σ_{A} satisfy 0.05×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and all σ_{A} satisfy 0.06×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and all σ_{A} satisfy 0.07×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and all σ_{A} satisfy 0.08×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and all σ_{A} satisfy 0.09×10⁻⁴ S/m≤σ_{A}≤1×10⁻⁴ S/m.

According to an embodiment of the present disclosure, the lateral conductivity per unit doping of the common first organic layer is σ_{A}, wherein σ_{A}=B_{A}/A, and all σ_{A} satisfy 0.1×10⁻⁴ S/m σ_{A}≤1×10⁻⁴ S/m.

According to an embodiment of the present disclosure, the lateral conductivity per unit doping of the common first organic layer is σ_{A}, wherein σ_{A}=B_{A}/A, and all σ_{A} satisfy 0.1×10⁻⁴ S/m≤σ_{A}≤0.8×10⁻⁴ S/m.

According to an embodiment of the present disclosure, the lateral conductivity per unit doping of the common first organic layer is σ_{A}, wherein σ_{A}=B_{A}/A, and all σ_{A} satisfy 0.05×10⁻⁴ S/m≤σ_{A}≤0.9×10⁻⁴ S/m.

According to an embodiment of the present disclosure, the lateral conductivity per unit doping of the common first organic layer is σ_{A}, wherein σ_{A}=B_{A}/A, and all of satisfy 0.05×10⁻⁴ S/m≤σ_{A}≤0.8×10⁻⁴ S/m.

According to an embodiment of the present disclosure, the lateral conductivity per unit doping of the common first organic layer is σ_{A}, wherein σ_{A}=B_{A}/A, and all σ_{A} satisfy 0.05×10⁻⁴ S/m≤σ_{A}≤0.7×10⁻⁴ S/m.

According to an embodiment of the present disclosure, the lateral conductivity per unit doping of the common first organic layer is σ_{A}, wherein σ_{A}=B_{A}/A, and all σ_{A} satisfy 0.05×10⁻⁴ S/m≤σ_{A}≤0.6×10⁻⁴ S/m.

According to an embodiment of the present disclosure, the lateral conductivity per unit doping of the common first organic layer is σ_{A}, wherein σ_{A}=B_{A}/A, and all σ_{A} satisfy 0.05×10⁻⁴ S/m≤σ_{A}≤0.5×10⁻⁴ S/m.

According to an embodiment of the present disclosure, the lateral conductivity per unit doping of the common first organic layer is JA, wherein σ_{A}=B_{A}/A, and all σ_{A} satisfy 0.15×10⁻⁴ S/m≤σ_{A}≤1×10⁻⁴ S/m.

According to an embodiment of the present disclosure, the lateral conductivity per unit doping of the common first organic layer is JA, wherein σ_{A}=B_{A}/A, and all σ_{A} satisfy 0.16×10⁻⁴ S/m≤σ_{A}≤0.7×10⁻⁴ S/m.

According to an embodiment of the present disclosure, −5.30 eV≤LUMO_{first_organic_material}≤−4.80 eV.

According to an embodiment of the present disclosure, −5.20 eV<LUMO_{first_organic_material}≤−4.90 eV.

According to an embodiment of the present disclosure, −5.16 eV≤LUMO_{first_organic_material}≤−4.80 eV.

According to an embodiment of the present disclosure, −5.14 eV≤LUMO_{first_organic_material}≤−4.80 eV.

According to an embodiment of the present disclosure, −5.12 eV≤LUMO_{first_organic_material}≤−4.80 eV.

According to an embodiment of the present disclosure, −5.35 eV≤HOMO_{second_organic_material}≤−5.00 eV.

According to an embodiment of the present disclosure, −5.33 eV≤HOMO_{second_organic_material}≤−5.00 eV.

According to an embodiment of the present disclosure, −5.30 eV≤HOMO_{second_organic_material}≤−5.00 eV.

According to an embodiment of the present disclosure, −5.25 eV≤HOMO_{second_organic_material}≤−5.00 eV.

According to an embodiment of the present disclosure, −5.25 eV<HOMO_{second_organic_material}≤−5.10 eV.

According to an embodiment of the present disclosure, −5.30 eV≤HOMO_{second_organic_material}≤−5.04 eV.

According to an embodiment of the present disclosure, −5.30 eV≤HOMO_{second_organic_material}≤−5.06 eV.

According to an embodiment of the present disclosure, −5.30 eV≤HOMO_{second_organic_material}≤−5.08 eV.

According to an embodiment of the present disclosure, the plurality of pixels are capable of emitting light of the same color or light of different colors.

According to an embodiment of the present disclosure, the lateral conductivity of the common first organic layer is B_{A}, and 0.2×10⁻⁴ S/m≤B_{A}<15×10⁻⁴ S/m.

According to an embodiment of the present disclosure, the lateral conductivity of the common first organic layer is B_{A}, and 0.3×10⁻⁴ S/m≤B_{A}<15×10⁻⁴ S/m.

According to an embodiment of the present disclosure, the lateral conductivity of the common first organic layer is B_{A}, and 0.4×10⁻⁴ S/m≤B_{A}<15×10⁻⁴ S/m.

According to an embodiment of the present disclosure, the lateral conductivity of the common first organic layer is B_{A}, and 0.5×10⁻⁴ S/m≤B_{A}<15×10⁻⁴ S/m.

According to an embodiment of the present disclosure, the lateral conductivity of the common first organic layer is B_{A}, and 0.2×10⁻⁴ S/m≤B_{A}<13×10⁻⁴ S/m.

According to an embodiment of the present disclosure, the lateral conductivity of the common first organic layer is B_{A}, and 0.2×10⁻⁴ S/m≤B_{A}<11×10⁻⁴ S/m.

According to an embodiment of the present disclosure, the lateral conductivity of the common first organic layer is B_{A}, and 0.2×10⁻⁴ S/m≤B_{A}<9×10⁻⁴ S/m.

According to an embodiment of the present disclosure, the lateral conductivity of the common first organic layer is B_{A}, and 0.2×10⁻⁴ S/m≤B_{A}<7×10⁻⁴ S/m.

According to an embodiment of the present disclosure, the lateral conductivity B_{A} of the common first organic layer is tested in the following method: depositing the first organic material and the second organic material on a test substrate prepared with an aluminum electrode in advance at a certain mass ratio through co-deposition at a vacuum degree of about 10⁻⁶ Torr, forming a to-be-tested region with a thickness of 100 nm, a length of 6 mm and a width of 1 mm, obtaining an electric resistance value of the region through a method of applying a voltage to the electrode and measuring a current at room temperature, and calculating the lateral conductivity B_{A} of the layer of Ohm's law and a geometric dimension.

According to an embodiment of the present disclosure, the first organic material is selected from the following compounds: quinone or quinone derivatives, radialene compounds, dehydrobenzoxazole and dehydrobenzothiazole compounds, and bisoxazole or bisthiazole compounds.

According to an embodiment of the present disclosure, the first organic material has a structure represented by Formula 1:

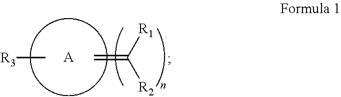

wherein
n is selected from an integer from 1 to 6;
the ring A is selected from a conjugated ring having 3 to 30 ring atoms;
R₃ represents mono-substitution, multiple substitutions or non-substitution;
R₁, R₂ and R₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁, R₂ and R₃ can be optionally joined to form a ring.

Herein, the expression that “the ring A is selected from a conjugated ring having 3 to 30 ring atoms” is intended to mean that the ring A is a ring structure having 3 to 30 ring atoms and the ring A has a structural feature of being conjugated. For example, the ring A comprises, but is not limited to, the structures represented by Formula A-1 to Formula A-13 in the present application. The ring A may be a monocyclic structure or a polycyclic structure, wherein the polycyclic ring may be a parallel-ring structure or a fused-ring structure or may be an integrally conjugated structure formed by connecting two conjugated rings by a double bond, such as the structure represented by Formula A-12 in the present application. The ring A may be a carbocyclic ring or a heterocyclic ring.

Herein, the expression that “adjacent substituents R₁, R₂ and R₃ can be optionally joined to form a ring” is intended to mean that any one or more of groups of adjacent substituents, such as substituents R₃, substituents R₁ and R₂, substituents R₁ and R₃, and substituents R₂ and R₃, can be joined to form a ring. Obviously, it is also possible that none of these substituents are joined to form a ring.

According to an embodiment of the present disclosure, n is an even number.

According to an embodiment of the present disclosure, n is selected from 2, 4 or 6.

According to an embodiment of the present disclosure, n is selected from 1, 2 or 3.

According to an embodiment of the present disclosure, n is selected from 1 or 2.

According to an embodiment of the present disclosure, the ring A is selected from a conjugated ring having 3 to 20 ring atoms.

According to an embodiment of the present disclosure, the ring A is selected from a conjugated ring having 4 to 20 ring atoms.

According to an embodiment of the present disclosure, at least one of the substituents R₁, R₂ and R₃ is a substituent comprising at least one electron-withdrawing group.

According to an embodiment of the present disclosure, R₁ and/or R₂ are substituents comprising at least one electron withdrawing group.

According to an embodiment of the present disclosure, the Hammett constant of the electron-withdrawing group is greater than or equal to 0.05.

According to an embodiment of the present disclosure, the Hammett constant of the electron-withdrawing group is greater than or equal to 0.3.

According to an embodiment of the present disclosure, the Hammett constant of the electron-withdrawing group is greater than or equal to 0.5.

In the present disclosure, the Hammett substituent constant value of the electron-withdrawing group is ≥0.05, for example, ≥0.1 or ≥0.2; preferably ≥0.3; more preferably ≥0.5. The electron-withdrawing ability is relatively strong, which can significantly reduce the LUMO energy level of the compound and achieve the improvement of the charge mobility.

It should be noted that the Hammett substituent constant value includes Hammett substituent para-constant and/or meta-constant. As long as the conditions that the para-constant and the meta-constant are both greater than 0 and one of the para-constant and the meta-constant is greater than or equal to 0.05 are satisfied, the substituent can be used as the group selected in the present disclosure.

According to an embodiment of the present disclosure, the electron-withdrawing group is selected from the group consisting of: halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, an aza-aromatic ring group and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group and an aza-aromatic ring group: alkyl having 1 to 20 carbon atoms, cycloalkyl having 3 to 20 ring carbon atoms, heteroalkyl having 1 to 20 carbon atoms, a heterocyclic group having 3 to 20 ring atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms, and combinations thereof.

According to an embodiment of the present disclosure, the electron-withdrawing group is selected from the group consisting of: halogen, a nitroso group, a nitro group, an acyl group, a carbonyl group, a carboxylic acid group, an ester group, SF₅, a boranyl group, a sulfinyl group, a sulfonyl group, a phosphoroso group, an aza-aromatic ring group and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group and an aza-aromatic ring group: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms, and combinations thereof.

According to an embodiment of the present disclosure, the electron-withdrawing group is selected from the group consisting of: fluorine, an acyl group, a carbonyl group, an ester group, SF₅, a boranyl group, an aza-aromatic ring group and any one of the following groups substituted with one or more of fluorine, a cyano group, an isocyano group, SCN, OCN, SF₅, CF₃, OCF₃, SCF₃, and an aza-aromatic ring group: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms, and combinations thereof.

According to an embodiment of the present disclosure, the ring A is selected from the group consisting of Formula A-1 to Formula A-13:

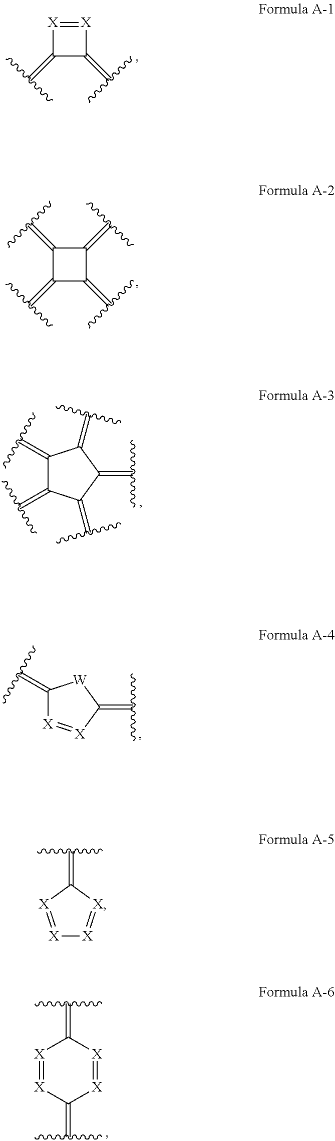

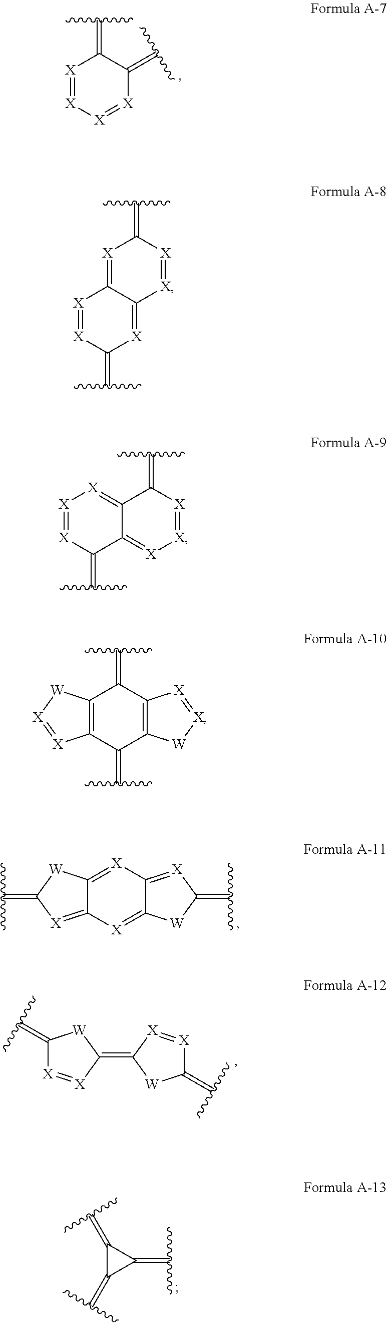

wherein
X is, at each occurrence identically or differently, selected from N or CR₃;
W is, at each occurrence identically or differently, selected from O, S, Se or NR₃;
R₃ is, at each occurrence identically or differently, selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group or a combination thereof;
adjacent substituents R₃ can be optionally joined to form a ring;
“ [symbol] ” represents a position where Formula A-1 to Formula A-13 are joined to the double bond in Formula 1.

According to an embodiment of the present disclosure, the ring A is selected from Formula A-6, Formula A-8, Formula A-10, Formula A-11 or Formula A-12.

According to an embodiment of the present disclosure, the first organic material has a structure represented by one of Formula 1-1 to Formula 1-5:

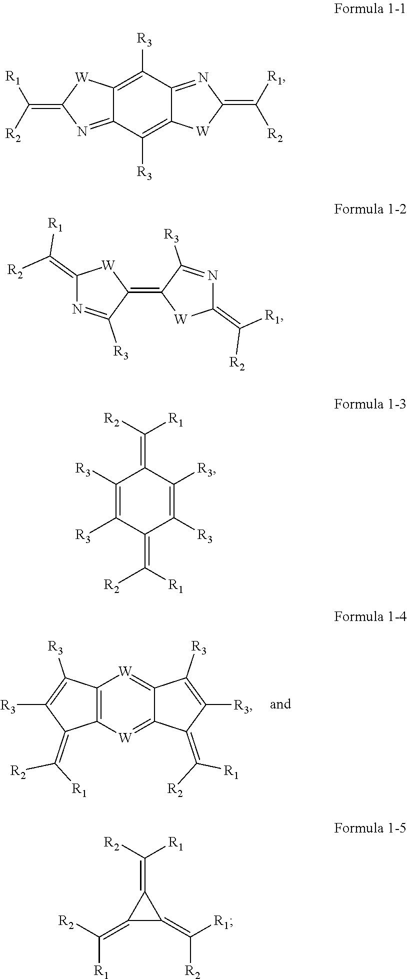

wherein
W is, at each occurrence identically or differently, selected from the group consisting of O, S, Se, CR₃ and NR₃;
R₁, R₂ and R₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino group having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁, R₂ and R₃ can be optionally joined to form a ring.

According to an embodiment of the present disclosure, W is, at each occurrence identically or differently, selected from O, S or Se.

According to an embodiment of the present disclosure, W is, at each occurrence identically or differently, selected from O or S.

According to an embodiment of the present disclosure, W is selected from O.

According to an embodiment of the present disclosure, R₁, R₂ and R₃ are, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, unsubstituted alkyl having 1 to 20 carbon atoms, unsubstituted cycloalkyl having 3 to 20 ring carbon atoms, unsubstituted alkoxy having 1 to 20 carbon atoms, unsubstituted alkenyl having 2 to 20 carbon atoms, unsubstituted aryl having 6 to 30 carbon atoms, unsubstituted heteroaryl having 3 to 30 carbon atoms, and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group and a phosphoroso group: alkyl having 1 to 20 carbon atoms, cycloalkyl having 3 to 20 ring carbon atoms, alkoxy having 1 to 20 carbon atoms, alkenyl having 2 to 20 carbon atoms, aryl having 6 to 30 carbon atoms, heteroaryl having 3 to 30 carbon atoms, and combinations thereof.

According to an embodiment of the present disclosure, R₁, R₂ and R₃ are, at each occurrence identically or differently, selected from the group consisting of: hydrogen, deuterium, methyl, isopropyl, NO₂, SO₂CH₃, SCF₃, C₂F₅, OC₂F₅, OCH₃, diphenylmethylsilyl, phenyl, methoxyphenyl, p-methylphenyl, 2,6-diisopropylphenyl, polyfluorophenyl, difluoropyridyl, nitrophenyl, dimethylthiazolyl, vinyl substituted with one or more of CN or CF₃, acetenyl substituted with one of CN or CF₃, dimethylphosphoroso, diphenylphosphoroso, F, CF₃, OCF₃, SF₅, SO₂CF₃, a cyano group, an isocyano group, SCN, OCN, trifluoromethylphenyl, trifluoromethoxyphenyl, bis(trifluoromethyl)phenyl, bis(trifluoromethoxy)phenyl, 4-cyanotetrafluorophenyl, phenyl or biphenyl substituted with one or more of F, CN or CF₃, tetrafluoropyridyl, pyrimidinyl, triazinyl, diphenylboranyl, oxaboraanthryl, and combinations thereof.

According to an embodiment of the present disclosure, R₁ and R₂ are, at each occurrence identically or differently, selected from the group consisting of: halogen, cyano, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, R₁ and R₂ are, at each occurrence identically or differently, selected from the group consisting of: cyano, substituted or unsubstituted aryl having 6 to 30 carbon atoms, substituted or unsubstituted heteroaryl having 3 to 30 carbon atoms, and combinations thereof.

According to an embodiment of the present disclosure, R₁ is selected from cyano.

According to an embodiment of the present disclosure, R₁ and R₂ are selected from cyano.

According to an embodiment of the present disclosure, R₃ is selected from substituted or unsubstituted aryl having 6 to 30 carbon atoms, substituted or unsubstituted heteroaryl having 3 to 30 carbon atoms or a combination thereof.

According to an embodiment of the present disclosure, the first organic material has a structure represented by Formula 1-1 or Formula 1-2.

According to an embodiment of the present disclosure, the first organic material has a structure represented by Formula 1-1.

According to an embodiment of the present disclosure, the first organic material is selected from the group consisting of Compound 1-1 to Compound 1-47, Compound 2-2 to Compound 2-22, Compound 3-1 to Compound 3-9, Compound 4-1 to Compound 4-9, and Compound 5-1 to Compound 5-11:

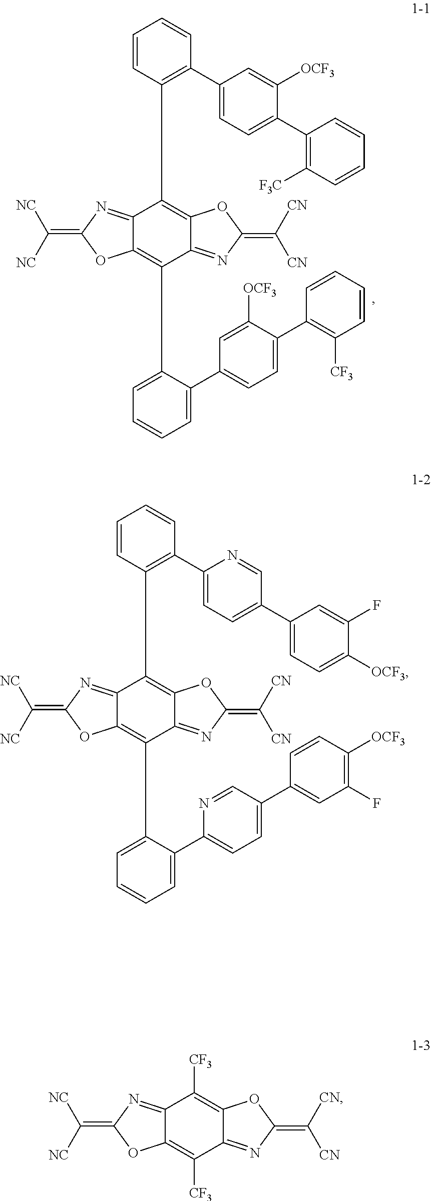 [SMILES: N#CC(C#N)=c1nc2c(-c3ccccc3-c3ccc(-c4ccccc4C(F)(F)F)c(OC(F)(F)F)c3)c3oc(=C(C#N)C#N)nc3c(-c3ccccc3-c3ccc(-c4ccccc4C(F)(F)F)c(OC(F)(F)F)c3)c2o1 ; "," ; N#CC(C#N)=c1nc2c(-c3ccccc3-c3ccc(-c4ccc(OC(F)(F)F)c(F)c4)cn3)c3oc(=C(C#N)C#N)nc3c(-c3ccccc3-c3ccc(-c4ccc(OC(F)(F)F)c(F)c4)cn3)c2o1 ; N#CC(C#N)=c1nc2c(C(F)(F)F)c3oc(=C(C#N)C#N)nc3c(C(F)(F)F)c2o1]

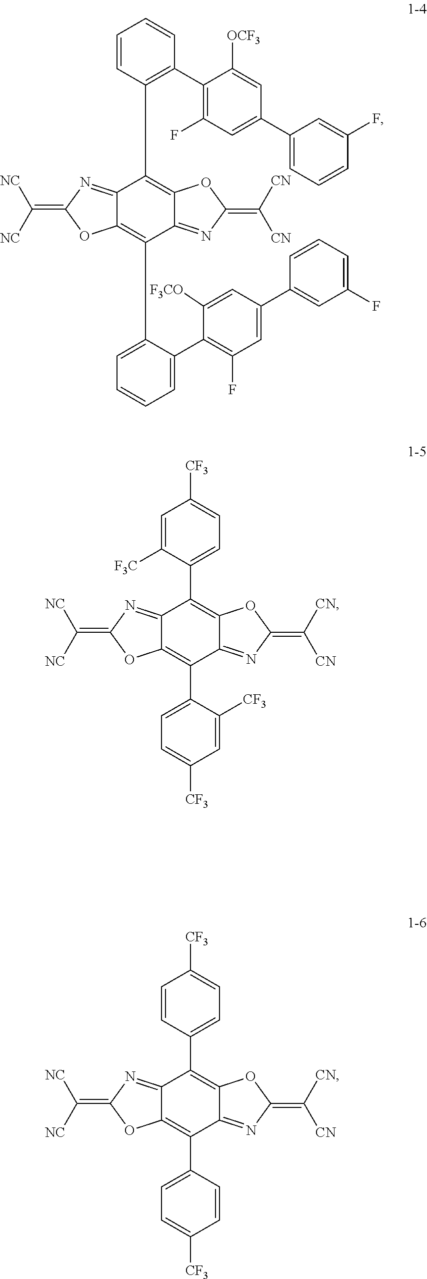 [SMILES: N#CC(C#N)=c1nc2c(-c3ccccc3-c3c(F)cc(-c4cccc(F)c4)cc3OC(F)(F)F)c3oc(=C(C#N)C#N)nc3c(-c3ccccc3-c3c(F)cc(-c4cccc(F)c4)cc3OC(F)(F)F)c2o1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; N#CC(C#N)=c1nc2c(-c3ccc(C(F)(F)F)cc3)c3oc(=C(C#N)C#N)nc3c(-c3ccc(C(F)(F)F)cc3)c2o1]

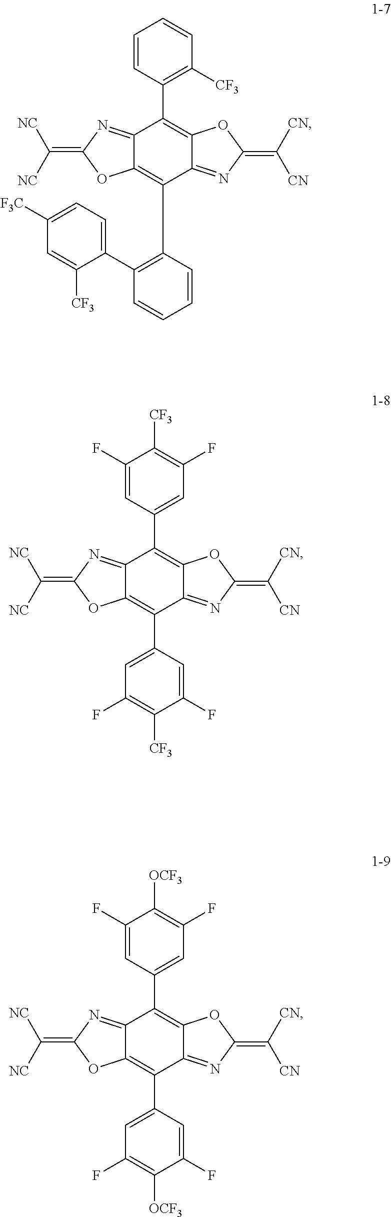 [SMILES: N#CC(C#N)=c1nc2c(-c3ccccc3C(F)(F)F)c3oc(=C(C#N)C#N)nc3c(-c3ccccc3-c3ccc(C(F)(F)F)cc3C(F)(F)F)c2o1 ; N#CC(C#N)=c1nc2c(-c3cc(F)c(C(F)(F)F)c(F)c3)c3oc(=C(C#N)C#N)nc3c(-c3cc(F)c(C(F)(F)F)c(F)c3)c2o1 ; N#CC(C#N)=c1nc2c(-c3cc(F)c(OC(F)(F)F)c(F)c3)c3oc(=C(C#N)C#N)nc3c(-c3cc(F)c(OC(F)(F)F)c(F)c3)c2o1]

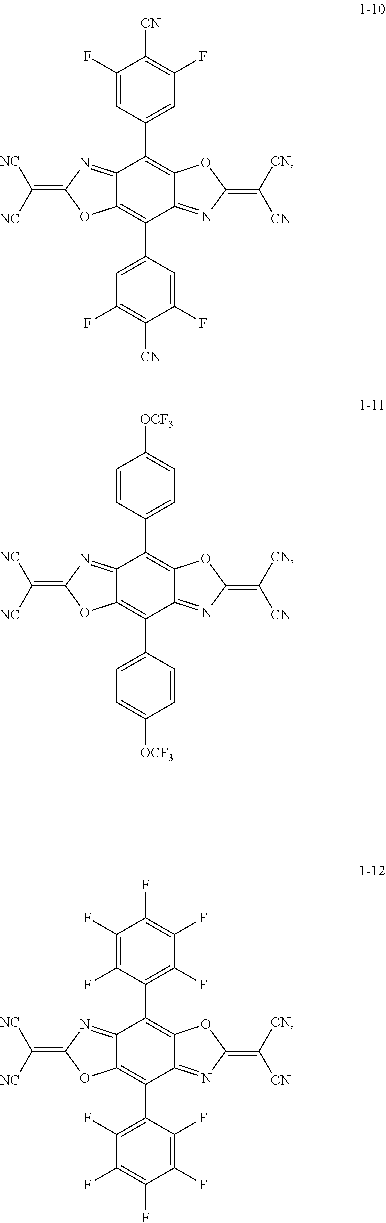 [SMILES: N#CC(C#N)=c1nc2c(-c3cc(F)c(C#N)c(F)c3)c3oc(=C(C#N)C#N)nc3c(-c3cc(F)c(C#N)c(F)c3)c2o1 ; N#CC(C#N)=c1nc2c(-c3ccc(OC(F)(F)F)cc3)c3oc(=C(C#N)C#N)nc3c(-c3ccc(OC(F)(F)F)cc3)c2o1 ; N#CC(C#N)=c1nc2c(-c3c(F)c(F)c(F)c(F)c3F)c3oc(=C(C#N)C#N)nc3c(-c3c(F)c(F)c(F)c(F)c3F)c2o1]

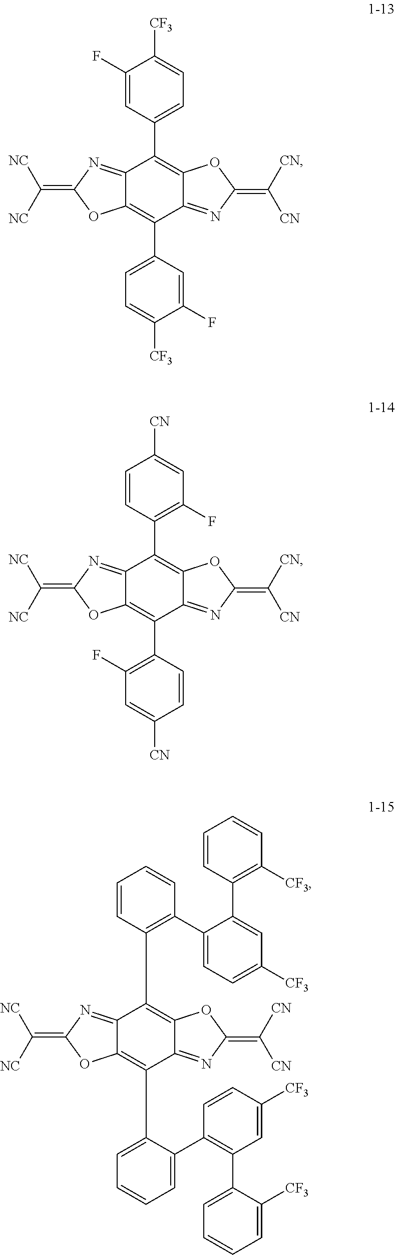 [SMILES: N#CC(C#N)=c1nc2c(-c3ccc(C(F)(F)F)c(F)c3)c3oc(=C(C#N)C#N)nc3c(-c3ccc(C(F)(F)F)c(F)c3)c2o1 ; N#CC(C#N)=c1nc2c(-c3ccc(C#N)cc3F)c3oc(=C(C#N)C#N)nc3c(-c3ccc(C#N)cc3F)c2o1 ; N#CC(C#N)=c1nc2c(-c3ccccc3-c3ccc(C(F)(F)F)cc3-c3ccccc3C(F)(F)F)c3oc(=C(C#N)C#N)nc3c(-c3ccccc3-c3ccc(C(F)(F)F)cc3-c3ccccc3C(F)(F)F)c2o1]

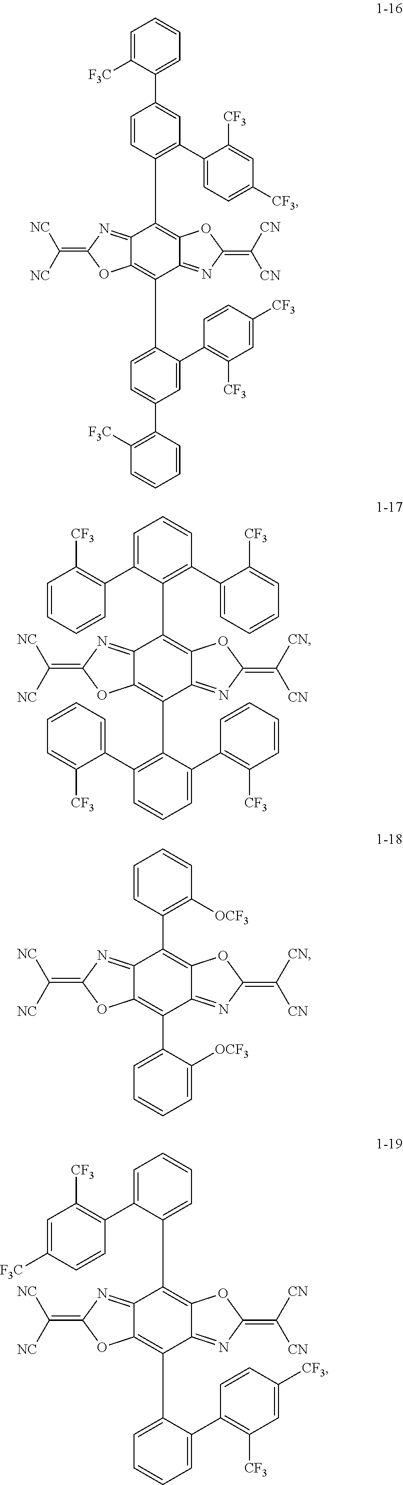

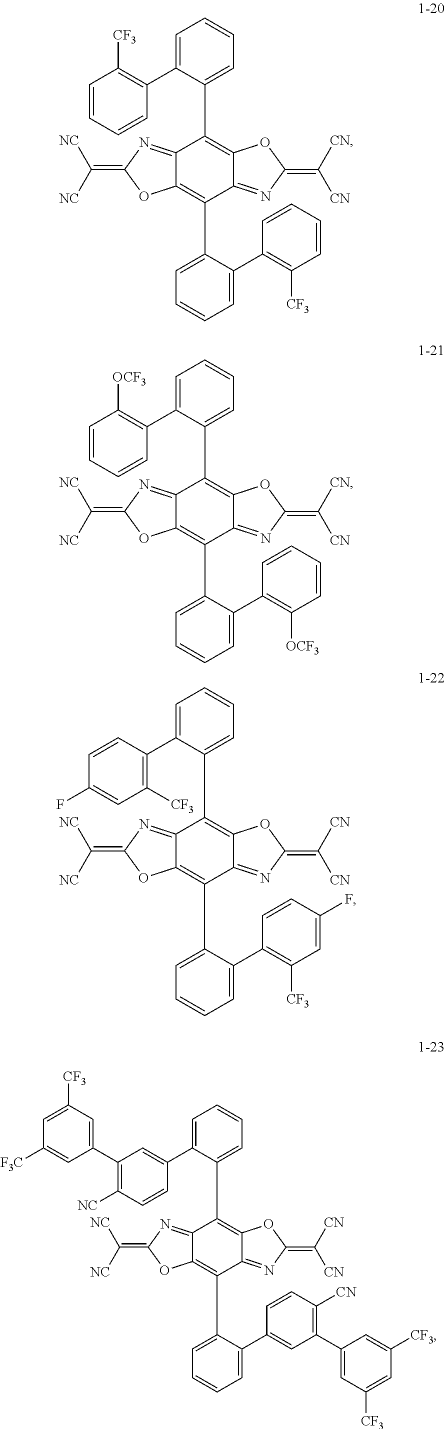

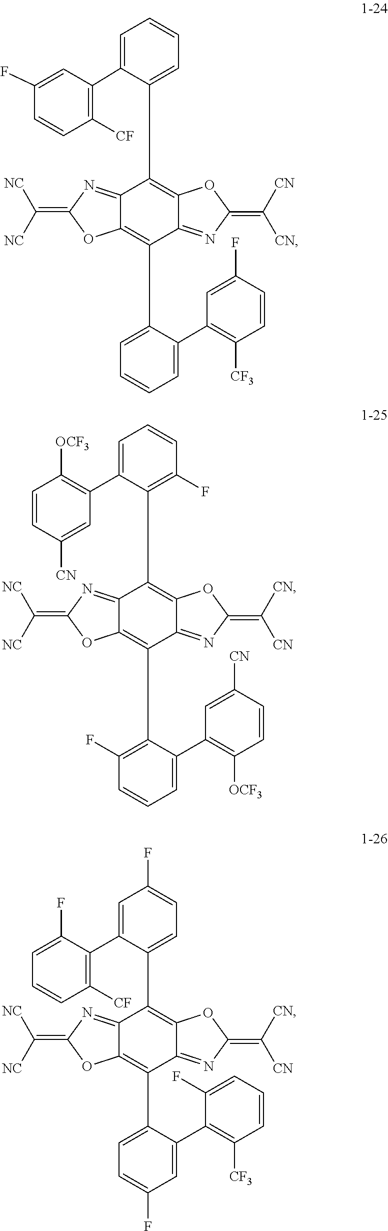

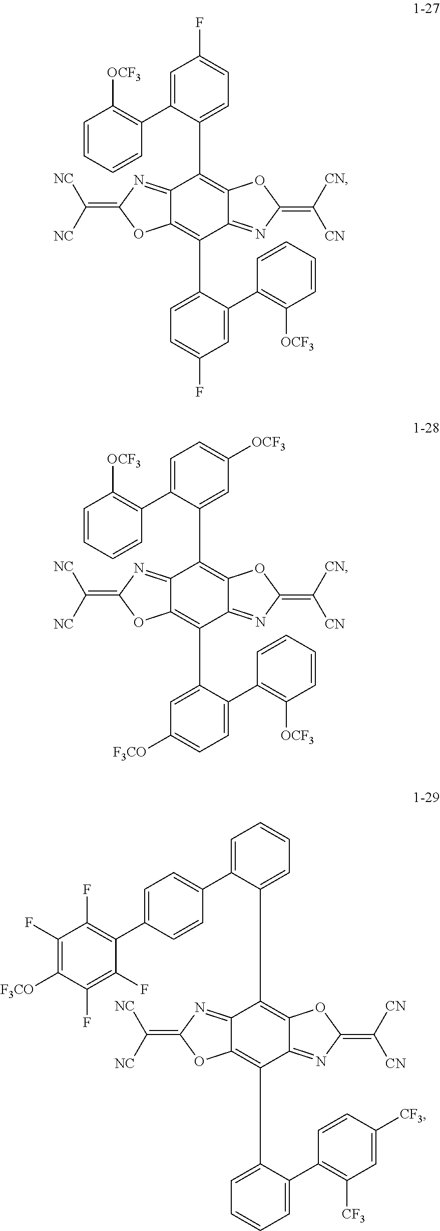 [SMILES: N#CC(C#N)=c1nc2c(-c3ccc(F)cc3-c3ccccc3OC(F)(F)F)c3oc(=C(C#N)C#N)nc3c(-c3ccc(F)cc3-c3ccccc3OC(F)(F)F)c2o1 ; N#CC(C#N)=c1nc2c(-c3cc(OC(F)(F)F)ccc3-c3ccccc3OC(F)(F)F)c3oc(=C(C#N)C#N)nc3c(-c3cc(OC(F)(F)F)ccc3-c3ccccc3OC(F)(F)F)c2o1 ; N#CC(C#N)=c1nc2c(-c3ccccc3-c3ccc(C(F)(F)F)cc3C(F)(F)F)c3oc(=C(C#N)C#N)nc3c(-c3ccccc3-c3ccc(-c4c(F)c(F)c(OC(F)(F)F)c(F)c4F)cc3)c2o1]

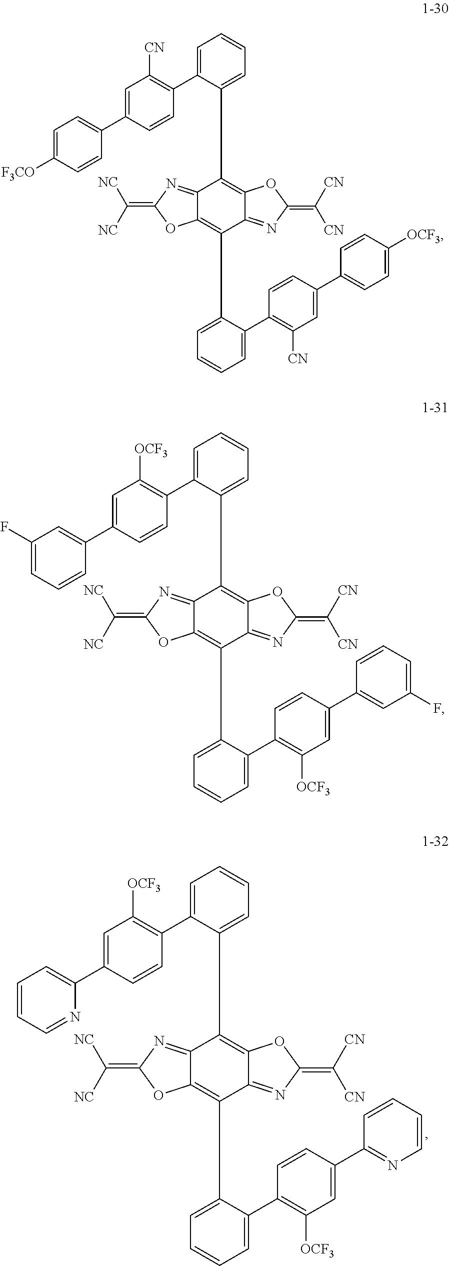 [SMILES: N#CC(C#N)=c1nc2c(-c3ccccc3-c3ccc(-c4ccc(OC(F)(F)F)cc4)cc3C#N)c3oc(=C(C#N)C#N)nc3c(-c3ccccc3-c3ccc(-c4ccc(OC(F)(F)F)cc4)cc3C#N)c2o1 ; N#CC(C#N)=c1nc2c(-c3ccccc3-c3ccc(-c4cccc(F)c4)cc3OC(F)(F)F)c3oc(=C(C#N)C#N)nc3c(-c3ccccc3-c3ccc(-c4cccc(F)c4)cc3OC(F)(F)F)c2o1 ; N#CC(C#N)=c1nc2c(-c3ccccc3-c3ccc(-c4ccccn4)cc3OC(F)(F)F)c3oc(=C(C#N)C#N)nc3c(-c3ccccc3-c3ccc(-c4ccccn4)cc3OC(F)(F)F)c2o1]

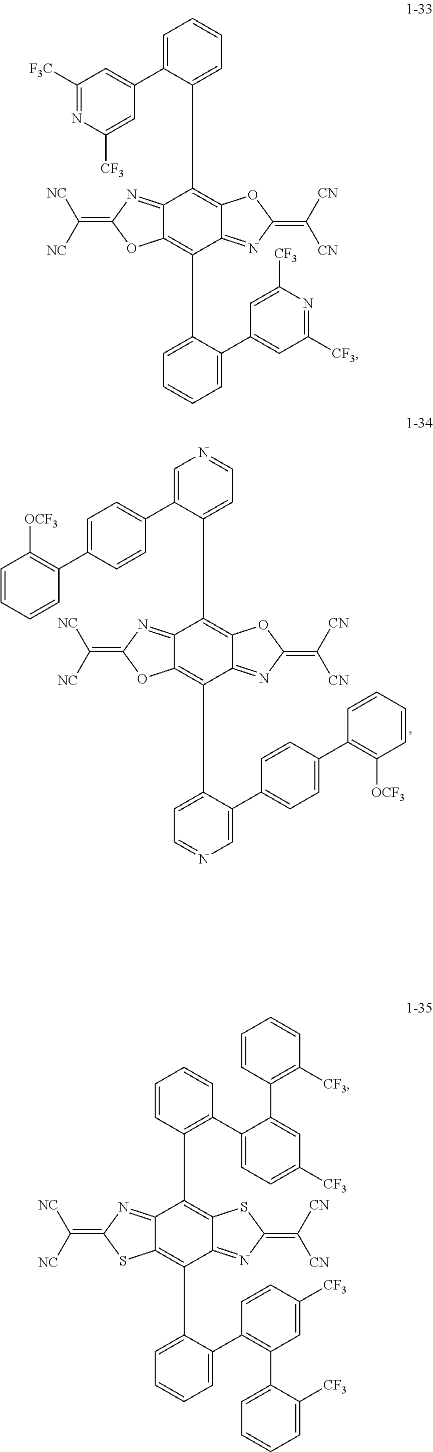 [SMILES: N#CC(C#N)=c1nc2c(-c3ccccc3-c3cc(C(F)(F)F)nc(C(F)(F)F)c3)c3oc(=C(C#N)C#N)nc3c(-c3ccccc3-c3cc(C(F)(F)F)nc(C(F)(F)F)c3)c2o1 ; N#CC(C#N)=c1nc2c(-c3ccncc3-c3ccc(-c4ccccc4OC(F)(F)F)cc3)c3oc(=C(C#N)C#N)nc3c(-c3ccncc3-c3ccc(-c4ccccc4OC(F)(F)F)cc3)c2o1 ; N#CC(C#N)=c1nc2c(-c3ccccc3-c3ccc(C(F)(F)F)cc3-c3ccccc3C(F)(F)F)c3sc(=C(C#N)C#N)nc3c(-c3ccccc3-c3ccc(C(F)(F)F)cc3-c3ccccc3C(F)(F)F)c2s1]

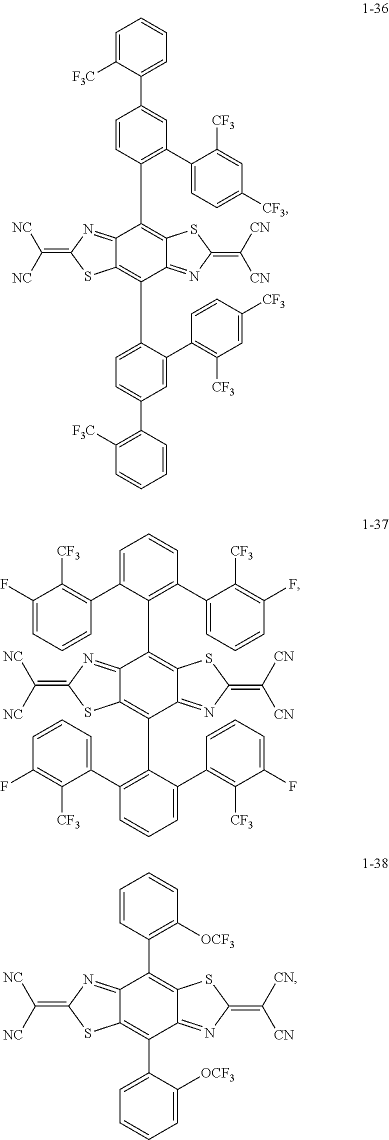

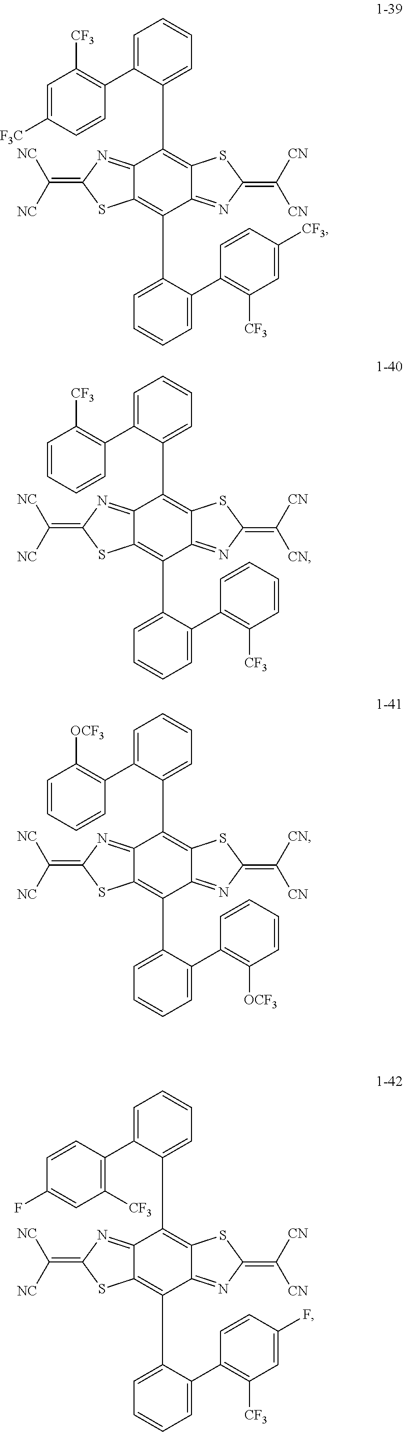

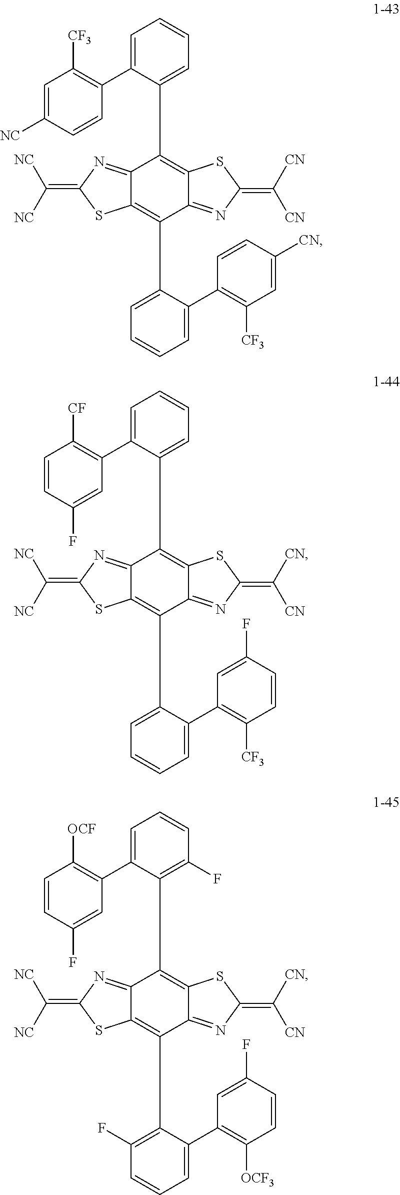

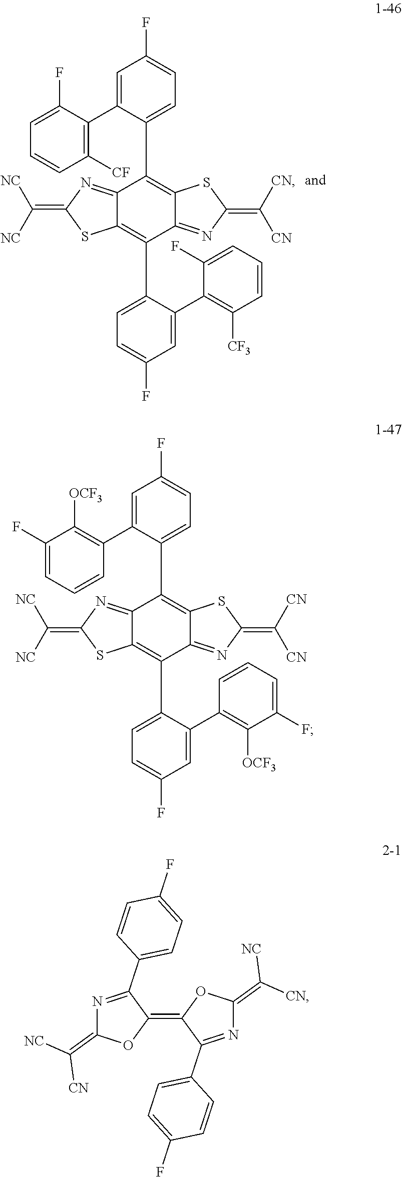

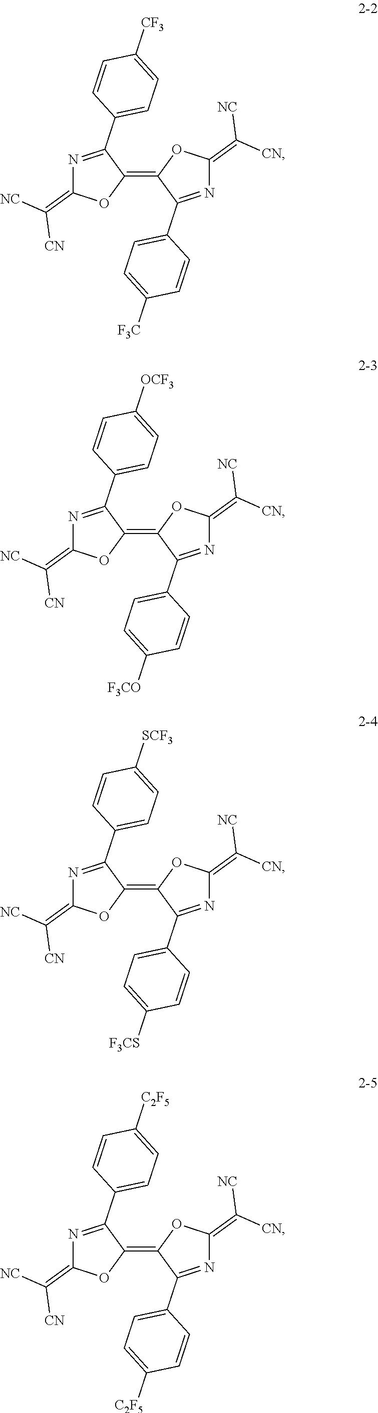

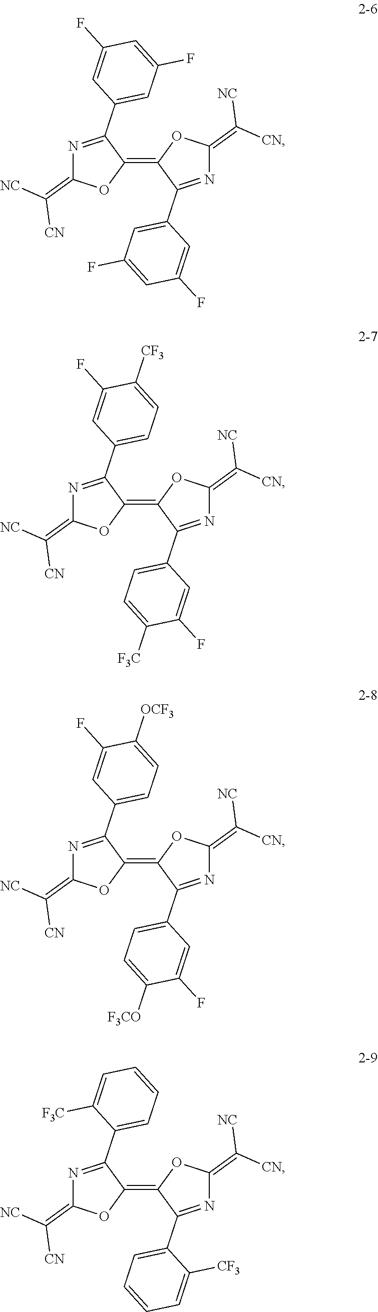 [SMILES: N#CC(C#N)=c1nc(-c2cc(F)cc(F)c2)/c(=c2\oc(=C(C#N)C#N)nc2-c2cc(F)cc(F)c2)o1 ; N#CC(C#N)=c1nc(-c2ccc(C(F)(F)F)c(F)c2)/c(=c2\oc(=C(C#N)C#N)nc2-c2ccc(C(F)(F)F)c(F)c2)o1 ; N#CC(C#N)=c1nc(-c2ccc(OC(F)(F)F)c(F)c2)/c(=c2\oc(=C(C#N)C#N)nc2-c2ccc(OC(F)(F)F)c(F)c2)o1 ; N#CC(C#N)=c1nc(-c2ccccc2C(F)(F)F)/c(=c2\oc(=C(C#N)C#N)nc2-c2ccccc2C(F)(F)F)o1]

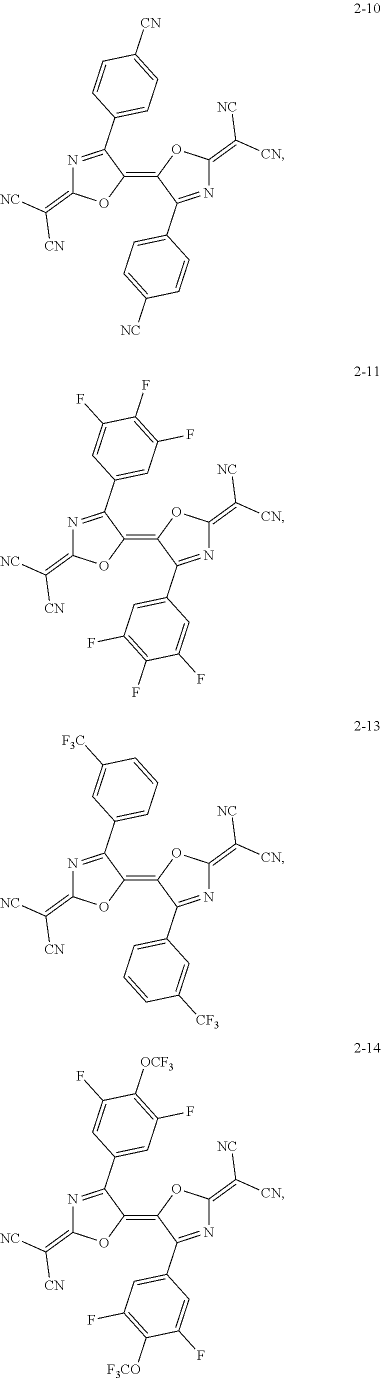 [SMILES: N#CC(C#N)=c1nc(-c2ccc(C#N)cc2)/c(=c2\oc(=C(C#N)C#N)nc2-c2ccc(C#N)cc2)o1 ; N#CC(C#N)=c1nc(-c2cc(F)c(F)c(F)c2)/c(=c2\oc(=C(C#N)C#N)nc2-c2cc(F)c(F)c(F)c2)o1 ; N#CC(C#N)=c1nc(-c2cccc(C(F)(F)F)c2)/c(=c2\oc(=C(C#N)C#N)nc2-c2cccc(C(F)(F)F)c2)o1 ; N#CC(C#N)=c1nc(-c2cc(F)c(OC(F)(F)F)c(F)c2)/c(=c2\oc(=C(C#N)C#N)nc2-c2cc(F)c(OC(F)(F)F)c(F)c2)o1]

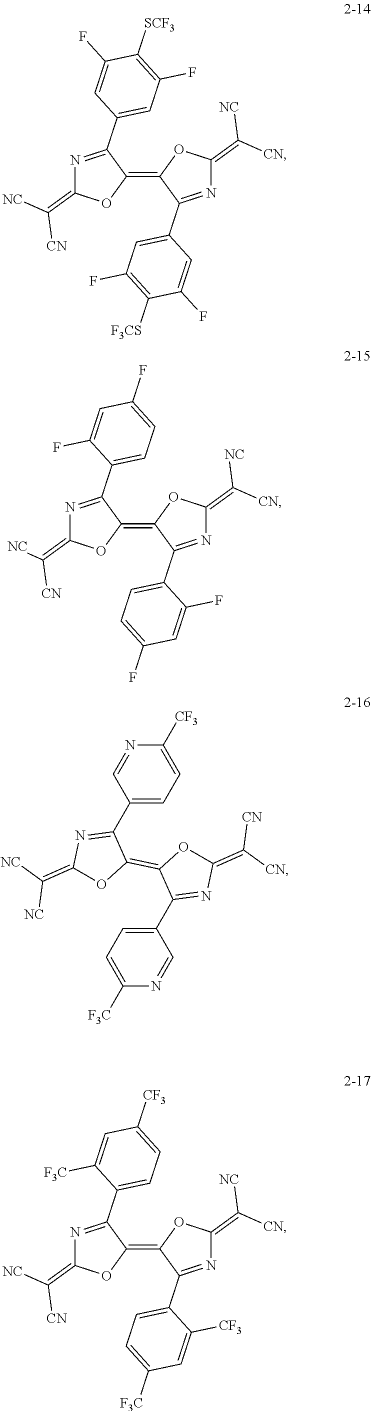

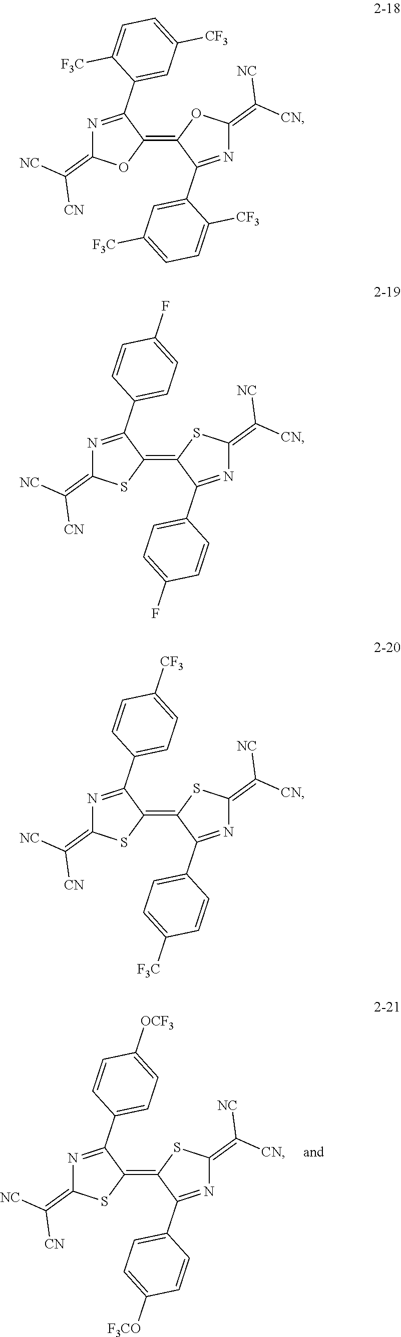

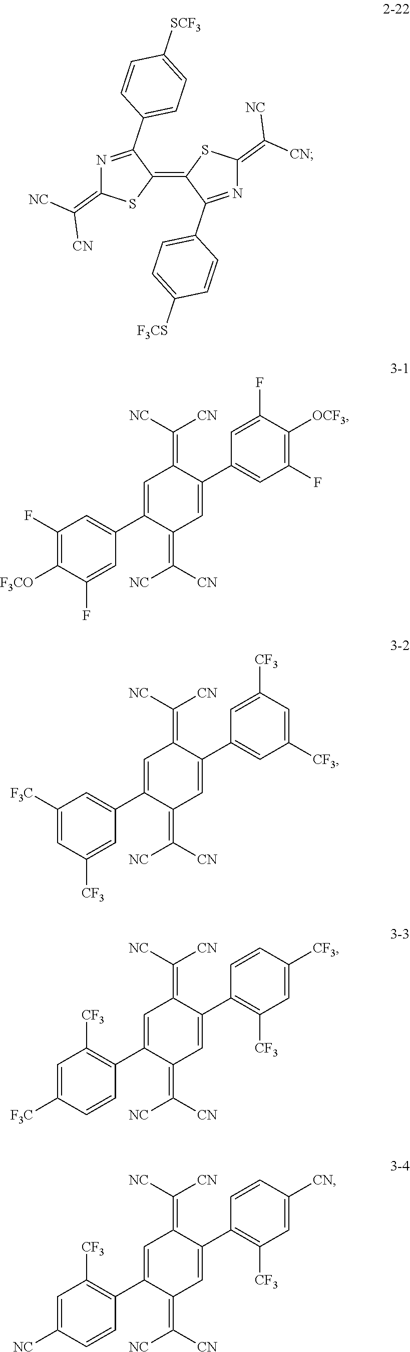

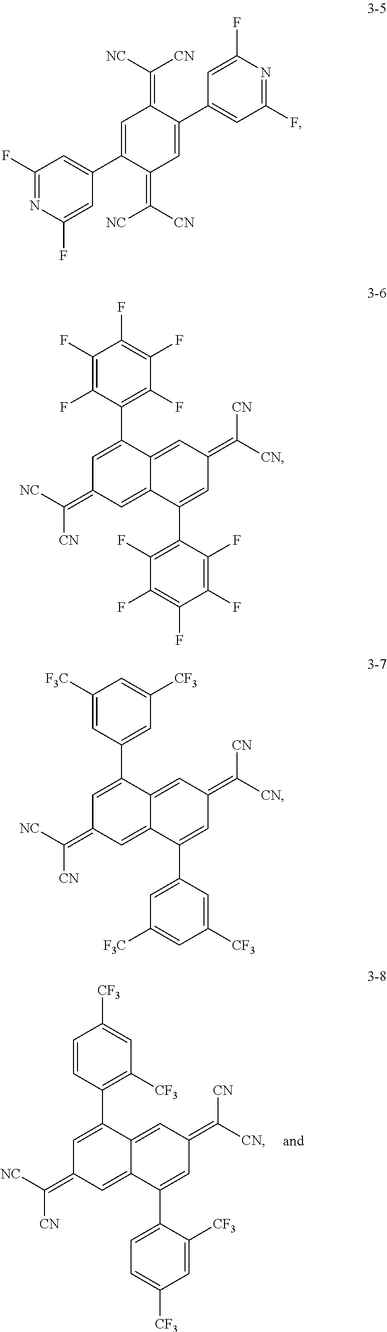

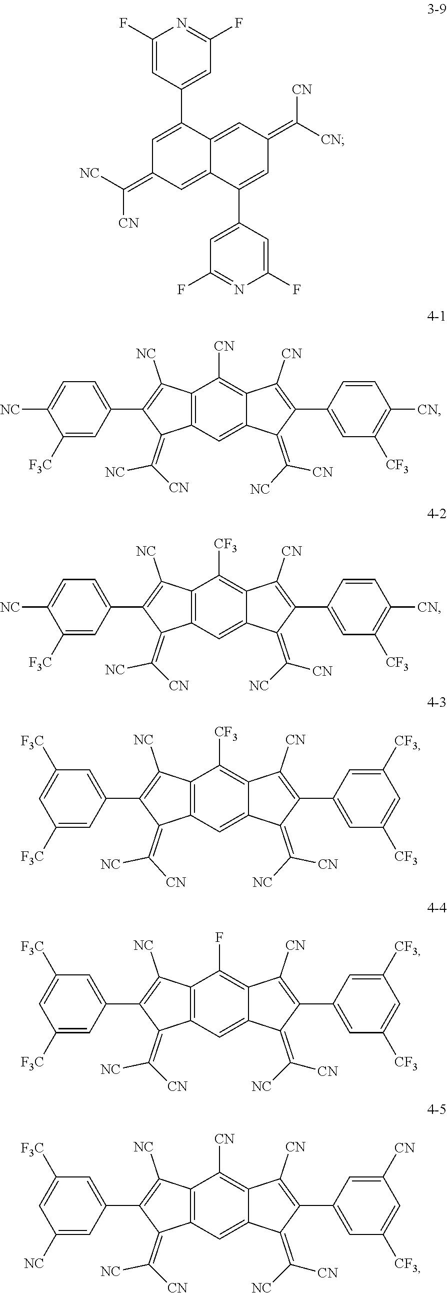

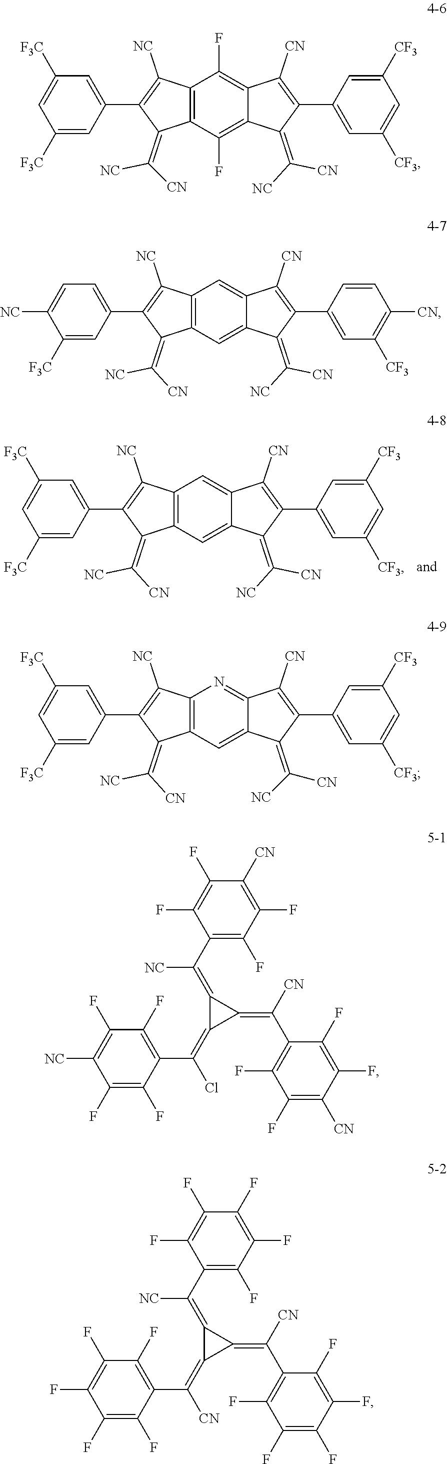

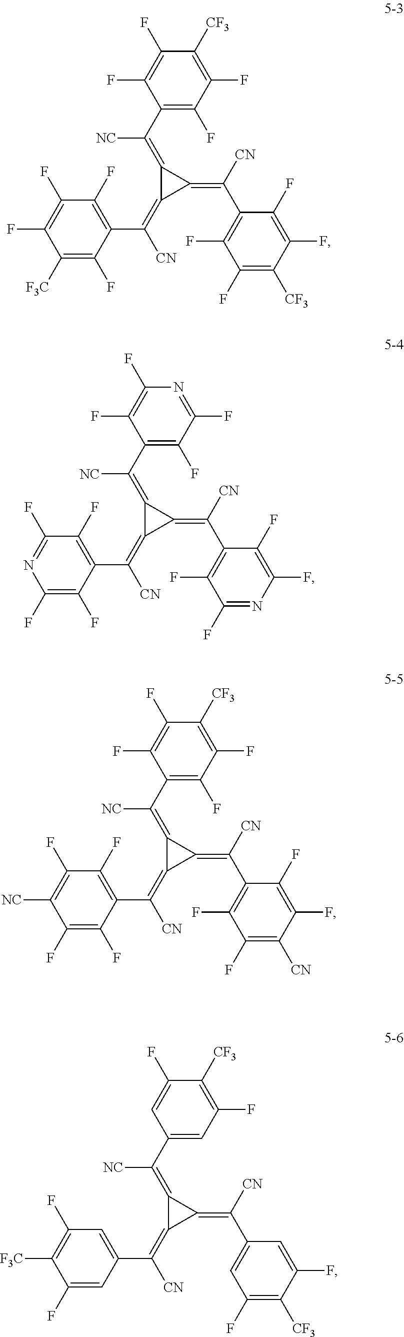 [SMILES: N#C/C(=C1/C(=C(\C#N)c2c(F)c(F)c(F)c(C(F)(F)F)c2F)/C1=C(\C#N)c1c(F)c(F)c(C(F)(F)F)c(F)c1F)c1c(F)c(F)c(C(F)(F)F)c(F)c1F ; N#CC(=C1C(=C(C#N)c2c(F)c(F)nc(F)c2F)C1=C(C#N)c1c(F)c(F)nc(F)c1F)c1c(F)c(F)nc(F)c1F ; N#C/C(=C1/C(=C(\C#N)c2c(F)c(F)c(C#N)c(F)c2F)/C1=C(\C#N)c1c(F)c(F)c(C(F)(F)F)c(F)c1F)c1c(F)c(F)c(C#N)c(F)c1F ; N#CC(=C1C(=C(C#N)c2cc(F)c(C(F)(F)F)c(F)c2)C1=C(C#N)c1cc(F)c(C(F)(F)F)c(F)c1)c1cc(F)c(C(F)(F)F)c(F)c1]

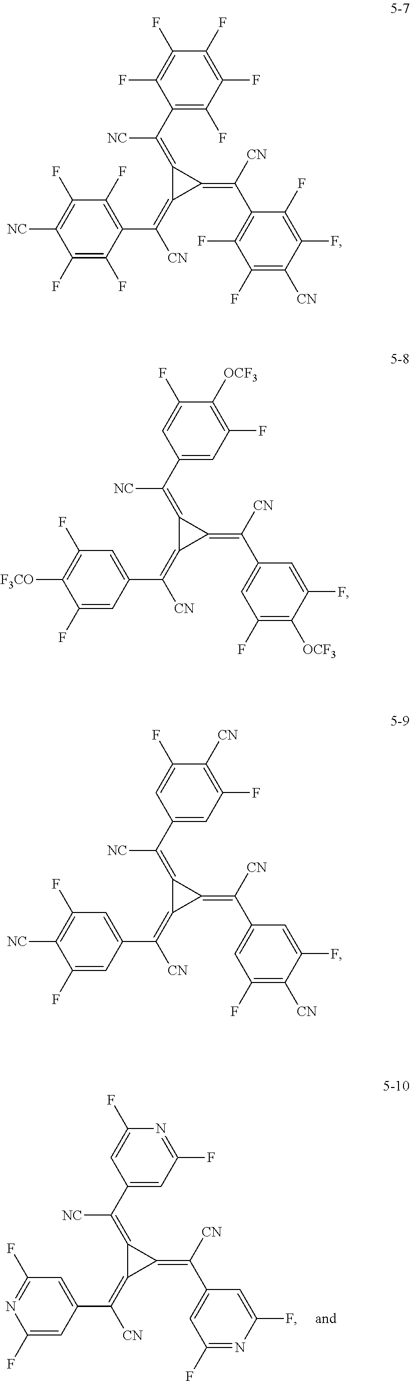 [SMILES: N#C/C(=C1\C(=C(\C#N)c2c(F)c(F)c(F)c(F)c2F)\C1=C(\C#N)c1c(F)c(F)c(C#N)c(F)c1F)c1c(F)c(F)c(C#N)c(F)c1F ; N#CC(=C1C(=C(C#N)c2cc(F)c(OC(F)(F)F)c(F)c2)C1=C(C#N)c1cc(F)c(OC(F)(F)F)c(F)c1)c1cc(F)c(OC(F)(F)F)c(F)c1 ; N#CC(=C1C(=C(C#N)c2cc(F)c(C#N)c(F)c2)C1=C(C#N)c1cc(F)c(C#N)c(F)c1)c1cc(F)c(C#N)c(F)c1 ; N#CC(=C1C(=C(C#N)c2cc(F)nc(F)c2)C1=C(C#N)c1cc(F)nc(F)c1)c1cc(F)nc(F)c1]

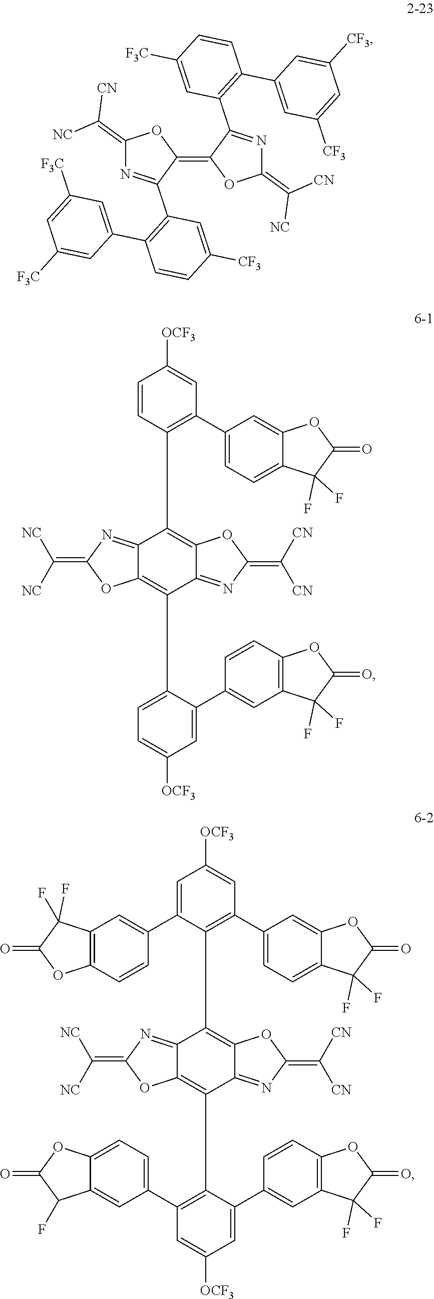 [SMILES: N#CC(C#N)=c1nc(-c2cc(C(F)(F)F)ccc2-c2cc(C(F)(F)F)cc(C(F)(F)F)c2)/c(=c2\oc(=C(C#N)C#N)nc2-c2cc(C(F)(F)F)ccc2-c2cc(C(F)(F)F)cc(C(F)(F)F)c2)o1 ; N#CC(C#N)=c1nc2c(-c3ccc(OC(F)(F)F)cc3-c3ccc4c(c3)C(F)(F)C(=O)O4)c3oc(=C(C#N)C#N)nc3c(-c3ccc(OC(F)(F)F)cc3-c3ccc4c(c3)OC(=O)C4(F)F)c2o1 ; N#CC(C#N)=c1nc2c(-c3c(-c4ccc5c(c4)C(F)C(=O)O5)cc(OC(F)(F)F)cc3-c3ccc4c(c3)C(F)(F)C(=O)O4)c3oc(=C(C#N)C#N)nc3c(-c3c(-c4ccc5c(c4)OC(=O)C5(F)F)cc(OC(F)(F)F)cc3-c3ccc4c(c3)C(F)(F)C(=O)O4)c2o1]

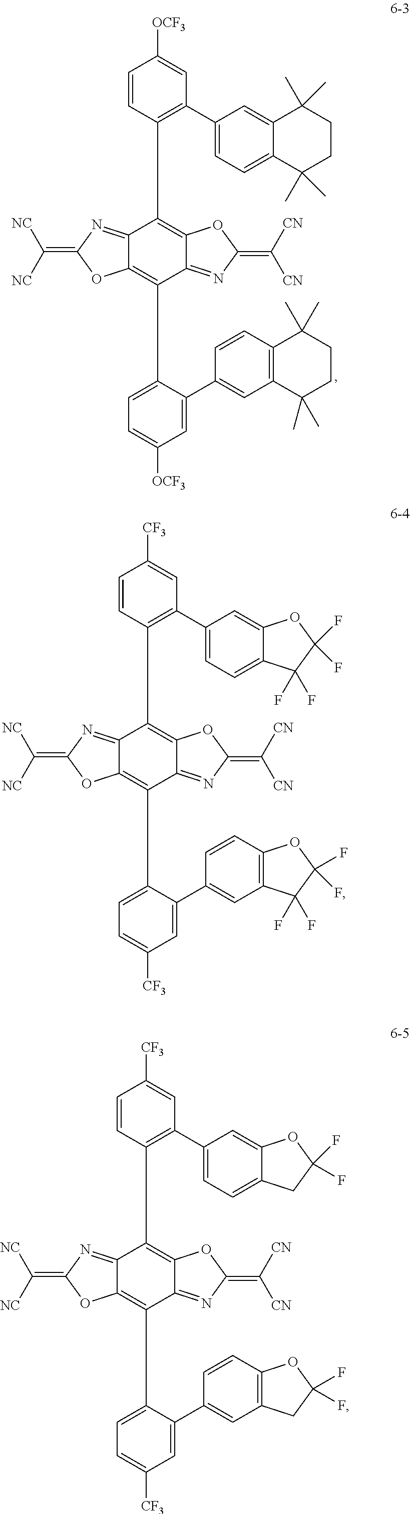 [SMILES: CC1(C)CCC(C)(C)c2cc(-c3cc(OC(F)(F)F)ccc3-c3c4nc(=C(C#N)C#N)oc4c(-c4ccc(OC(F)(F)F)cc4-c4ccc5c(c4)C(C)(C)CCC5(C)C)c4nc(=C(C#N)C#N)oc34)ccc21 ; N#CC(C#N)=c1nc2c(-c3ccc(C(F)(F)F)cc3-c3ccc4c(c3)C(F)(F)C(F)(F)O4)c3oc(=C(C#N)C#N)nc3c(-c3ccc(C(F)(F)F)cc3-c3ccc4c(c3)OC(F)(F)C4(F)F)c2o1 ; N#CC(C#N)=c1nc2c(-c3ccc(C(F)(F)F)cc3-c3ccc4c(c3)OC(F)(F)C4)c3oc(=C(C#N)C#N)nc3c(-c3ccc(C(F)(F)F)cc3-c3ccc4c(c3)CC(F)(F)O4)c2o1]

According to an embodiment of the present disclosure, hydrogens in the structures of Compound 1-1 to Compound 1-47, Compound 2-2 to Compound 2-22, Compound 3-1 to Compound 3-9, Compound 4-1 to Compound 4-9, and Compound 5-1 to Compound 5-11 can be partially or fully substituted with deuterium.

According to an embodiment of the present disclosure, the first organic material is selected from the group consisting of Compound 1-1 to Compound 1-47, Compound 2-2 to Compound 2-22, Compound 3-1 to Compound 3-9, Compound 4-1 to Compound 4-9, Compound 5-1 to Compound 5-11, Compound 2-23, and Compound 6-1 to Compound 6-47; Compound 2-23, Compound 6-1 to Compound 6-47 are as follows:

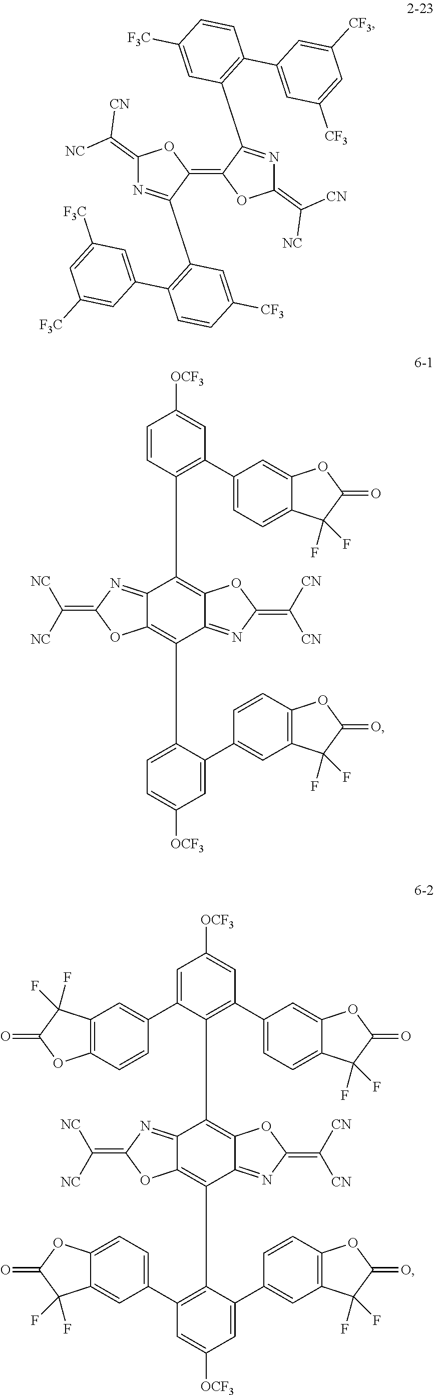 [SMILES: N#CC(C#N)=c1nc(Cc2cc(C(F)(F)F)ccc2-c2cc(C(F)(F)F)cc(C(F)(F)F)c2)/c(=c2\oc(=C(C#N)C#N)nc2Cc2cc(C(F)(F)F)ccc2-c2cc(C(F)(F)F)cc(C(F)(F)F)c2)o1 ; N#CC(C#N)=c1nc2c(CCc3ccc(OC(F)(F)F)cc3-c3ccc4c(c3)C(F)(F)C(=O)O4)c3oc(=C(C#N)C#N)nc3c(CCc3ccc(OC(F)(F)F)cc3-c3ccc4c(c3)OC(=O)C4(F)F)c2o1 ; N#CC(C#N)=c1nc2c(CCc3c(-c4ccc5c(c4)C(F)(F)C(=O)O5)cc(OC(F)(F)F)cc3-c3ccc4c(c3)C(F)(F)C(=O)O4)c3oc(=C(C#N)C#N)nc3c(CCc3c(-c4ccc5c(c4)OC(=O)C5(F)F)cc(OC(F)(F)F)cc3-c3ccc4c(c3)C(F)(F)C(=O)O4)c2o1]

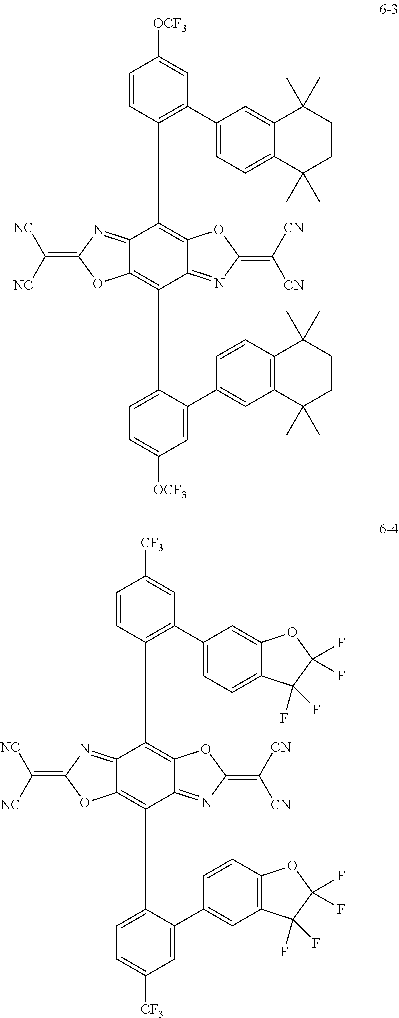 [SMILES: CC1(C)CCC(C)(C)c2cc(-c3cc(OC(F)(F)F)ccc3CCc3c4nc(=C(C#N)C#N)oc4c(CCc4ccc(OC(F)(F)F)cc4-c4ccc5c(c4)C(C)(C)CCC5(C)C)c4nc(=C(C#N)C#N)oc34)ccc21 ; N#CC(C#N)=c1nc2c(CCc3ccc(C(F)(F)F)cc3-c3ccc4c(c3)C(F)(F)C(F)(F)O4)c3oc(=C(C#N)C#N)nc3c(CCc3ccc(C(F)(F)F)cc3-c3ccc4c(c3)OC(F)(F)C4(F)F)c2o1]

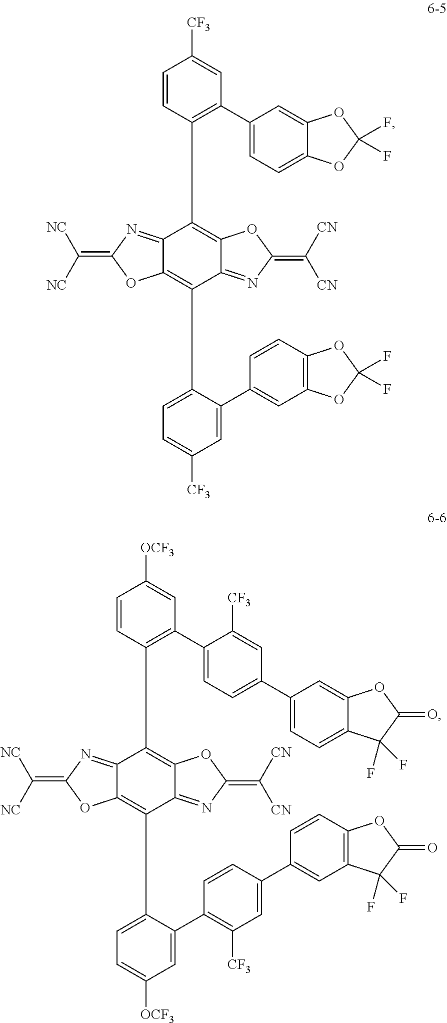 [SMILES: N#CC(C#N)=c1nc2c(CCc3ccc(C(F)(F)F)cc3-c3ccc4c(c3)OC(F)(F)O4)c3oc(=C(C#N)C#N)nc3c(CCc3ccc(C(F)(F)F)cc3-c3ccc4c(c3)OC(F)(F)O4)c2o1 ; N#CC(C#N)=c1nc2c(CCc3ccc(OC(F)(F)F)cc3-c3ccc(-c4ccc5c(c4)C(F)(F)C(=O)O5)cc3C(F)(F)F)c3oc(=C(C#N)C#N)nc3c(CCc3ccc(OC(F)(F)F)cc3-c3ccc(-c4ccc5c(c4)OC(=O)C5(F)F)cc3C(F)(F)F)c2o1]

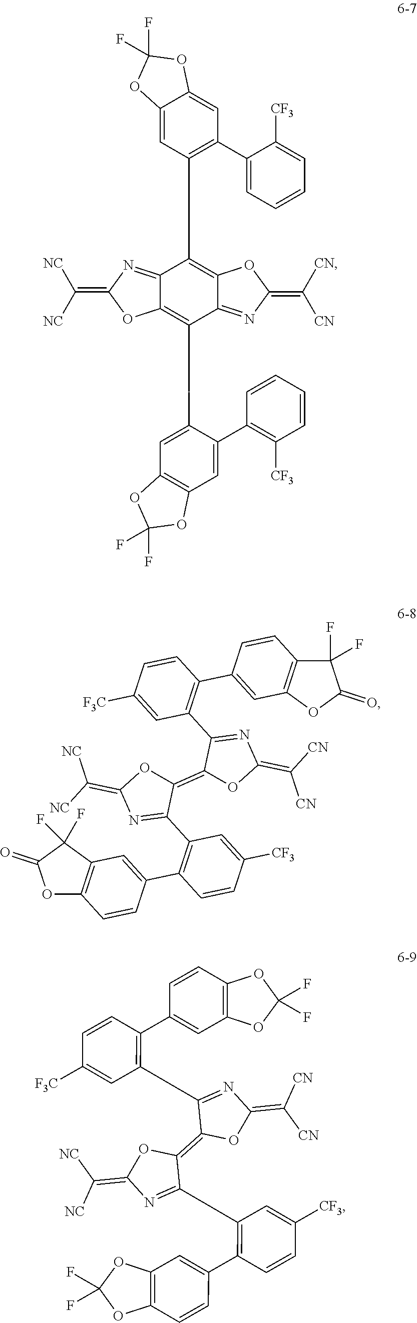 [SMILES: N#CC(C#N)=c1nc2c(CCc3cc4c(cc3-c3ccccc3C(F)(F)F)OC(F)(F)O4)c3oc(=C(C#N)C#N)nc3c(CCc3cc4c(cc3-c3ccccc3C(F)(F)F)OC(F)(F)O4)c2o1 ; N#CC(C#N)=c1nc(-c2cc(C(F)(F)F)ccc2-c2ccc3c(c2)OC(=O)C3(F)F)/c(=c2\oc(=C(C#N)C#N)nc2-c2cc(C(F)(F)F)ccc2-c2ccc3c(c2)C(F)(F)C(=O)O3)o1 ; N#CC(C#N)=c1nc(Cc2cc(C(F)(F)F)ccc2-c2ccc3c(c2)OC(F)(F)O3)/c(=c2\oc(=C(C#N)C#N)nc2Cc2cc(C(F)(F)F)ccc2-c2ccc3c(c2)OC(F)(F)O3)o1]

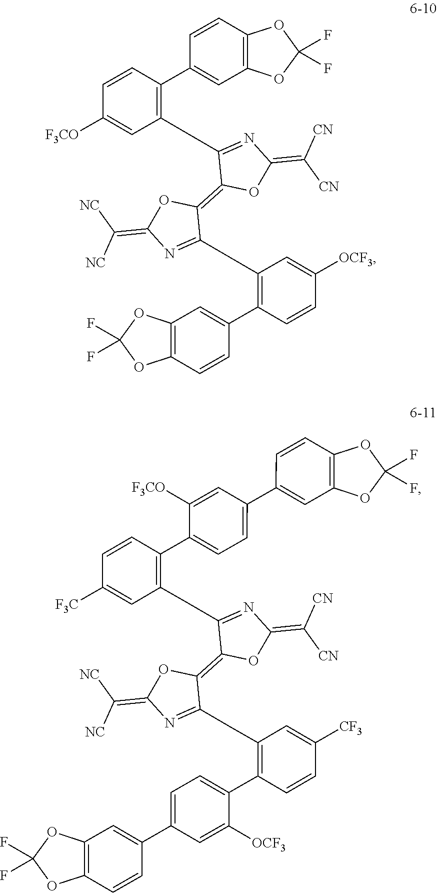 [SMILES: N#CC(C#N)=c1nc(Cc2cc(OC(F)(F)F)ccc2-c2ccc3c(c2)OC(F)(F)O3)/c(=c2\oc(=C(C#N)C#N)nc2Cc2cc(OC(F)(F)F)ccc2-c2ccc3c(c2)OC(F)(F)O3)o1 ; N#CC(C#N)=c1nc(Cc2cc(C(F)(F)F)ccc2-c2ccc(-c3ccc4c(c3)OC(F)(F)O4)cc2OC(F)(F)F)/c(=c2\oc(=C(C#N)C#N)nc2Cc2cc(C(F)(F)F)ccc2-c2ccc(-c3ccc4c(c3)OC(F)(F)O4)cc2OC(F)(F)F)o1]

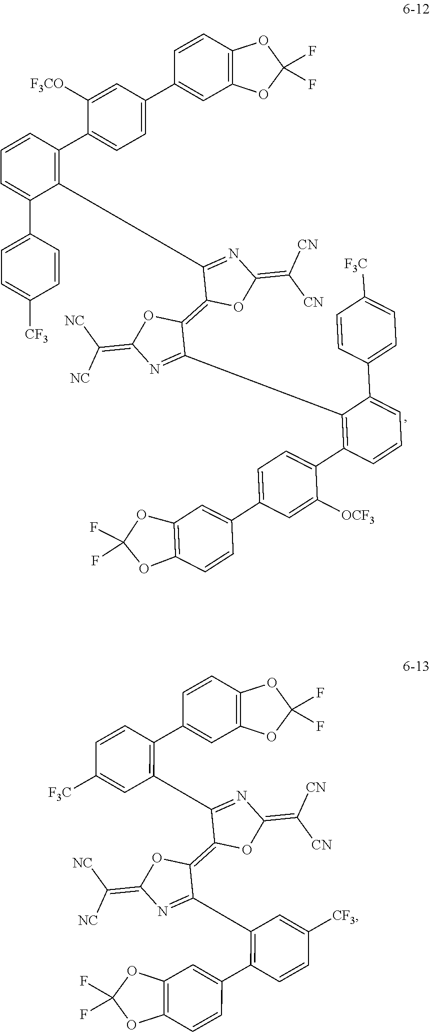 [SMILES: N#CC(C#N)=c1nc(CCCCc2c(-c3ccc(C(F)(F)F)cc3)cccc2-c2ccc(-c3ccc4c(c3)OC(F)(F)O4)cc2OC(F)(F)F)/c(=c2\oc(=C(C#N)C#N)nc2-c2c(-c3ccc(C(F)(F)F)cc3)cccc2-c2ccc(-c3ccc4c(c3)OC(F)(F)O4)cc2OC(F)(F)F)o1 ; N#CC(C#N)=c1nc(Cc2cc(C(F)(F)F)ccc2-c2ccc3c(c2)OC(F)(F)O3)/c(=c2\oc(=C(C#N)C#N)nc2Cc2cc(C(F)(F)F)ccc2-c2ccc3c(c2)OC(F)(F)O3)o1]

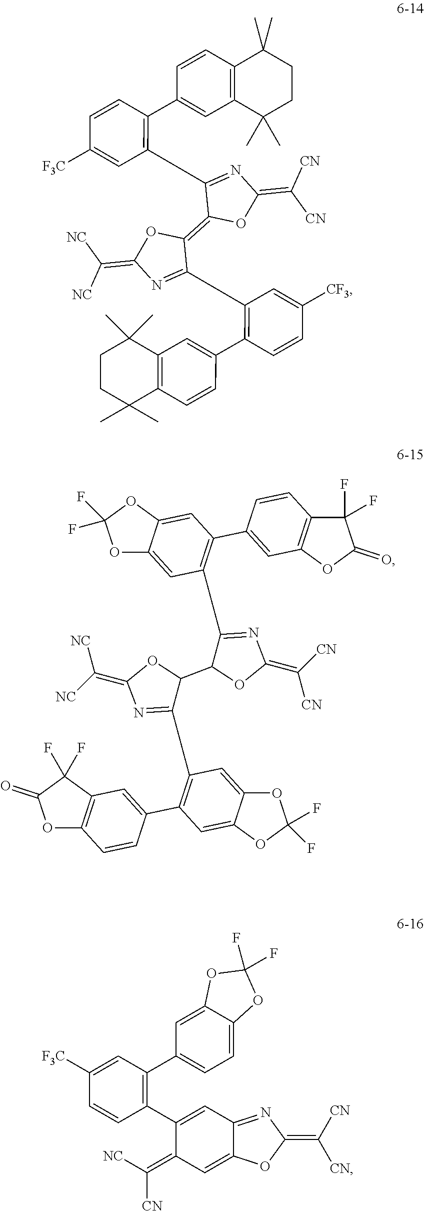 [SMILES: CC1(C)CCC(C)(C)c2cc(-c3ccc(C(F)(F)F)cc3Cc3nc(=C(C#N)C#N)o/c3=c3/oc(=C(C#N)C#N)nc3Cc3cc(C(F)(F)F)ccc3-c3ccc4c(c3)C(C)(C)CCC4(C)C)ccc21 ; N#CC(C#N)=C1N=C(Cc2cc3c(cc2-c2ccc4c(c2)OC(=O)C4(F)F)OC(F)(F)O3)C(C2OC(=C(C#N)C#N)N=C2Cc2cc3c(cc2-c2ccc4c(c2)C(F)(F)C(=O)O4)OC(F)(F)O3)O1 ; N#CC(C#N)=c1nc2cc(-c3ccc(C(F)(F)F)cc3-c3ccc4c(c3)OC(F)(F)O4)c(=C(C#N)C#N)cc2o1]

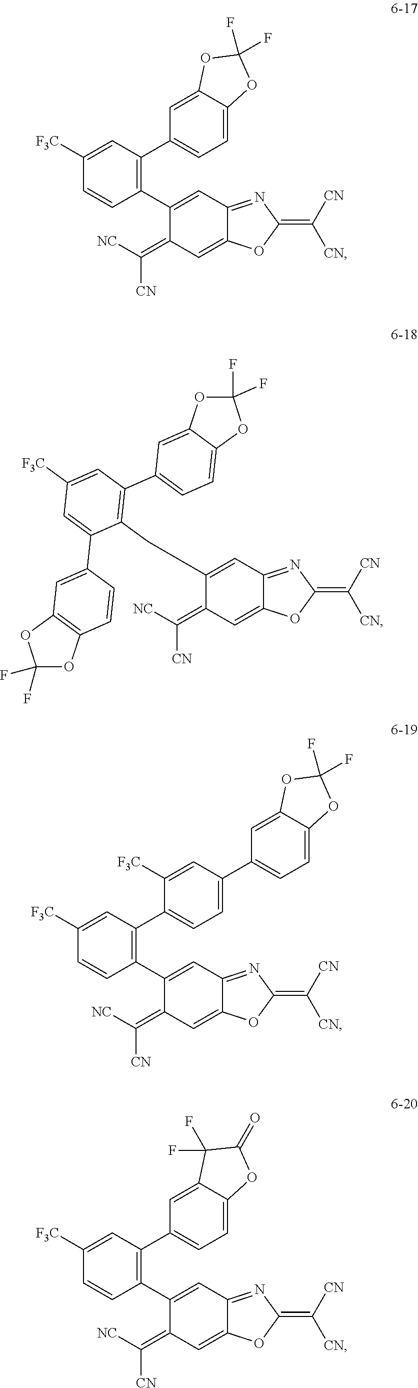 [SMILES: N#CC(C#N)=c1nc2cc(-c3ccc(C(F)(F)F)cc3-c3ccc4c(c3)OC(F)(F)O4)c(=C(C#N)C#N)cc2o1 ; N#CC(C#N)=c1nc2cc(CCc3c(-c4ccc5c(c4)OC(F)(F)O5)cc(C(F)(F)F)cc3-c3ccc4c(c3)OC(F)(F)O4)c(=C(C#N)C#N)cc2o1 ; N#CC(C#N)=c1nc2cc(-c3ccc(C(F)(F)F)cc3-c3ccc(-c4ccc5c(c4)OC(F)(F)O5)cc3C(F)(F)F)c(=C(C#N)C#N)cc2o1 ; N#CC(C#N)=c1nc2cc(-c3ccc(C(F)(F)F)cc3-c3ccc4c(c3)C(F)(F)C(=O)O4)c(=C(C#N)C#N)cc2o1]

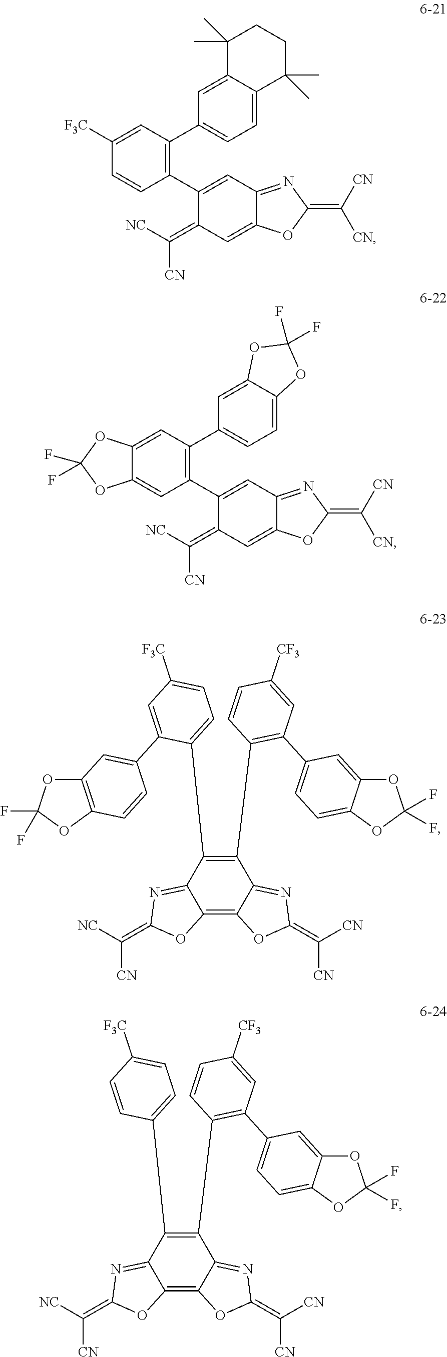 [SMILES: CC1(C)CCC(C)(C)c2cc(-c3cc(C(F)(F)F)ccc3-c3cc4nc(=C(C#N)C#N)oc4cc3=C(C#N)C#N)ccc21 ; N#CC(C#N)=c1nc2cc(-c3cc4c(cc3-c3ccc5c(c3)OC(F)(F)O5)OC(F)(F)O4)c(=C(C#N)C#N)cc2o1 ; N#CC(C#N)=c1nc2c(-c3ccc(C(F)(F)F)cc3-c3ccc4c(c3)OC(F)(F)O4)c(-c3ccc(C(F)(F)F)cc3-c3ccc4c(c3)OC(F)(F)O4)c3nc(=C(C#N)C#N)oc3c2o1 ; N#CC(C#N)=c1nc2c(-c3ccc(C(F)(F)F)cc3)c(-c3ccc(C(F)(F)F)cc3-c3ccc4c(c3)OC(F)(F)O4)c3nc(=C(C#N)C#N)oc3c2o1]

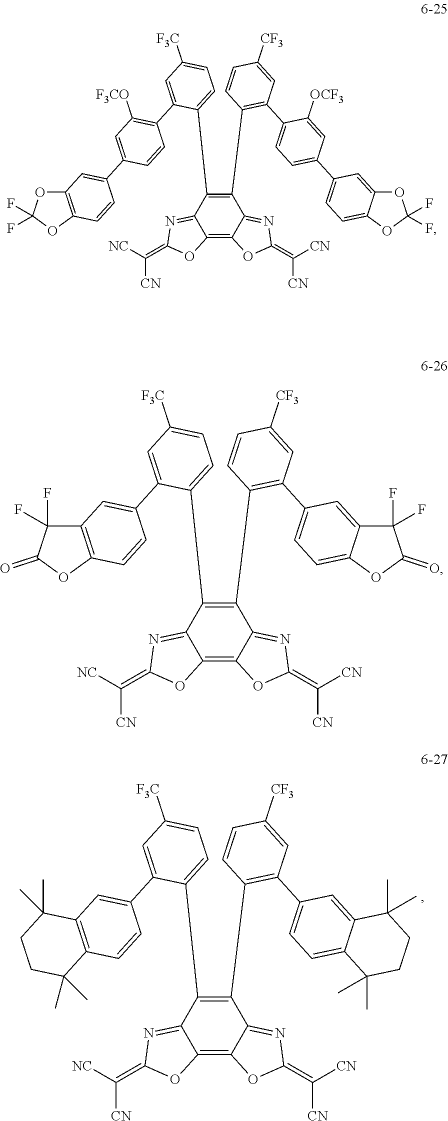

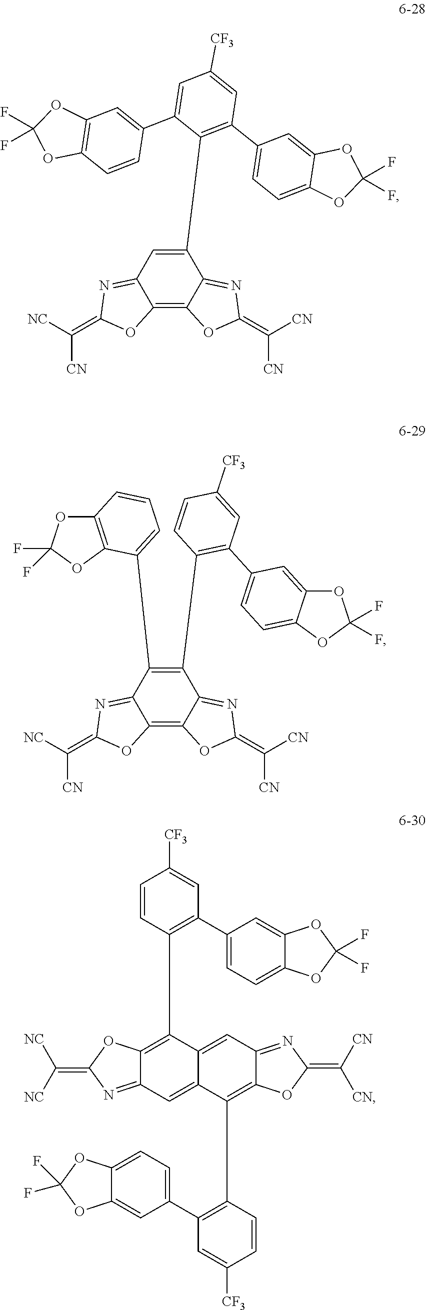 [SMILES: N#CC(C#N)=c1nc2cc(-c3c(-c4ccc5c(c4)OC(F)(F)O5)cc(C(F)(F)F)cc3-c3ccc4c(c3)OC(F)(F)O4)c3nc(=C(C#N)C#N)oc3c2o1 ; N#CC(C#N)=c1nc2c(-c3ccc(C(F)(F)F)cc3-c3ccc4c(c3)OC(F)(F)O4)c(-c3cccc4c3OC(F)(F)O4)c3nc(=C(C#N)C#N)oc3c2o1 ; N#CC(C#N)=c1nc2cc3c(CCc4ccc(C(F)(F)F)cc4-c4ccc5c(c4)OC(F)(F)O5)c4oc(=C(C#N)C#N)nc4cc3c(CCc3ccc(C(F)(F)F)cc3-c3ccc4c(c3)OC(F)(F)O4)c2o1]

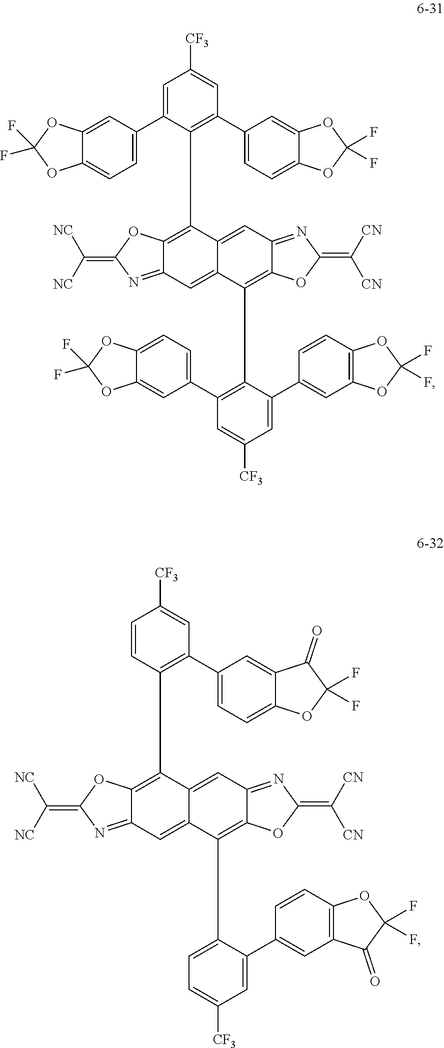 [SMILES: N#CC(C#N)=c1nc2cc3c(CCc4c(-c5ccc6c(c5)OC(F)(F)O6)cc(C(F)(F)F)cc4-c4ccc5c(c4)OC(F)(F)O5)c4oc(=C(C#N)C#N)nc4cc3c(CCc3c(-c4ccc5c(c4)OC(F)(F)O5)cc(C(F)(F)F)cc3-c3ccc4c(c3)OC(F)(F)O4)c2o1 ; N#CC(C#N)=c1nc2cc3c(CCc4ccc(C(F)(F)F)cc4-c4ccc5c(c4)C(=O)C(F)(F)O5)c4oc(=C(C#N)C#N)nc4cc3c(CCc3ccc(C(F)(F)F)cc3-c3ccc4c(c3)C(=O)C(F)(F)O4)c2o1]

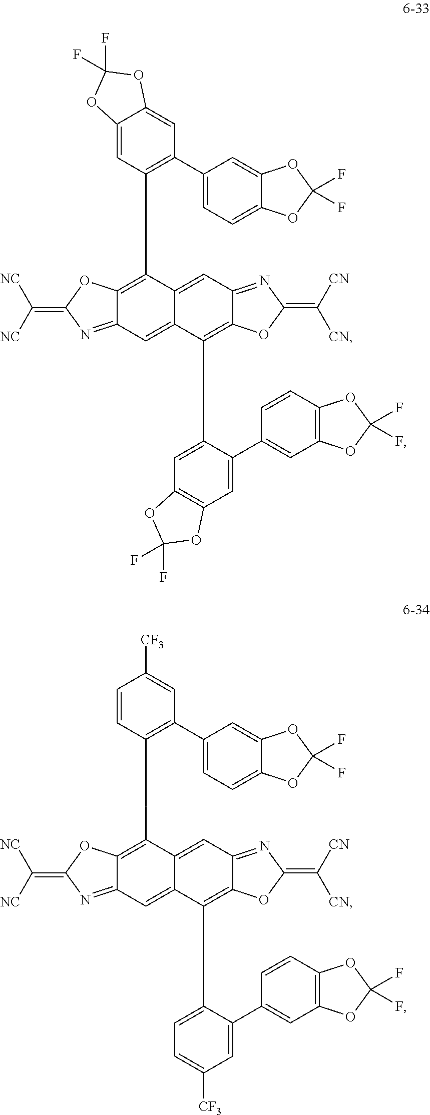 [SMILES: N#CC(C#N)=c1nc2cc3c(CCc4cc5c(cc4-c4ccc6c(c4)OC(F)(F)O6)OC(F)(F)O5)c4oc(=C(C#N)C#N)nc4cc3c(CCc3cc4c(cc3-c3ccc5c(c3)OC(F)(F)O5)OC(F)(F)O4)c2o1 ; N#CC(C#N)=c1nc2cc3c(CCc4ccc(C(F)(F)F)cc4-c4ccc5c(c4)OC(F)(F)O5)c4oc(=C(C#N)C#N)nc4cc3c(CCc3ccc(C(F)(F)F)cc3-c3ccc4c(c3)OC(F)(F)O4)c2o1]

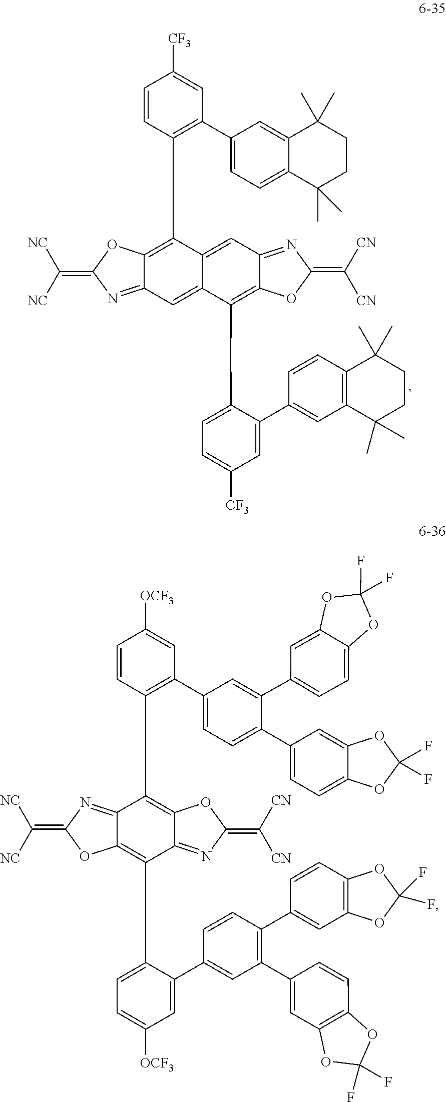 [SMILES: CC1(C)CCC(C)(C)c2cc(-c3cc(C(F)(F)F)ccc3CCc3c4cc5nc(=C(C#N)C#N)oc5c(CCc5ccc(C(F)(F)F)cc5-c5ccc6c(c5)C(C)(C)CCC6(C)C)c4cc4nc(=C(C#N)C#N)oc34)ccc21 ; N#CC(C#N)=c1nc2c(CCc3ccc(OC(F)(F)F)cc3-c3ccc(-c4ccc5c(c4)OC(F)(F)O5)c(-c4ccc5c(c4)OC(F)(F)O5)c3)c3oc(=C(C#N)C#N)nc3c(CCc3ccc(OC(F)(F)F)cc3-c3ccc(-c4ccc5c(c4)OC(F)(F)O5)c(-c4ccc5c(c4)OC(F)(F)O5)c3)c2o1]

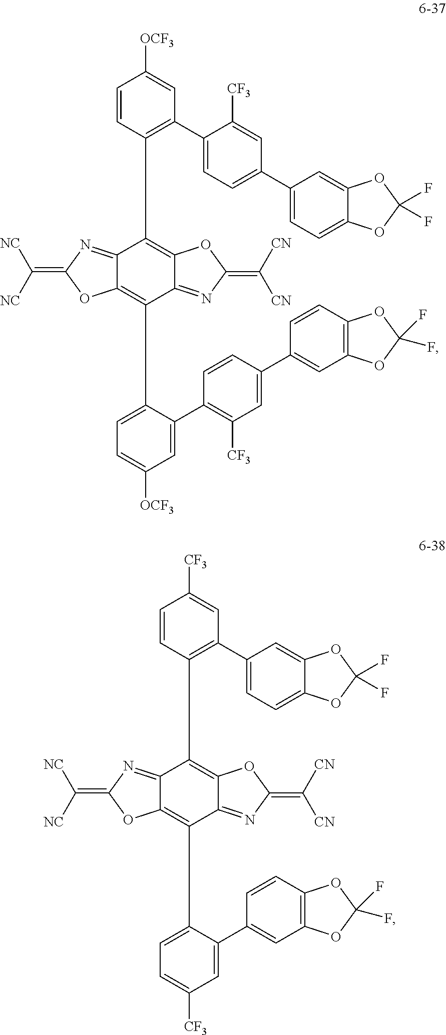 [SMILES: N#CC(C#N)=c1nc2c(CCc3ccc(OC(F)(F)F)cc3-c3ccc(-c4ccc5c(c4)OC(F)(F)O5)cc3C(F)(F)F)c3oc(=C(C#N)C#N)nc3c(CCc3ccc(OC(F)(F)F)cc3-c3ccc(-c4ccc5c(c4)OC(F)(F)O5)cc3C(F)(F)F)c2o1 ; N#CC(C#N)=c1nc2c(CCc3ccc(C(F)(F)F)cc3-c3ccc4c(c3)OC(F)(F)O4)c3oc(=C(C#N)C#N)nc3c(CCc3ccc(C(F)(F)F)cc3-c3ccc4c(c3)OC(F)(F)O4)c2o1]

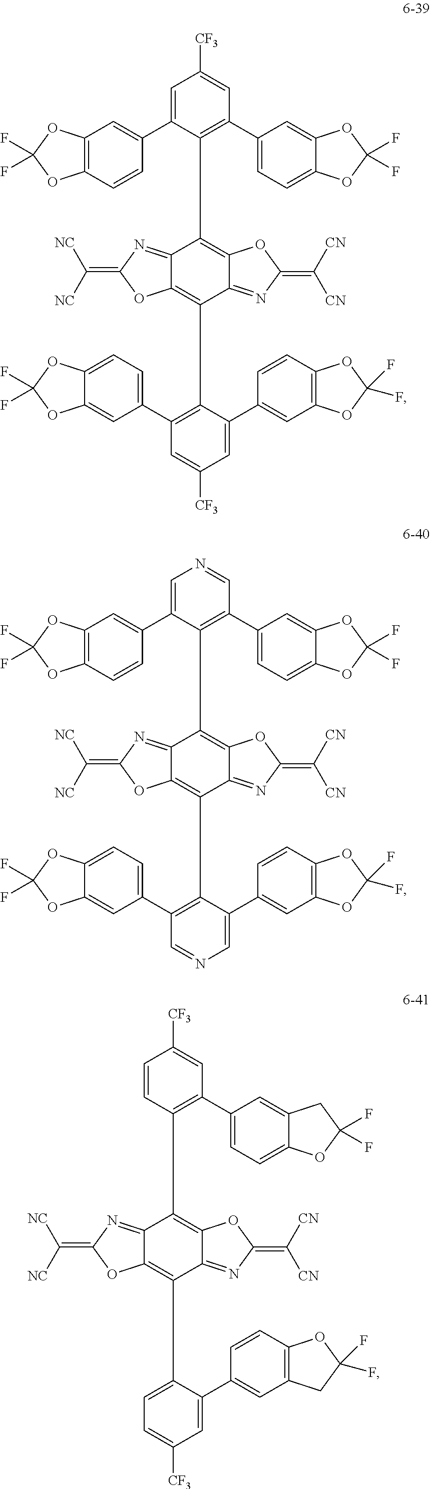 [SMILES: N#CC(C#N)=c1nc2c(CCc3c(-c4ccc5c(c4)OC(F)(F)O5)cc(C(F)(F)F)cc3-c3ccc4c(c3)OC(F)(F)O4)c3oc(=C(C#N)C#N)nc3c(CCc3c(-c4ccc5c(c4)OC(F)(F)O5)cc(C(F)(F)F)cc3-c3ccc4c(c3)OC(F)(F)O4)c2o1 ; N#CC(C#N)=c1nc2c(CCc3c(-c4ccc5c(c4)OC(F)(F)O5)cncc3-c3ccc4c(c3)OC(F)(F)O4)c3oc(=C(C#N)C#N)nc3c(CCc3c(-c4ccc5c(c4)OC(F)(F)O5)cncc3-c3ccc4c(c3)OC(F)(F)O4)c2o1 ; N#CC(C#N)=c1nc2c(CCc3ccc(C(F)(F)F)cc3-c3ccc4c(c3)CC(F)(F)O4)c3oc(=C(C#N)C#N)nc3c(CCc3ccc(C(F)(F)F)cc3-c3ccc4c(c3)CC(F)(F)O4)c2o1]

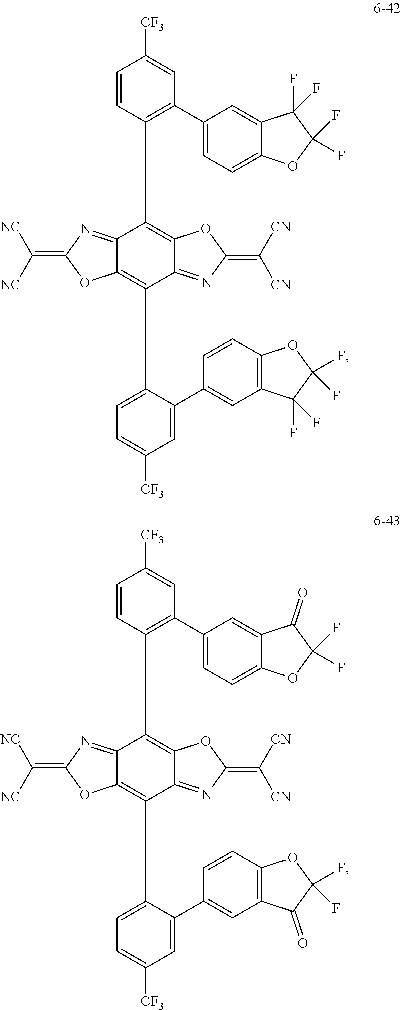

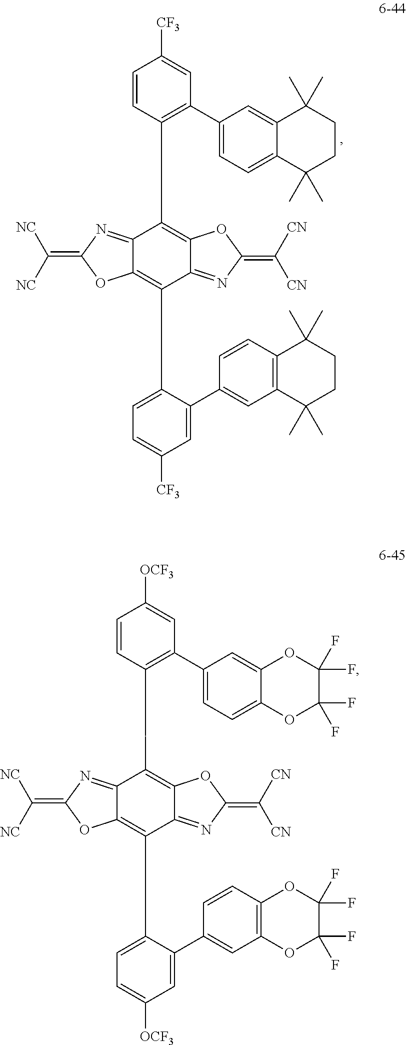 [SMILES: CC1(C)CCC(C)(C)c2cc(-c3cc(C(F)(F)F)ccc3CCc3c4nc(=C(C#N)C#N)oc4c(CCc4ccc(C(F)(F)F)cc4-c4ccc5c(c4)C(C)(C)CCC5(C)C)c4nc(=C(C#N)C#N)oc34)ccc21 ; N#CC(C#N)=c1nc2c(CCc3ccc(OC(F)(F)F)cc3-c3ccc4c(c3)OC(F)(F)C(F)(F)O4)c3oc(=C(C#N)C#N)nc3c(CCc3ccc(OC(F)(F)F)cc3-c3ccc4c(c3)OC(F)(F)C(F)(F)O4)c2o1]

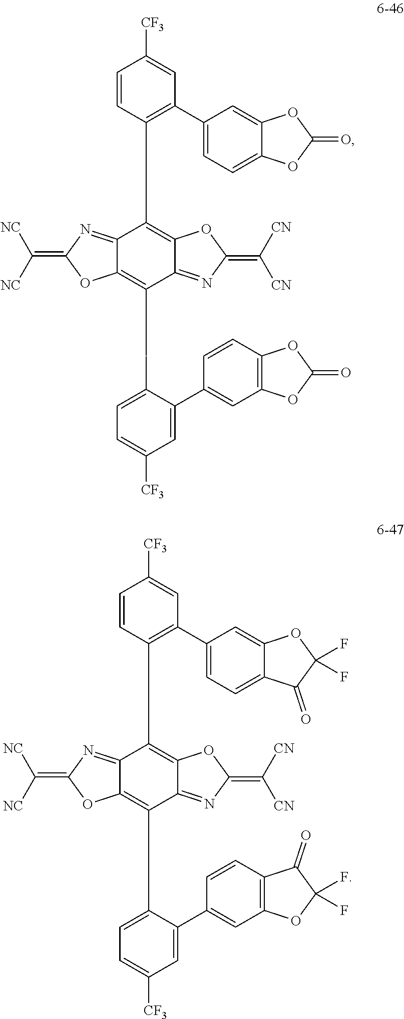 [SMILES: N#CC(C#N)=c1nc2c(CCc3ccc(C(F)(F)F)cc3-c3ccc4oc(=O)oc4c3)c3oc(=C(C#N)C#N)nc3c(CCc3ccc(C(F)(F)F)cc3-c3ccc4oc(=O)oc4c3)c2o1 ; N#CC(C#N)=c1nc2c(CCc3ccc(C(F)(F)F)cc3-c3ccc4c(c3)OC(F)(F)C4=O)c3oc(=C(C#N)C#N)nc3c(CCc3ccc(C(F)(F)F)cc3-c3ccc4c(c3)OC(F)(F)C4=O)c2o1]

According to an embodiment of the present disclosure, hydrogen in the structures of Compound 2-23, Compound 6-1 to Compound 6-47 can be partially or fully substituted with deuterium.

According to an embodiment of the present disclosure, the second organic material is selected from the group consisting of the following compounds: a compound having a triarylamine unit, a spirobifluorene compound, a pentacene compound, an oligothiophene compound, an oligophenyl compound, an oligophenylenevinylene compound, an oligofluorene compound, a porphyrin complex or a metallic phthalocyanine complex.

According to an embodiment of the present disclosure, the second organic material comprises one or more chemical structural units selected from the group consisting of: triarylamine, carbazole, fluorene, spirobifluorene, thiophene, furan, phenyl, oligophenylenevinylene, oligofluorene, and combinations thereof.

According to an embodiment of the present disclosure, the second organic material comprises a monotriarylamine structural unit or a bistriarylamine structural unit.

According to an embodiment of the present disclosure, the second organic material comprises any one or more chemical structural units selected from the group consisting of: a monotriarylamine-carbazole structural unit, a monotriarylamine-thiophene structural unit, a monotriarylamine-furan structural unit, a monotriarylamine-fluorene structural unit, a bistriarylamine-carbazole structural unit, a bistriarylamine-thiophene structural unit, a bistriarylamine-furan structural unit, and a bistriarylamine-fluorene structural unit.

According to an embodiment of the present disclosure, the second organic material is a monotriarylamine compound or a bistriarylamine compound.

According to an embodiment of the present disclosure, the second organic material is selected from a monotriarylamine-carbazole compound, a monotriarylamine-thiophene compound, a monotriarylamine-furan compound, a monotriarylamine-fluorene compound, a bistriarylamine-carbazole compound, a bistriarylamine-thiophene compound, a bistriarylamine-furan compound or a bistriarylamine-fluorene compound.

According to an embodiment of the present disclosure, the second organic material has a structure represented by Formula 2 or Formula 3:

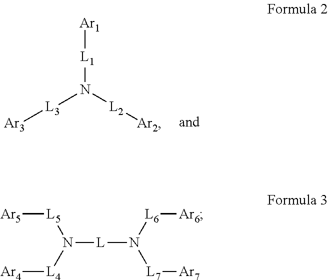

wherein Ar₁ to Ar₇ are, at each occurrence identically or differently, selected from substituted or unsubstituted aryl having 6 to 30 carbon atoms, substituted or unsubstituted heteroaryl having 3 to 30 carbon atoms or a combination thereof;
L is selected from substituted or unsubstituted arylene having 6 to 30 carbon atoms, substituted or unsubstituted heteroarylene having 3 to 30 carbon atoms or a combination thereof;
L₁ to L₇ are, at each occurrence identically or differently, selected from a single bond, substituted or unsubstituted arylene having 6 to 30 carbon atoms, substituted or unsubstituted heteroarylene having 3 to 30 carbon atoms or a combination thereof.

According to an embodiment of the present disclosure, Formula 2 represents a monoamine compound comprising only one amino N atom shown.

According to an embodiment of the present disclosure, Ar₁ to Ar₇ are, at each occurrence identically or differently, selected from substituted or unsubstituted phenyl, substituted or unsubstituted biphenyl, substituted or unsubstituted terphenyl, substituted or unsubstituted naphthyl, substituted or unsubstituted dibenzofuryl, substituted or unsubstituted dibenzothienyl, substituted or unsubstituted dibenzoselenophenyl, substituted or unsubstituted carbazolyl, substituted or unsubstituted phenanthryl, substituted or unsubstituted triphenylenyl, substituted or unsubstituted pyridyl, substituted or unsubstituted anthryl, substituted or unsubstituted pyrenyl, substituted or unsubstituted fluorenyl or a combination thereof.

According to an embodiment of the present disclosure, L is selected from substituted or unsubstituted phenylene, substituted or unsubstituted biphenylylene, substituted or unsubstituted terphenylene, substituted or unsubstituted naphthylene, substituted or unsubstituted dibenzofurylene, substituted or unsubstituted dibenzothienylene, substituted or unsubstituted dibenzoselenophenylene, substituted or unsubstituted carbazolylene, substituted or unsubstituted phenanthrylene, substituted or unsubstituted triphenylenylene, substituted or unsubstituted pyridylene, substituted or unsubstituted anthrylene, substituted or unsubstituted pyrenylene, substituted or unsubstituted fluorenylene or a combination thereof.

According to an embodiment of the present disclosure, L₁ to L₇ are, at each occurrence identically or differently, selected from a single bond, substituted or unsubstituted phenylene, substituted or unsubstituted biphenylylene, substituted or unsubstituted terphenylene, substituted or unsubstituted naphthylene, substituted or unsubstituted dibenzofurylene, substituted or unsubstituted dibenzothienylene, substituted or unsubstituted dibenzoselenophenylene, substituted or unsubstituted carbazolylene, substituted or unsubstituted phenanthrylene, substituted or unsubstituted triphenylenylene, substituted or unsubstituted pyridylene, substituted or unsubstituted anthrylene, substituted or unsubstituted pyrenylene, substituted or unsubstituted fluorenylene or a combination thereof.

According to an embodiment of the present disclosure, the second organic material has a structure represented by Formula 2-1:

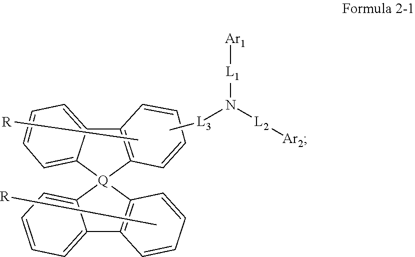

wherein Q is selected from C, Si or Ge;
Ar₁ and Ar₂ are, at each occurrence identically or differently, selected from substituted or unsubstituted aryl having 6 to 30 carbon atoms, substituted or unsubstituted heteroaryl having 3 to 30 carbon atoms or a combination thereof;
L₁ and L₂ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
R represents, at each occurrence identically or differently, mono-substitution, multiple substitutions or non-substitution;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R can be optionally joined to form a ring.

According to an embodiment of the present disclosure, the second organic material is selected from the group consisting of Compound HT-1 to Compound HT-60:

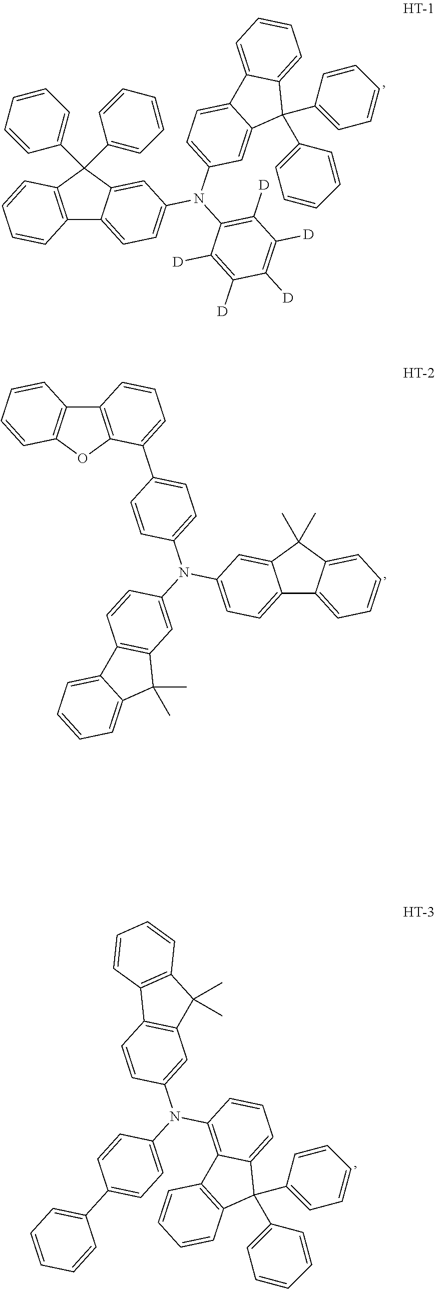 [SMILES: [2H]c1c([2H])c([2H])c(N(c2ccc3c(c2)C(c2ccccc2)(c2ccccc2)c2ccccc2-3)c2ccc3c(c2)C(c2ccccc2)(c2ccccc2)c2ccccc2-3)c([2H])c1[2H] ; CC1(C)c2ccccc2-c2ccc(N(c3ccc(-c4cccc5c4oc4ccccc45)cc3)c3ccc4c(c3)C(C)(C)c3ccccc3-4)cc21 ; CC1(C)c2ccccc2-c2ccc(N(c3ccc(-c4ccccc4)cc3)c3cccc4c3-c3ccccc3C4(c3ccccc3)c3ccccc3)cc21]

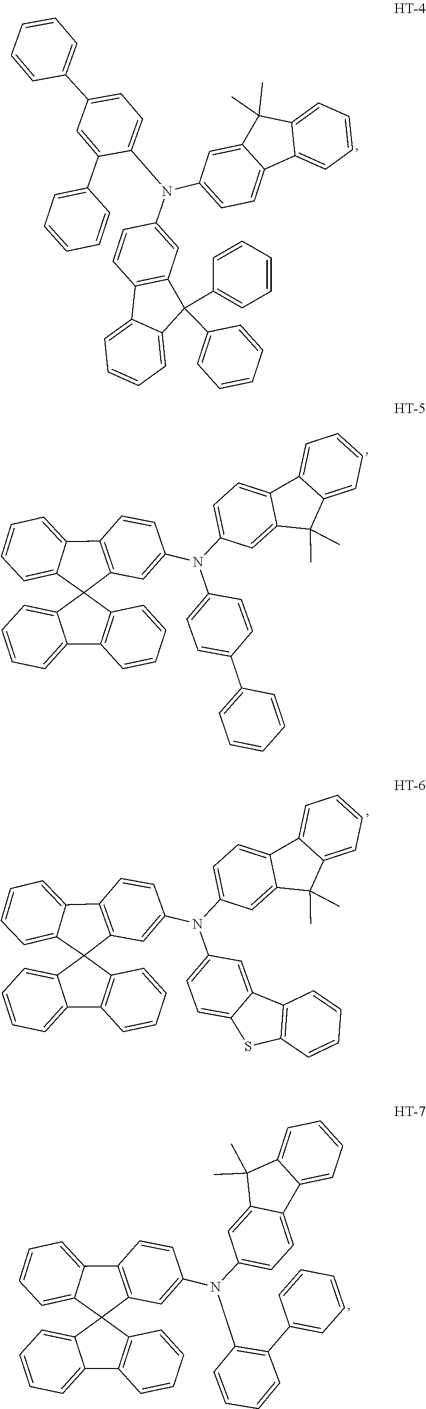 [SMILES: CC1(C)c2ccccc2-c2ccc(N(c3ccc4c(c3)C(c3ccccc3)(c3ccccc3)c3ccccc3-4)c3ccc(-c4ccccc4)cc3-c3ccccc3)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3ccc4c(c3)C3(c5ccccc5-c5ccccc53)c3ccccc3-4)c3ccc4sc5ccccc5c4c3)cc21 ; CC1(C)c2ccccc2-c2ccc(N(c3ccc4c(c3)C3(c5ccccc5-c5ccccc53)c3ccccc3-4)c3ccccc3-c3ccccc3)cc21]

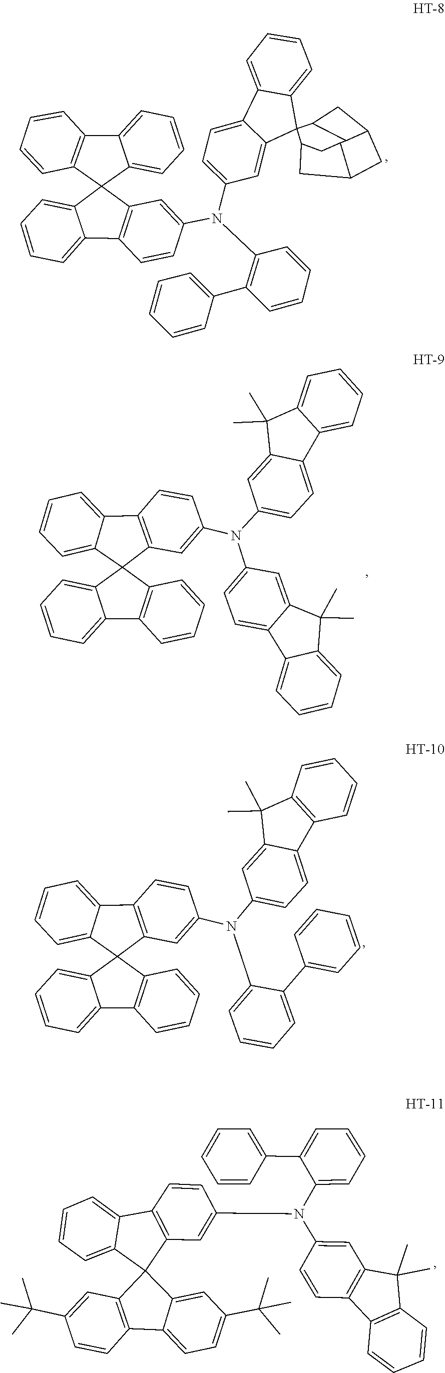 [SMILES: CC12CC3CC1CC1CC(C12)C31c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3ccc4c(c3)C(C)(C)c3ccccc3-4)c3ccc4c(c3)C3(c5ccccc5-c5ccccc53)c3ccccc3-4)cc21 ; CC1(C)c2ccccc2-c2ccc(N(c3ccc4c(c3)C3(c5ccccc5-c5ccccc53)c3ccccc3-4)c3ccccc3-c3ccccc3)cc21 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

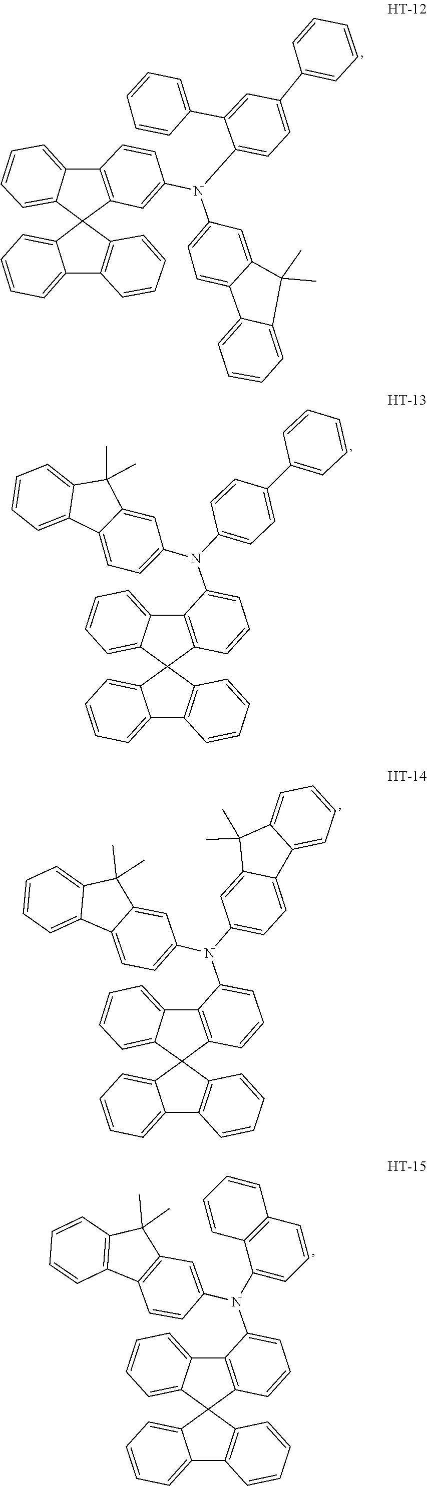

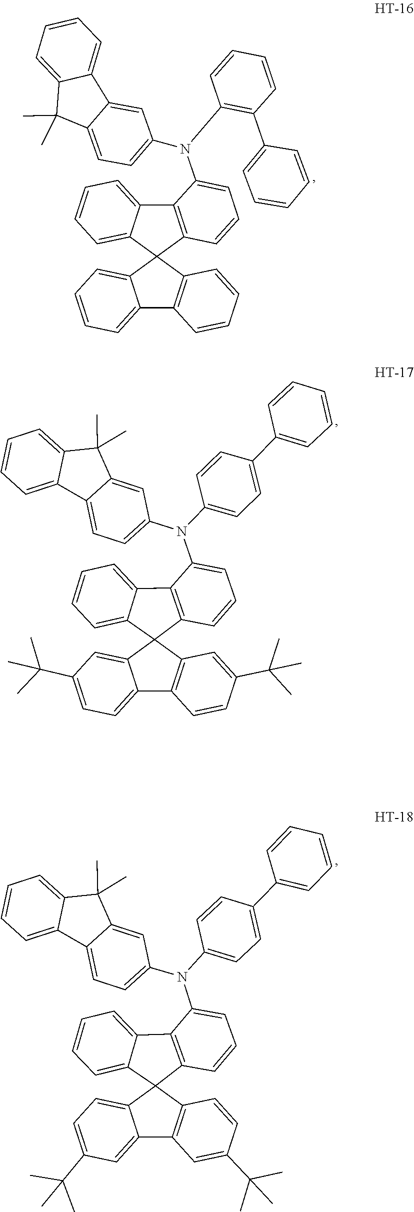 [SMILES: CC1(C)c2ccccc2-c2cc(N(c3ccccc3-c3ccccc3)c3cccc4c3-c3ccccc3C43c4ccccc4-c4ccccc43)ccc21 ; CC(C)(C)c1ccc2c(c1)C1(c3cc(C(C)(C)C)ccc3-2)c2ccccc2-c2c(N(c3ccc(-c4ccccc4)cc3)c3ccc4c(c3)C(C)(C)c3ccccc3-4)cccc21 ; CC(C)(C)c1ccc2c(c1)-c1cc(C(C)(C)C)ccc1C21c2ccccc2-c2c(N(c3ccc(-c4ccccc4)cc3)c3ccc4c(c3)C(C)(C)c3ccccc3-4)cccc21]

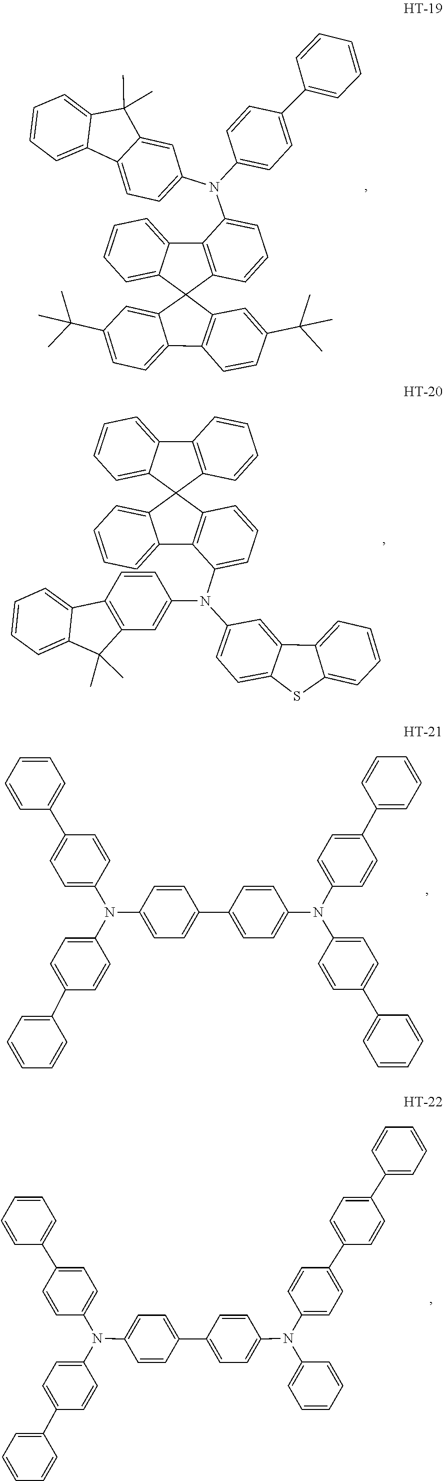 [SMILES: CC(C)(C)c1ccc2c(c1)C1(c3cc(C(C)(C)C)ccc3-2)c2ccccc2-c2c(N(c3ccc(-c4ccccc4)cc3)c3ccc4c(c3)C(C)(C)c3ccccc3-4)cccc21 ; CC1(C)c2ccccc2-c2ccc(N(c3ccc4sc5ccccc5c4c3)c3cccc4c3-c3ccccc3C43c4ccccc4-c4ccccc43)cc21 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

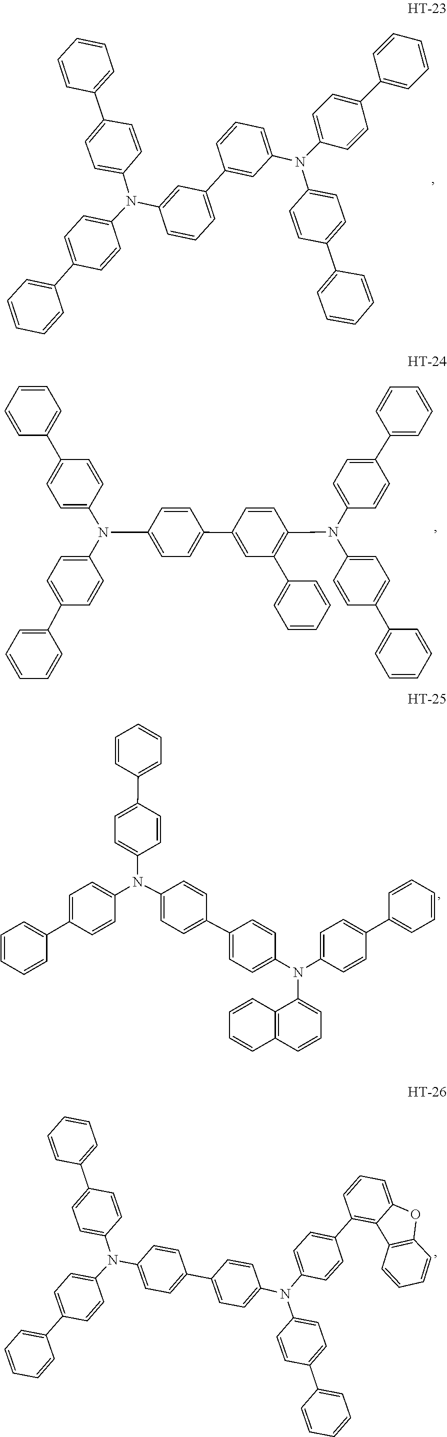 [SMILES: c1ccc(-c2ccc(N(c3ccc(-c4ccccc4)cc3)c3cccc(-c4cccc(N(c5ccc(-c6ccccc6)cc5)c5ccc(-c6ccccc6)cc5)c4)c3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)c(-c5ccccc5)c4)cc3)cc2)cc1 ; c1ccc(-c2ccc(N(c3ccc(-c4ccccc4)cc3)c3ccc(-c4ccc(N(c5ccc(-c6ccccc6)cc5)c5cccc6ccccc56)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6cccc7oc8ccccc8c67)cc5)cc4)cc3)cc2)cc1]

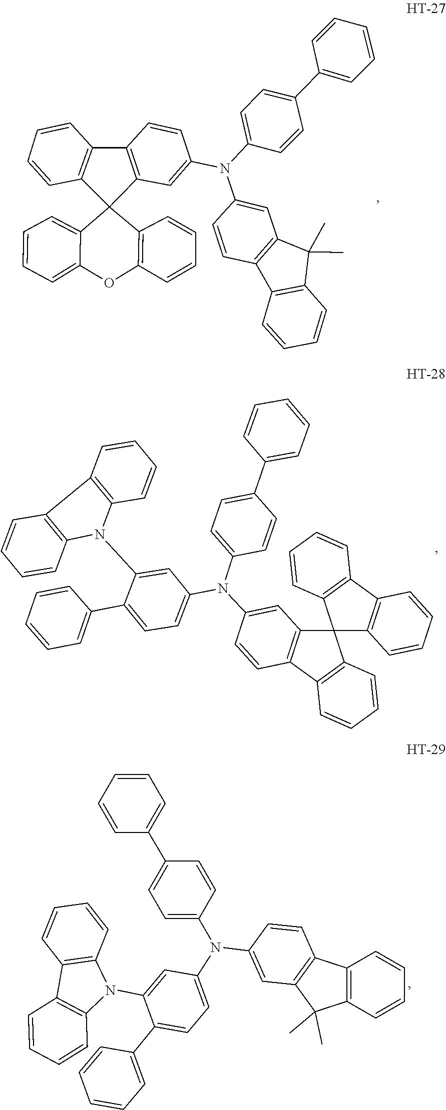 [SMILES: CC1(C)c2ccccc2-c2ccc(N(c3ccc(-c4ccccc4)cc3)c3ccc4c(c3)C3(c5ccccc5Oc5ccccc53)c3ccccc3-4)cc21 ; c1ccc(-c2ccc(N(c3ccc(-c4ccccc4)c(-n4c5ccccc5c5ccccc54)c3)c3ccc4c(c3)C3(c5ccccc5-c5ccccc53)c3ccccc3-4)cc2)cc1 ; CC1(C)c2ccccc2-c2ccc(N(c3ccc(-c4ccccc4)cc3)c3ccc(-c4ccccc4)c(-n4c5ccccc5c5ccccc54)c3)cc21]

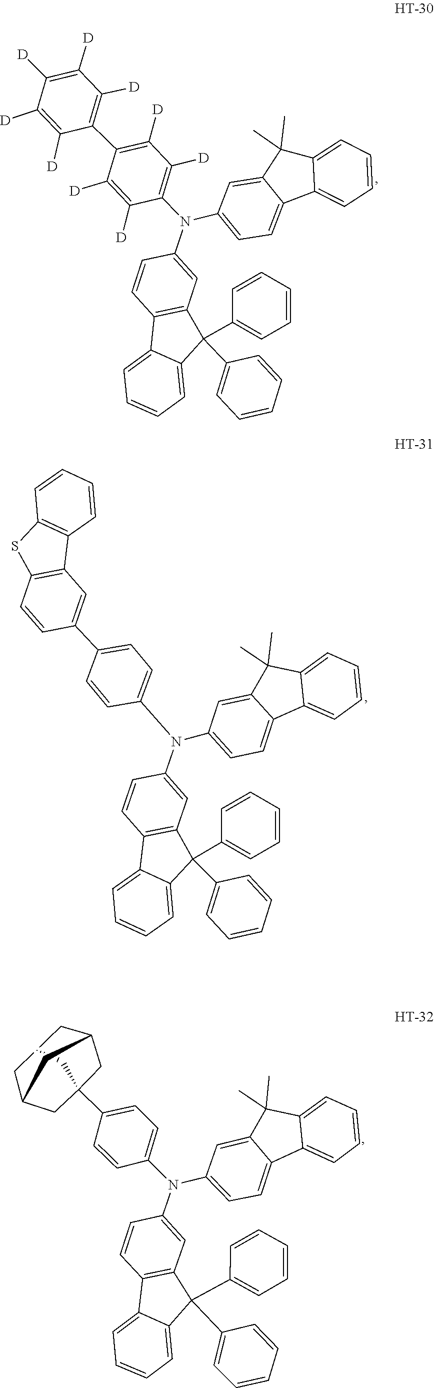

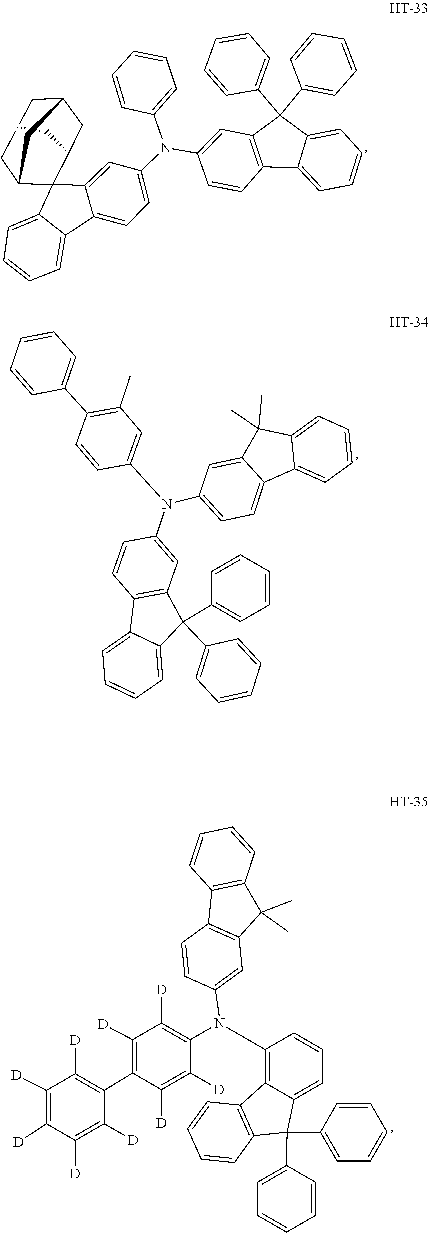

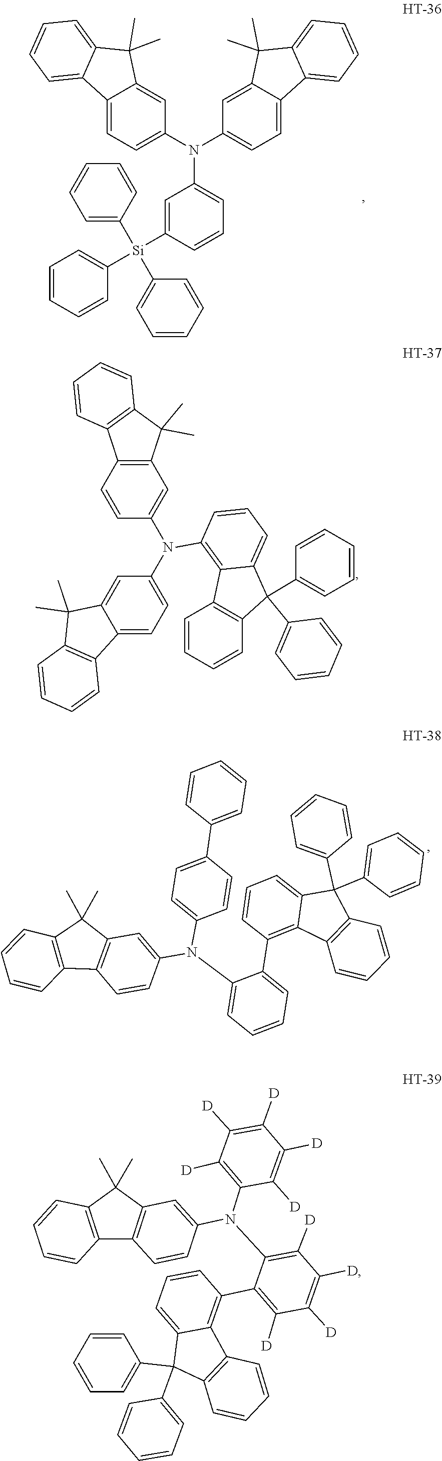

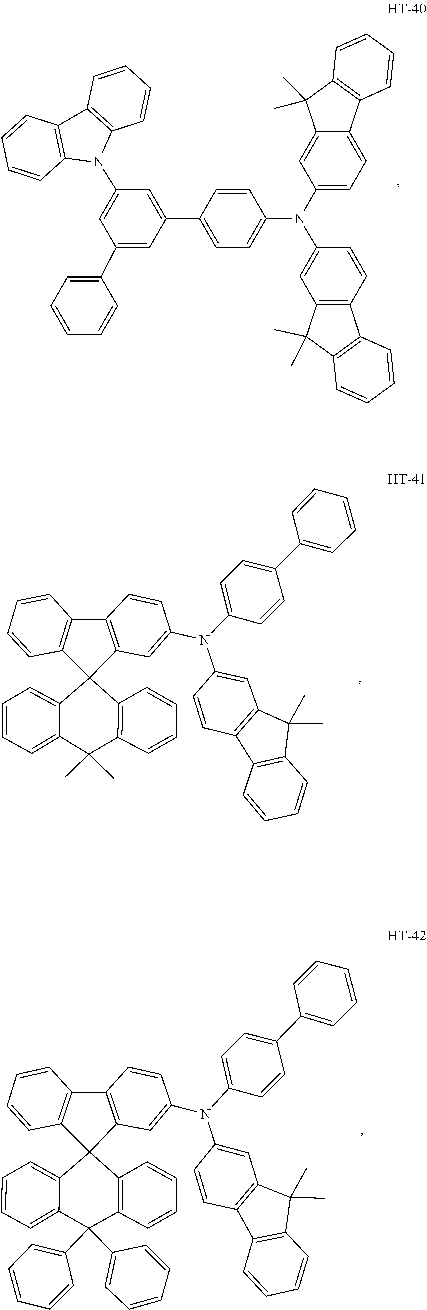 [SMILES: CC1(C)c2ccccc2-c2ccc(N(c3ccc(-c4cc(-c5ccccc5)cc(-n5c6ccccc6c6ccccc65)c4)cc3)c3ccc4c(c3)C(C)(C)c3ccccc3-4)cc21 ; CC1(C)c2ccccc2-c2ccc(N(c3ccc(-c4ccccc4)cc3)c3ccc4c(c3)C3(c5ccccc5-4)c4ccccc4C(C)(C)c4ccccc43)cc21 ; CC1(C)c2ccccc2-c2ccc(N(c3ccc(-c4ccccc4)cc3)c3ccc4c(c3)C3(c5ccccc5-4)c4ccccc4C(c4ccccc4)(c4ccccc4)c4ccccc43)cc21]

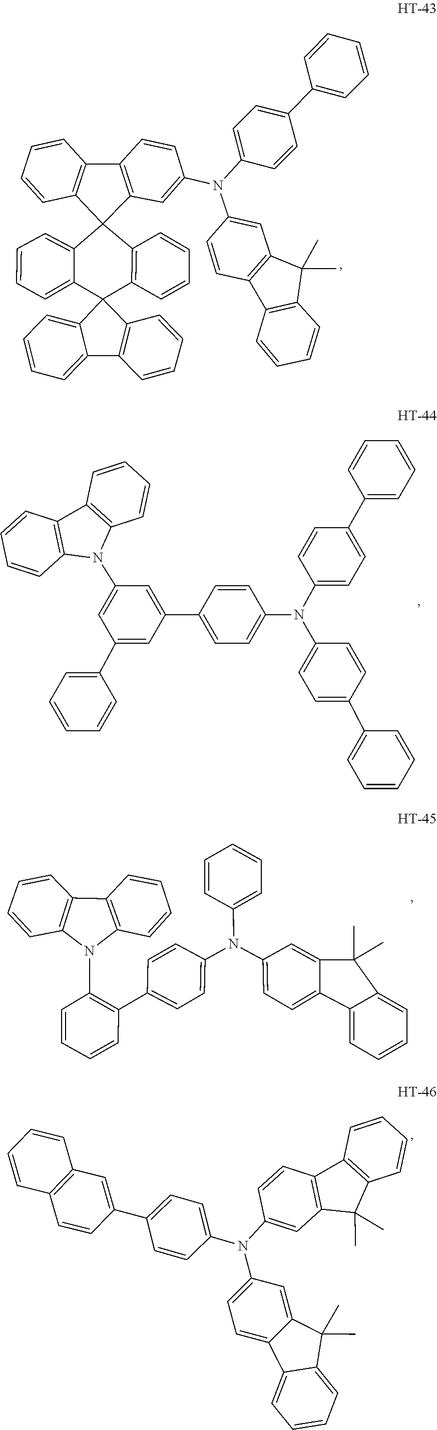 [SMILES: CC1(C)c2ccccc2-c2ccc(N(c3ccc(-c4ccccc4)cc3)c3ccc4c(c3)C3(c5ccccc5-4)c4ccccc4C4(c5ccccc5-c5ccccc54)c4ccccc43)cc21 ; c1ccc(-c2ccc(N(c3ccc(-c4ccccc4)cc3)c3ccc(-c4cc(-c5ccccc5)cc(-n5c6ccccc6c6ccccc65)c4)cc3)cc2)cc1 ; CC1(C)c2ccccc2-c2ccc(N(c3ccccc3)c3ccc(-c4ccccc4-n4c5ccccc5c5ccccc54)cc3)cc21 ; CC1(C)c2ccccc2-c2ccc(N(c3ccc(-c4ccc5ccccc5c4)cc3)c3ccc4c(c3)C(C)(C)c3ccccc3-4)cc21]

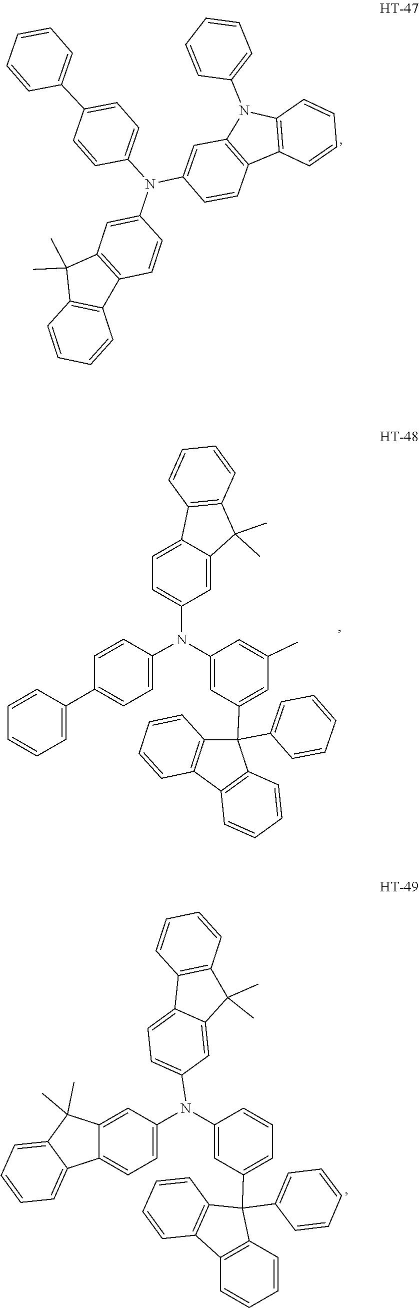 [SMILES: CC1(C)c2ccccc2-c2ccc(N(c3ccc(-c4ccccc4)cc3)c3ccc4c5ccccc5n(-c5ccccc5)c4c3)cc21 ; Cc1cc(N(c2ccc(-c3ccccc3)cc2)c2ccc3c(c2)C(C)(C)c2ccccc2-3)cc(C2(c3ccccc3)c3ccccc3-c3ccccc32)c1 ; CC1(C)c2ccccc2-c2ccc(N(c3cccc(C4(c5ccccc5)c5ccccc5-c5ccccc54)c3)c3ccc4c(c3)C(C)(C)c3ccccc3-4)cc21]

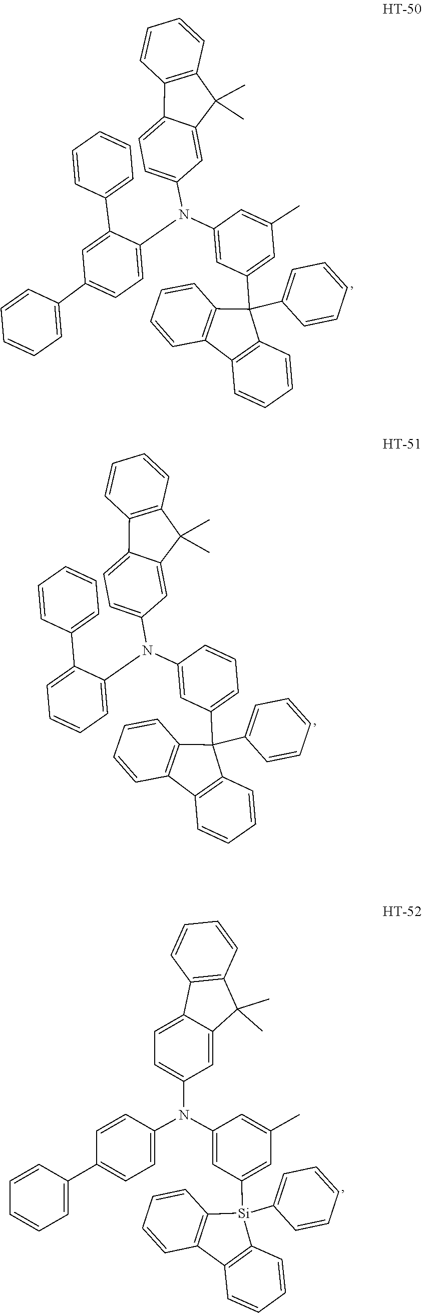 [SMILES: Cc1cc(N(c2ccc3c(c2)C(C)(C)c2ccccc2-3)c2ccc(-c3ccccc3)cc2-c2ccccc2)cc(C2(c3ccccc3)c3ccccc3-c3ccccc32)c1 ; CC1(C)c2ccccc2-c2ccc(N(c3cccc(C4(c5ccccc5)c5ccccc5-c5ccccc54)c3)c3ccccc3-c3ccccc3)cc21 ; Cc1cc(N(c2ccc(-c3ccccc3)cc2)c2ccc3c(c2)C(C)(C)c2ccccc2-3)cc([Si]2(c3ccccc3)c3ccccc3-c3ccccc32)c1]

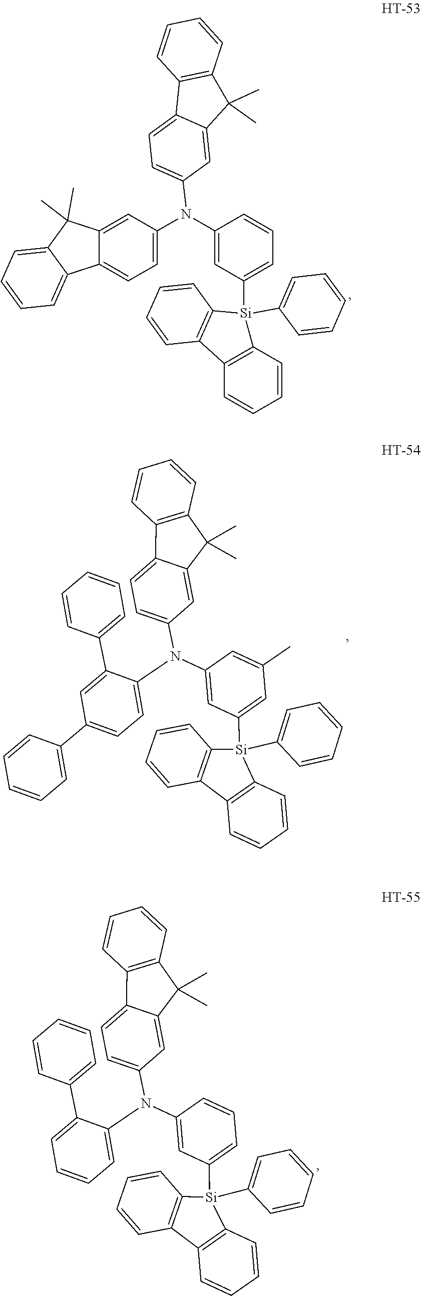 [SMILES: CC1(C)c2ccccc2-c2ccc(N(c3cccc([Si]4(c5ccccc5)c5ccccc5-c5ccccc54)c3)c3ccc4c(c3)C(C)(C)c3ccccc3-4)cc21 ; Cc1cc(N(c2ccc3c(c2)C(C)(C)c2ccccc2-3)c2ccc(-c3ccccc3)cc2-c2ccccc2)cc([Si]2(c3ccccc3)c3ccccc3-c3ccccc32)c1 ; CC1(C)c2ccccc2-c2ccc(N(c3cccc([Si]4(c5ccccc5)c5ccccc5-c5ccccc54)c3)c3ccccc3-c3ccccc3)cc21]

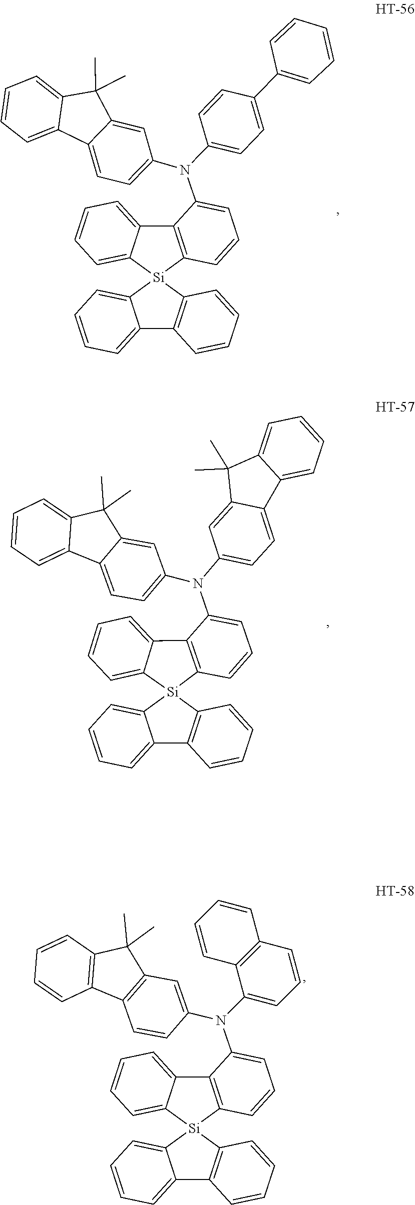 [SMILES: CC1(C)c2ccccc2-c2ccc(N(c3ccc(-c4ccccc4)cc3)c3cccc4c3-c3ccccc3[Si]43c4ccccc4-c4ccccc43)cc21 ; CC1(C)c2ccccc2-c2ccc(N(c3ccc4c(c3)C(C)(C)c3ccccc3-4)c3cccc4c3-c3ccccc3[Si]43c4ccccc4-c4ccccc43)cc21 ; CC1(C)c2ccccc2-c2ccc(N(c3cccc4c3-c3ccccc3[Si]43c4ccccc4-c4ccccc43)c3cccc4ccccc34)cc21]

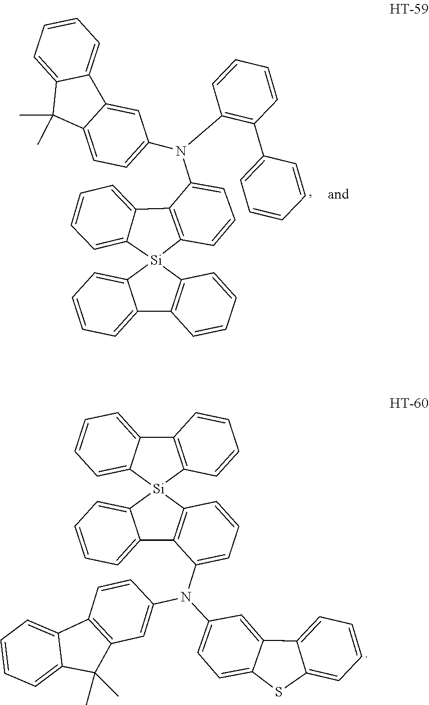 [SMILES: CC1(C)c2ccccc2-c2cc(N(c3ccccc3-c3ccccc3)c3cccc4c3-c3ccccc3[Si]43c4ccccc4-c4ccccc43)ccc21 ; CC1(C)c2ccccc2-c2ccc(N(c3ccc4sc5ccccc5c4c3)c3cccc4c3-c3ccccc3[Si]43c4ccccc4-c4ccccc43)cc21]

According to an embodiment of the present disclosure, hydrogens in Compound HT-1 to Compound HT-60 can be partially or fully substituted by deuterium.

According to an embodiment of the present disclosure, the organic layer comprises a common second organic layer, the common second organic layer is shared by at least two pixels, and the common second organic layer is disposed between the common first organic layer and the cathode.

According to an embodiment of the present disclosure, the common second organic layer is in direct contact with the common first organic layer.

According to an embodiment of the present disclosure, the common second organic layer is a hole transport layer.

According to an embodiment of the present disclosure, the common second organic layer comprises a third organic material.

According to an embodiment of the present disclosure, the third organic material is the same as or different from the second organic material.

According to an embodiment of the present disclosure, the third organic material is the same as the second organic material.

According to an embodiment of the present disclosure, the common second organic layer further comprises a fourth organic material, and the fourth organic material is a p-type conductive doping material.

According to an embodiment of the present disclosure, the fourth organic material is the same as or different from the first organic material.

According to an embodiment of the present disclosure, the thickness of the common second organic layer is greater than or equal to 20 nm.

According to an embodiment of the present disclosure, the thickness of the common second organic layer is greater than or equal to 40 nm.

According to an embodiment of the present disclosure, the thickness of the common second organic layer is greater than or equal to 60 nm.

According to an embodiment of the present disclosure, the thickness of the common second organic layer is greater than or equal to 80 nm.

According to an embodiment of the present disclosure, the thickness of the common second organic layer is greater than or equal to 100 nm.

According to an embodiment of the present disclosure, the organic electroluminescent device comprises multiple laminated layers between the anode and the cathode, and the laminated layer comprises at least two light-emitting units, wherein at least one light-emitting unit comprises the common first organic layer.

According to an embodiment of the present disclosure, the organic electroluminescent device comprises multiple stacked layers between the anode and the cathode, the stacked layer comprises at least a first light-emitting unit and a second light-emitting unit, and at least one charge generation layer is disposed between two adjacent light-emitting units, wherein the charge generation layer comprises a p-type charge generation layer and an n-type charge generation layer, and the p-type charge generation layer comprises at least a p-type conductive doping material.

According to an embodiment of the present disclosure, the p-type conductive doping material is selected from the following compounds: quinone or quinone derivatives, radialene compounds, dehydrobenzoxazole and dehydrobenzothiazole compounds, and bisoxazole or bisthiazole compounds.

According to an embodiment of the present disclosure, the p-type conductive doping material may be the same as or different from the first organic material.

According to an embodiment of the present disclosure, the p-type charge generation layer further comprises at least one hole transport material, the p-type charge generation layer is formed by doping the p-type conductive doping material to the at least one hole transport material, the hole transport material is selected from a compound having a triarylamine unit, a spirobifluorene compound, a pentacene compound, an oligothiophene compound, an oligophenyl compound, an oligophenylenevinylene compound, an oligofluorene compound, a porphyrin complex or a metallic phthalocyanine complex, and the molar doping ratio of the p-type conductive doping material to the hole transport material is 10000:1 to 1:10000.

According to an embodiment of the present disclosure, in the p-type charge generation layer, the molar doping ratio of the p-type conductive doping material to the hole transport material is 10:1 to 1:100.

According to an embodiment of the present disclosure, an electronic device is further disclosed, which comprises the active-matrix organic electroluminescent display described in any one of the preceding embodiments.

Combination with Other Materials

The materials described in the present disclosure for a particular layer in an organic light emitting device can be used in combination with various other materials present in the device. The combinations of these materials are described in more detail in U.S. patent application No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of light-emitting dopants, hosts, transporting layers, blocking layers, injection layers, electrodes, and other layers that may be present. The combination of these materials is described in detail in paragraphs 0080-0101 of U.S. patent application No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of the device, the characteristics of the device were also tested using conventional equipment in the art (including, but not limited to, evaporator produced by ANGSTROM ENGINEERING, optical testing system produced by SUZHOU FSTAR, lifetime testing system produced by SUZHOU FSTAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

Preparation methods in the following device examples are only examples and are not to be construed as limiting. Those skilled in the art can make reasonable improvements to the preparation methods in the following device examples based on the related art.

Herein, the LUMO energy levels and HOMO energy levels of the organic materials herein were measured through cyclic voltammetry (CV). The CV tests were conducted using an electrochemical workstation CorrTest CS120 produced by WUHAN CORRTEST INSTRUMENTS CORP., LTD and a three-electrode working system where a platinum disk electrode served as a working electrode, an Ag/AgNO₃ electrode served as a reference electrode and a platinum wire electrode served as an auxiliary electrode. With anhydrous DCM as a solvent and 0.1 mol/L tetrabutylammonium hexafluorophosphate as a supporting electrolyte, a compound to be tested was prepared into a solution of 10⁻³ mol/L, and nitrogen was introduced into the solution for 10 min for oxygen removal before the test. The parameters of the instrument were set as follows: a scan rate of 100 mV/s, a potential interval of 0.5 mV, and a test window of −1 V to 1 V.

Herein, the lateral conductivity per unit doping of the common first organic layer is tested in the following method: the first organic material and the second organic material were deposited through co-deposition at a certain mass ratio under a vacuum degree of about 10⁻⁶ Torr onto a test substrate pre-patterned with an aluminum electrode to form a test region with a thickness of 100 nm, a length of 6 mm and a width of 1 mm, an electric resistance value of the test region was determined at room temperature by applying a voltage to the electrode and measuring a current, the lateral conductivity B_{A} of the layer was calculated based on Ohm's law and geometric dimensions of the test region, and the lateral conductivity per unit doping σ_{A} of the common first organic layer was calculated according the equation σ_{A}=B_{A}/A.

Table 1 shows the LUMO energy levels of some first organic materials and the HOMO energy levels of some second organic materials measured by the above method, as well as the energy level difference between the two. Table 1 also shows the lateral conductivities per unit doping σ_{A} of the common first organic layers formed by combining different first organic materials at their recorded mass doping ratios (A %) with different second organic materials (wherein the layer structure was denoted as second organic material: first organic material).

TABLE 1
Layer structures, material energy levels and lateral conductivities per unit doping

| | | | | | | Lateral |
|---|---|---|---|---|---|---|
| | | | | | | conductivity |
| | | | | LUMO_{first}_{_{—}}_{organic}_{_{—}}ₘₐₜₑᵣᵢₐₗ − | Mass doping | per unit |
| | Layer | LUMO_{first}_{_{—}}_{organic}_{_{—}}ₘₐₜₑᵣᵢₐₗ | HOMO_{second}_{_{—}}_{organic}_{_{—}}ₘₐₜₑᵣᵢₐₗ | HOMO_{second}_{_{—}}_{organic}_{_{—}}ₘₐₜₑᵣᵢₐₗ | ratio A | doping σ_{A} |
| Layer No. | structure | (eV) | (eV) | (eV) | (%) | (10⁻⁴ S/m) |
| Example | HT- | −5.01 | −5.13 | 0.12 | 6 | 0.41 |
| layer 1 | 11:1-27 | | | | | |
| Example | | | | | 8 | 0.51 |
| layer 2 | | | | | | |
| Example | | | | | 10 | 0.64 |
| layer 3 | | | | | | |
| Example | HT- | −5.07 | −5.13 | 0.06 | 6 | 0.21 |
| layer 4 | 11:1-20 | | | | | |
| Example | | | | | 8 | 0.19 |
| layer 5 | | | | | | |
| Example | | | | | 10 | 0.17 |
| layer 6 | | | | | | |
| Example | HT- | −5.09 | −5.19 | 0.10 | 6 | 0.37 |
| layer 7 | 14:1-28 | | | | | |
| Example | | | | | 8 | 0.30 |
| layer 8 | | | | | | |
| Example | | | | | 10 | 0.30 |
| layer 9 | | | | | | |
| Example | HT- | −4.99 | −5.13 | 0.14 | 5 | 0.89 |
| layer 10 | 11:2-23 | | | | | |
| Example | | | | | 7 | 0.87 |
| layer 11 | | | | | | |
| Example | | | | | 9 | 0.62 |
| layer 12 | | | | | | |
| Comparative | HT- | −5.04 | −5.13 | 0.09 | 6 | 4.75 |
| Example | 11:5-1 | | | | | |
| layer 1 | | | | | | |
| Comparative | | | | | 8 | 4.60 |
| Example | | | | | | |
| layer 2 | | | | | | |
| Comparative | | | | | 10 | 4.60 |
| Example | | | | | | |
| layer 3 | | | | | | |
| Comparative | HT- | −4.63 | −5.13 | 0.50 | 6 | 0.05 |
| Example | 11:PD-1 | | | | | |
| layer 4 | | | | | | |
| Comparative | | | | | 8 | 0.09 |
| Example | | | | | | |
| layer 5 | | | | | | |
| Comparative | | | | | 10 | 0.15 |
| Example | | | | | | |
| layer 6 | | | | | | |
| Comparative | HT- | −5.07 | −5.33 | 0.26 | 6 | 1.61 |
| Example | 23:1-20 | | | | | |
| layer 7 | | | | | | |
| Comparative | | | | | 8 | 1.22 |
| Example | | | | | | |
| layer 8 | | | | | | |
| Comparative | | | | | 10 | 1.00 |
| Example | | | | | | |
| layer 9 | | | | | | |

The structures of the materials used in the common first organic layers are as follows:

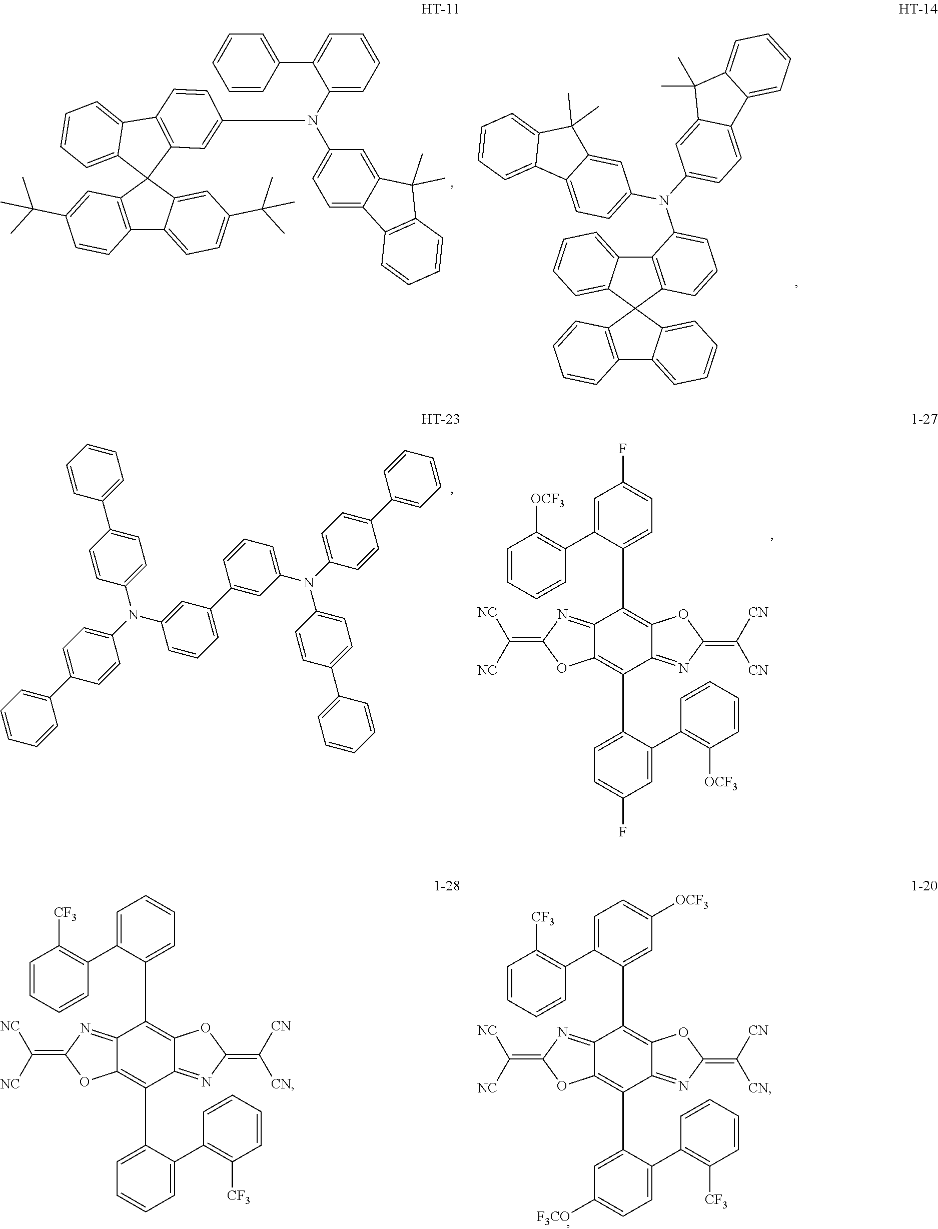

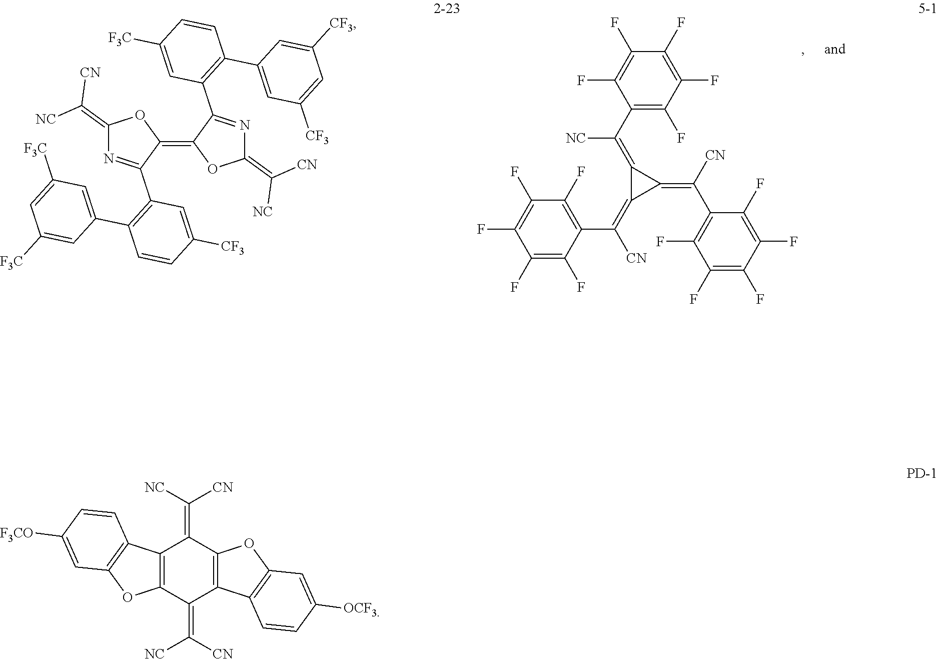 [SMILES: N#CC(C#N)=c1nc(-c2cc(C(F)(F)F)ccc2-c2cc(C(F)(F)F)cc(C(F)(F)F)c2)/c(=c2\oc(=C(C#N)C#N)nc2-c2cc(C(F)(F)F)ccc2-c2cc(C(F)(F)F)cc(C(F)(F)F)c2)o1 ; N#CC(=C1C(=C(C#N)c2c(F)c(F)c(F)c(F)c2F)C1=C(C#N)c1c(F)c(F)c(F)c(F)c1F)c1c(F)c(F)c(F)c(F)c1F ; N#CC(C#N)=c1c2oc3cc(OC(F)(F)F)ccc3c2c(=C(C#N)C#N)c2oc3cc(OC(F)(F)F)ccc3c12]

Table 1 shows the lateral conductivities per unit doping σ_{A} of different layers, and such indicators reflect the hole transport capability of the respective layers. As can be seen from the data in Table 1, Example layers 1 to 12 (common first organic layers) all exhibit specifically low lateral conductivities per unit doping when the first organic materials have specifically high mass doping ratios. Especially, as the mass doping ratios of the first organic material increase from 6% to 10% in Example layers 4 to 6 and 7 to 9, the lateral conductivities per unit doping decrease instead, which indicates that with an increasing doping ratio of the first organic material, the cumulative rate of holes in the common first organic layer appropriately decreases. Therefore, the common first organic layer is capable of maintaining a sufficient number of holes to guarantee adequate hole injection, and excessive hole accumulation can also be avoided simultaneously. Consequently, the hole density remains at a suitably low level, and the lateral migration of holes is at a relatively low level to effectively suppress the lateral migration of holes from one pixel to adjacent pixels through the common first organic layer, thereby significantly suppressing lateral crosstalk between pixels in the display. The above points are further verified by crosstalk testing below.

### Crosstalk Test Device Example 1

As shown in FIG. 4, a glass substrate having a thickness of 0.7 mm and patterned with two independent indium tin oxide (ITO) anodes 301a and 301b with a thickness of 800 Å, was washed with deionized water and a detergent, and then the ITO surface was treated with oxygen plasma and UV ozone. The substrate was dried in a glovebox to remove moisture, mounted on a support, and transferred into a vacuum chamber. The organic layers specified below were sequentially deposited on the anode layer through vacuum thermal evaporation at a rate of 0.01-10 Å/s and at a vacuum degree of about 10⁻⁶ Torr. Compound HT-11 and Compound 1-20 were co-deposited at a weight ratio of 90:10 to form a common hole injection layer 302 (HIL, 100 Å). Compound HT-11 was deposited to form a common hole transport layer 303 (HTL, 450 Å). Compound EB-1 was deposited to form electron blocking layers 304a and 304b (EBL, 50 Å). Compound RH-1 and Compound RD-1 were co-deposited at a weight ratio of 98:2 to form two independent emissive layers 305a and 305b (EML, 400 Å). Compound ET-1 and Liq were co-deposited at a weight ratio of 1:1 to form a common electron transport layer 306 (ETL, 300 Å). Liq with a thickness of 10 Å was deposited to form a common electron injection layer 307 (EIL). Metallic aluminum was deposited to form two independent cathodes 308a and 308b (Cathode, 1200 Å) of a pixel A and a pixel B that are independent of each other. The device was transferred back to the glovebox and encapsulated with a glass lid to complete the device.

### Crosstalk Test Device Comparative Example 1

The preparation method in this comparative example was the same as the preparation method in Crosstalk Test Device Example 1 except that Compound HT-11 and Compound 5-1 were co-deposited at a weight ratio of 90:10 to form a common hole injection layer 302 (HIL, 100 Å), instead of Compound HT-11 and Compound 1-20.

The structures of the materials used in the devices are as follows:

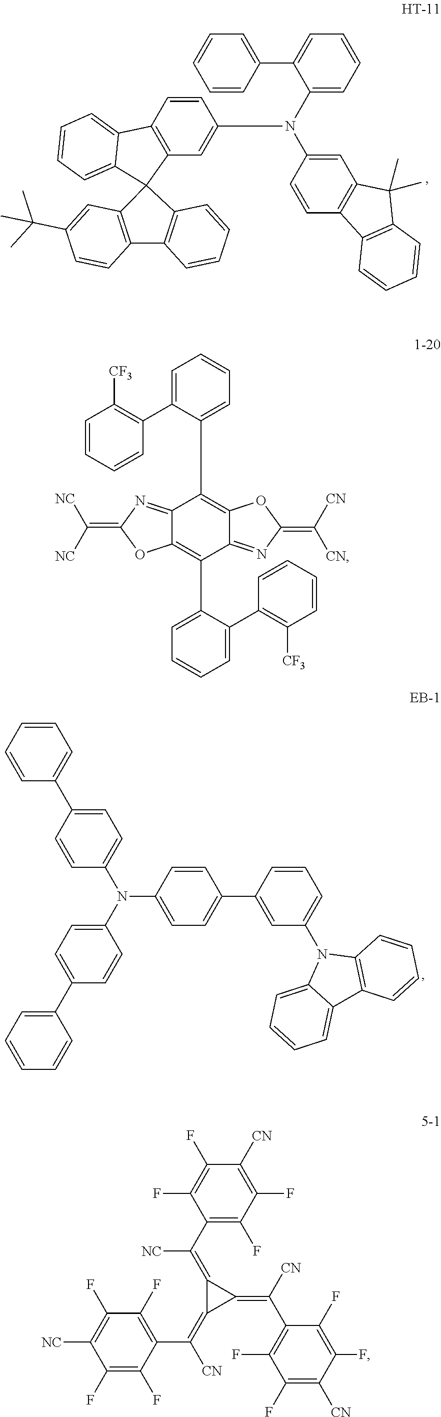 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1ccccc1-2 ; N#CC(C#N)=c1nc2c(-c3ccccc3-c3ccccc3C(F)(F)F)c3oc(=C(C#N)C#N)nc3c(-c3ccccc3-c3ccccc3C(F)(F)F)c2o1 ; c1ccc(-c2ccc(N(c3ccc(-c4ccccc4)cc3)c3ccc(-c4cccc(-n5c6ccccc6c6ccccc65)c4)cc3)cc2)cc1 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

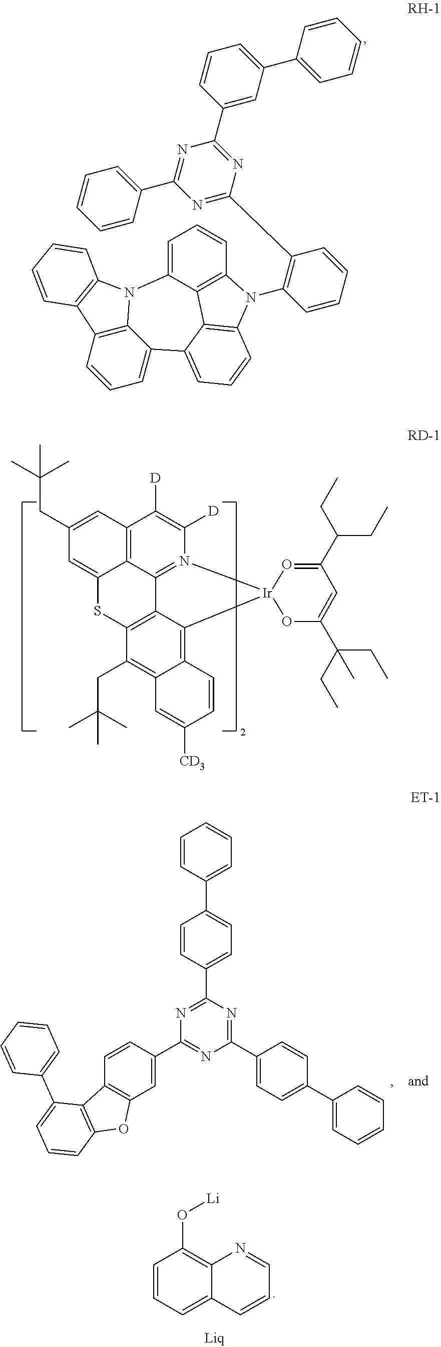

As shown in FIG. 4, the crosstalk test device included the pixel 3A and the pixel 3B, the anode 301a and the cathode 308b were electrically connected to a driving device, and the luminous brightness (cd/m²) of the pixel 3B was tested at a constant voltage of 21 V. The data are recorded and shown in Table 2.

TABLE 2
Luminous brightness of the pixel 3B in Crosstalk Test Device
Example 1 and Crosstalk Test Device Comparative Example 1

| | | Lateral | |
|---|---|---|---|
| | Common hole | conductivity per | Luminous |
| | injection layer | unit doping σ_{A} | brightness |
| Device No. | (HIL) | (10⁻⁴ S/m) | (cd/m²) |
| Crosstalk Test Device | HT-11:1-20 | 0.17 | 0 |
| Example 1 | (90:10) (100 Å) | | |
| Crosstalk Test Device | HT-11:5-1 | 4.60 | 1.1 |
| Comparative Example 1 | (90:10) (100 Å) | | |

As can be seen from the data in Table 2, the only difference between Crosstalk Test Device Example 1 and Crosstalk Test Device Comparative Example 1 lies in the common HIL shared by the pixel 3A and the pixel 3B. In Crosstalk Test Device Example 1, the common HIL (common first organic layer) shared by the pixel 3A and the pixel 3B has a specifically low lateral conductivity per unit doping (0.17×10⁻⁴ S/m), and the luminous brightness of the pixel 3B measured at a constant voltage of 21 V is 0 cd/m², which indicates that the lateral migration of holes within the common HIL in Crosstalk Test Device Example 1 is at a low level, making it difficult for holes to migrate from the pixel 3A to the pixel 3B through the common HIL. As a result, no luminescence is observed in the pixel 3B in Crosstalk Test Device Example 1, suggesting very little or no crosstalk between the two pixels. In contrast, the common HIL shared by the pixel 3A and the pixel 3B in Crosstalk Test Device Comparative Example 1 has an excessively high lateral conductivity per unit doping (4.6×10⁻⁴ S/m), and the luminous brightness of the pixel 3B measured under the same test conditions is 1.1 cd/m², which indicates that the excessively high lateral conductivity per unit doping in the common HIL causes holes to easily migrate from the pixel 3A to the pixel 3B through the common HIL in Crosstalk Test Device Comparative Example 1. Therefore, the pixel 3B in Crosstalk Test Device Comparative Example 1 exhibits noticeable luminescence, indicating significant crosstalk between the two pixels. The analysis of the above data confirms that the common HIL in the active-matrix organic electroluminescent display of the present disclosure, due to its specifically low lateral conductivity per unit doping, can effectively suppress lateral crosstalk between pixels.

Furthermore, the common first organic layer in the active-matrix OLED display of the present disclosure, which comprises a first organic material and a second organic material that satisfy a specific energy level relationship and exhibits a specific lateral conductivity per unit doping, not only effectively suppresses crosstalk between pixels when used as an HIL or a p-doped HTL in organic electroluminescent devices, but also enables the devices to obtain excellent device performance. As a result, such a common first organic layer can also contribute to superior overall display performance when employed as the common first organic layer in the active-matrix organic electroluminescent display of the present disclosure. Device examples and their device data are provided below for demonstration.

### Device Example

### Example 1

Firstly, a glass substrate having a thickness of 0.7 mm and patterned with an indium tin oxide (ITO) anode with a thickness of 800 Å was washed with deionized water and a detergent, and then the ITO surface was treated with oxygen plasma and UV ozone. The substrate was dried in a glovebox to remove moisture, mounted on a support, and transferred into a vacuum chamber. The organic layers specified below were sequentially deposited on the anode layer through vacuum thermal evaporation at a rate of 0.01-10 Å/s and at a vacuum degree of about 10⁻⁶ Torr. Compound HT-11 and Compound 1-27 were co-deposited at a weight ratio of 94:6 to form a hole injection layer (HIL, 100 Å). Compound HT-11 was deposited to form a hole transport layer (HTL, 1500 Å). Compound EB-2 was deposited to form an electron blocking layer (EBL, 50 Å). Compound BH-1 and Compound BD-1 were co-deposited at a weight ratio of 96:4 to form an emissive layer (EML, 250 Å). Compound HB-1 was deposited to form a hole blocking layer (HBL, 50 Å). Compound ET-2 and Liq were co-deposited at a weight ratio of 40:60 to form an electron transport layer (ETL, 300 Å). Liq with a thickness of 10 Å was deposited to form an electron injection layer (EIL). Metallic aluminum was deposited to form a cathode (1200 Å). The device was transferred back to the glovebox and encapsulated with a glass lid to complete the device.

### Example 2

The preparation method in this example was the same as the preparation method in Example 1 except that the weight ratio of Compound HT-11 to Compound 1-27 in the hole injection layer was adjusted to 92:8.

### Example 3

The preparation method in this example was the same as the preparation method in Example 1 except that the weight ratio of Compound HT-11 to Compound 1-27 in the hole injection layer was adjusted to 90:10.

### Example 4

The preparation method in this example was the same as the preparation method in Example 1 except that Compound HT-11 and Compound 1-20 were co-deposited at a weight ratio of 94:6 to form a hole injection layer (HIL, 100 Å), instead of Compound HT-11 and Compound 1-27.

### Example 5

The preparation method in this example was the same as the preparation method in Example 4 except that the weight ratio of Compound HT-11 to Compound 1-20 in the hole injection layer was adjusted to 92:8.

### Example 6

The preparation method in this example was the same as the preparation method in Example 4 except that the weight ratio of Compound HT-11 to Compound 1-20 in the hole injection layer was adjusted to 90:10.

### Example 7

The preparation method in this example was the same as the preparation method in Example 1 except that Compound HT-14 and Compound 1-28 were co-deposited at a weight ratio of 94:6 to form a hole injection layer (HIL, 100 Å), instated of Compound HT-11 and Compound 1-27, and Compound HT-14 was deposited to form a hole transport layer (HTL, 1500 Å).

### Example 8

The preparation method in this example was the same as the preparation method in Example 7 except that the weight ratio of Compound HT-14 to Compound 1-28 in the hole injection layer was adjusted to 92:8.

### Example 9

The preparation method in this example was the same as the preparation method in Example 7 except that the weight ratio of Compound HT-14 to Compound 1-28 in the hole injection layer was adjusted to 90:10.

### Example 10

The preparation method in this example was the same as the preparation method in Example 1 except that Compound HT-11 and Compound 2-23 were co-deposited at a weight ratio of 95:5 to form a hole injection layer (HIL, 100 Å), instated of Compound HT-11 and Compound 1-27, and the thickness of HTL was adjusted to 1440 Å.

### Example 11

The preparation method in this example was the same as the preparation method in Example 10 except that the weight ratio of Compound HT-11 to Compound 2-23 in the hole injection layer was adjusted to 93:7.

### Example 12

The preparation method in this example was the same as the preparation method in Example 10 except that the weight ratio of Compound HT-11 to Compound 2-23 in the hole injection layer was adjusted to 91:9.

### Comparative Example 1

The preparation method in this comparative example was the same as the preparation method in Example 1 except that Compound HT-11 and Compound 5-1 were co-deposited at a weight ratio of 94:6 to form a hole injection layer (HIL, 100 Å), instead of Compound HT-11 and Compound 1-27.

### Comparative Example 2

The preparation method in this comparative example was the same as the preparation method in Comparative Example 1 except that the weight ratio of Compound HT-11 to Compound 5-1 in the hole injection layer was adjusted to 92:8.

### Comparative Example 3

The preparation method in this comparative example was the same as the preparation method in Comparative Example 1 except that the weight ratio of Compound HT-11 to Compound 5-1 in the hole injection layer was adjusted to 90:10.

### Comparative Example 4

The preparation method in this comparative example was the same as the preparation method in Example 1 except that Compound HT-11 and Compound PD-1 were co-deposited at a weight ratio of 94:6 to form a hole injection layer (HIL, 100 Å), instead of Compound HT-11 and Compound 1-27.

### Comparative Example 5

The preparation method in this comparative example was the same as the preparation method in Comparative Example 4 except that the weight ratio of Compound HT-11 to Compound PD-1 in the hole injection layer was adjusted to 92:8.

### Comparative Example 6

The preparation method in this comparative example was the same as the preparation method in Comparative Example 4 except that the weight ratio of Compound HT-11 to Compound PD-1 in the hole injection layer was adjusted to 90:10.

### Comparative Example 7

The preparation method in this comparative example was the same as the preparation method in Example 1 except that Compound HT-23 and Compound 1-20 were co-deposited at a weight ratio of 94:6 to form a hole injection layer (HIL, 100 Å), instated of Compound HT-11 and Compound 1-27, and Compound HT-23 was deposited to form a hole transport layer (HTL, 1500 Å).

### Comparative Example 8

The preparation method in this comparative example was the same as the preparation method in Comparative Example 7 except that the weight ratio of Compound HT-23 to Compound 1-20 in the hole injection layer was adjusted to 92:8.

### Comparative Example 9

The preparation method in this comparative example was the same as the preparation method in Comparative Example 7 except that the weight ratio of Compound HT-23 to Compound 1-20 in the hole injection layer was adjusted to 90:10.

The structures and thicknesses of some layers of the devices are shown in Table 3. A layer using more than one material is obtained by doping different compounds at the respective weight ratios as recorded.

TABLE 3
Structures of some devices in Examples
1 to 12 and Comparative Examples 1 to 9

| Device No. | HIL | HTL |
|---|---|---|
| Example 1 | Compound HT-11:Compound 1-27 | Compound HT-11 |
| | (94:6) (100 Å) | (1500 Å) |
| Example 2 | Compound HT-11:Compound 1-27 | Compound HT-11 |
| | (92:8) (100 Å) | (1500 Å) |
| Example 3 | Compound HT-11:Compound 1-27 | Compound HT-11 |
| | (90:10) (100 Å) | (1500 Å) |
| Example 4 | Compound HT-11:Compound 1-20 | Compound HT-11 |
| | (94:6) (100 Å) | (1500 Å) |
| Example 5 | Compound HT-11:Compound 1-20 | Compound HT-11 |
| | (92:8) (100 Å) | (1500 Å) |
| Example 6 | Compound HT-11:Compound 1-20 | Compound HT-11 |
| | (90:10) (100 Å) | (1500 Å) |
| Example 7 | Compound HT-14:Compound 1-28 | Compound HT-14 |
| | (94:6) (100 Å) | (1500 Å) |
| Example 8 | Compound HT-14:Compound 1-28 | Compound HT-14 |
| | (92:8) (100 Å) | (1500 Å) |
| Example 9 | Compound HT-14:Compound 1-28 | Compound HT-14 |
| | (90:10) (100 Å) | (1500 Å) |
| Example 10 | Compound HT-11:Compound 2-23 | Compound HT-11 |
| | (95:5) (100 Å) | (1440 Å) |
| Example 11 | Compound HT-11:Compound 2-23 | Compound HT-11 |
| | (93:7) (100 Å) | (1440 Å) |
| Example 12 | Compound HT-11:Compound 2-23 | Compound HT-11 |
| | (91:9) (100 Å) | (1440 Å) |
| Comparative | Compound HT-11:Compound 5-1 | Compound HT-11 |
| Example 1 | (94:6) (100 Å) | (1500 Å) |
| Comparative | Compound HT-11:Compound 5-1 | Compound HT-11 |
| Example 2 | (92:8) (100 Å) | (1500 Å) |
| Comparative | Compound HT-11:Compound 5-1 | Compound HT-11 |
| Example 3 | (90:10) (100 Å) | (1500 Å) |
| Comparative | Compound HT-11:Compound PD-1 | Compound HT-11 |
| Example 4 | (94:6) (100 Å) | (1500 Å) |
| Comparative | Compound HT-11:Compound PD-1 | Compound HT-11 |
| Example 5 | (92:8) (100 Å) | (1500 Å) |
| Comparative | Compound HT-11:Compound PD-1 | Compound HT-11 |
| Example 6 | (90:10) (100 Å) | (1500 Å) |
| Comparative | Compound HT-23:Compound 1-20 | Compound HT-23 |
| Example 7 | (94:6) (100 Å) | (1500 Å) |
| Comparative | Compound HT-23:Compound 1-20 | Compound HT-23 |
| Example 8 | (92:8) (100 Å) | (1500 Å) |
| Comparative | Compound HT-23:Compound 1-20 | Compound HT-23 |
| Example 9 | (90:10) (100 Å) | (1500 Å) |

The structures of the materials used in the devices are as follows:

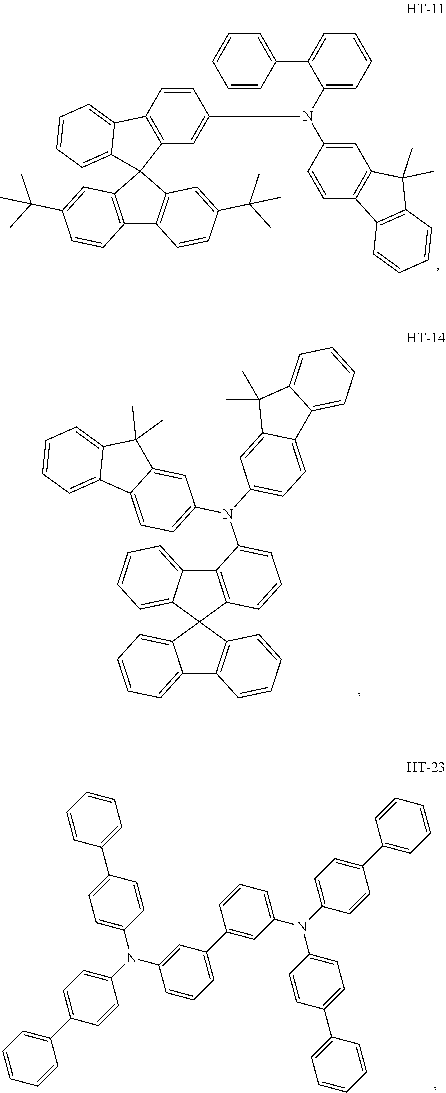 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; CC1(C)c2ccccc2-c2ccc(N(c3ccc4c(c3)C(C)(C)c3ccccc3-4)c3cccc4c3-c3ccccc3C43c4ccccc4-c4ccccc43)cc21 ; c1ccc(-c2ccc(N(c3ccc(-c4ccccc4)cc3)c3cccc(-c4cccc(N(c5ccc(-c6ccccc6)cc5)c5ccc(-c6ccccc6)cc5)c4)c3)cc2)cc1]

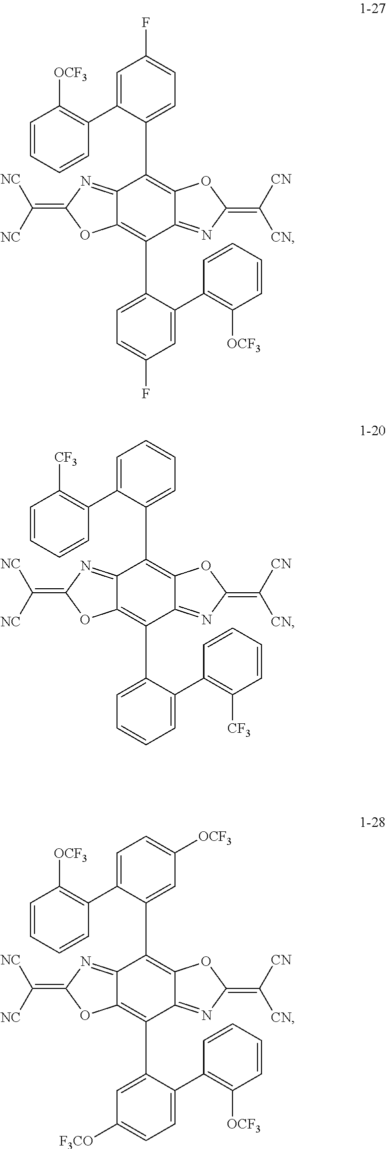 [SMILES: N#CC(C#N)=c1nc2c(-c3ccc(F)cc3-c3ccccc3OC(F)(F)F)c3oc(=C(C#N)C#N)nc3c(-c3ccc(F)cc3-c3ccccc3OC(F)(F)F)c2o1 ; N#CC(C#N)=c1nc2c(-c3ccccc3-c3ccccc3C(F)(F)F)c3oc(=C(C#N)C#N)nc3c(-c3ccccc3-c3ccccc3C(F)(F)F)c2o1 ; N#CC(C#N)=c1nc2c(-c3cc(OC(F)(F)F)ccc3-c3ccccc3OC(F)(F)F)c3oc(=C(C#N)C#N)nc3c(-c3cc(OC(F)(F)F)ccc3-c3ccccc3OC(F)(F)F)c2o1]

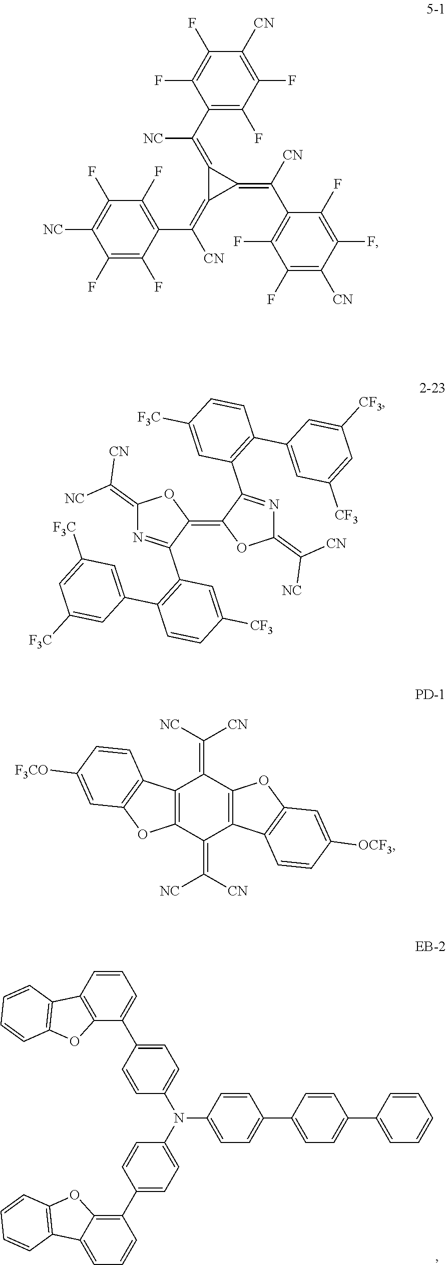 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC(C#N)=c1nc(-c2cc(C(F)(F)F)ccc2-c2cc(C(F)(F)F)cc(C(F)(F)F)c2)/c(=c2\oc(=C(C#N)C#N)nc2-c2cc(C(F)(F)F)ccc2-c2cc(C(F)(F)F)cc(C(F)(F)F)c2)o1 ; N#CC(C#N)=c1c2oc3cc(OC(F)(F)F)ccc3c2c(=C(C#N)C#N)c2oc3cc(OC(F)(F)F)ccc3c12 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

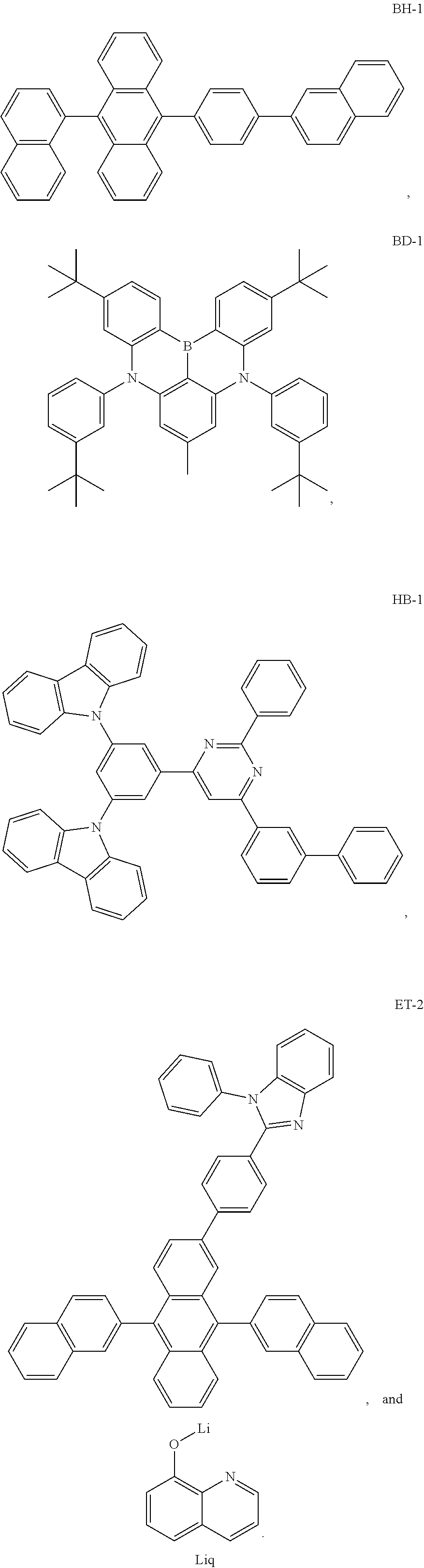

The device performance of Examples 1 to 12 and Comparative Examples 1 to 9 is summarized in Table 4. The voltage (V), current efficiency (CE), power efficiency (PE) and external quantum efficiency (EQE) were measured at a current density of 10 mA/cm².

TABLE 4
Device data in Examples 1 to 12 and Comparative Examples 1 to 9

| | Voltage | CE | PE | EQE |
|---|---|---|---|---|
| Device No. | (V) | (cd/A) | (lm/W) | (%) |
| Example 1 | 4.1 | 3.6 | 2.7 | 7.10 |
| Example 2 | 4.1 | 3.5 | 2.7 | 7.10 |
| Example 3 | 4.1 | 3.5 | 2.7 | 7.10 |
| Example 4 | 4.3 | 3.6 | 2.4 | 7.17 |
| Example 5 | 4.1 | 3.8 | 2.5 | 7.25 |
| Example 6 | 4.1 | 3.8 | 2.5 | 7.23 |
| Example 7 | 4.2 | 3.8 | 2.8 | 7.4 |
| Example 8 | 4.1 | 3.7 | 2.8 | 7.3 |
| Example 9 | 4.1 | 3.7 | 2.8 | 7.3 |
| Example 10 | 4.1 | 3.6 | 2.8 | 7.2 |
| Example 11 | 4.1 | 3.6 | 2.8 | 7.1 |
| Example 12 | 4.1 | 3.5 | 2.7 | 7.0 |
| Comparative Example 1 | 4.0 | 3.3 | 2.6 | 6.7 |
| Comparative Example 2 | 4.0 | 3.3 | 2.6 | 6.7 |
| Comparative Example 3 | 4.0 | 3.3 | 2.6 | 6.7 |
| Comparative Example 4 | 10 | 3.7 | 1.2 | 7.4 |
| Comparative Example 5 | 9.1 | 4.2 | 1.5 | 8.4 |
| Comparative Example 6 | 7.9 | 4.3 | 1.7 | 8.6 |
| Comparative Example 7 | 6.9 | 3.4 | 2.0 | 7.3 |
| Comparative Example 8 | 6.1 | 3.5 | 2.1 | 7.3 |
| Comparative Example 9 | 5.3 | 3.5 | 2.3 | 7.2 |

### DISCUSSION

Comparison of Examples 1 to 3 with Comparative Examples 1 to 3, Comparative Examples 4 to 6, and Comparative Examples 7 to 9:

Examples 1 to 3 each employ Compound 1-27 doped to Compound HT-11 to form the HIL, and the mass doping ratios of Compound 1-27 are 6%, 8%, and 10%, respectively. As can be seen from the data in Table 1, the energy level difference between Compound 1-27 and Compound HT-11 is 0.12 eV, which satisfies the specified limit of being greater than −0.1 eV and less than 0.25 eV, that is, the two compounds have a small energy level difference; the lateral conductivities per unit doping σ₆, σ₈, and σ₁₀ of the common first organic layers in Examples 1 to 3 are 0.41×10⁻⁴ S/m, 0.51×10⁻⁴ S/m, and 0.64×10⁻⁴ S/m, respectively, all satisfying the requirement of being greater than or equal to 0.05×10⁻⁴ S/m and less than or equal to 1×10⁻⁴ S/m.

Comparative Examples 1 to 3 each employ Compound 5-1 doped to Compound HT-11 to form the HIL, and the mass doping ratios of Compound 5-1 are 6%, 8%, and 10%, respectively. As can be seen from the data in Table 1, the energy level difference between Compound 5-1 and Compound HT-11 is 0.09 eV, which satisfies the specified limit of being greater than −0.1 eV and less than 0.25 eV; however, the lateral conductivities per unit doping of the common first organic layers in Comparative Examples 1 to 3 are extremely high, and σ₆, σ₈, and Gio are 4.75×10⁻⁴ S/m, 4.60×10⁻⁴ S/m, and 4.60×10⁻⁴ S/m, respectively, far exceeding 1×10⁻⁴ S/m. Therefore, compared with the HIL in Comparative Examples 1 to 3, the HIL in Examples 1 to 3 exhibits specifically low lateral conductivities per unit doping, and the lateral migration of holes in the HIL is maintained at a low level, thereby significantly suppressing lateral crosstalk. Moreover, as can be seen from the data in Table 4, the materials used in Comparative Examples 1 to 3 are commonly used in the industry and already exhibit very good device performance; Examples 1 to 3 achieve comparably low voltages and further improvements in the CE, PE and EQE, which indicates that Examples 1 to 3 not only markedly suppress lateral crosstalk but also demonstrate excellent overall device performance.

Comparative Examples 4 to 6 each employ Compound PD-1 doped to Compound HT-11 to form the HIL, and the mass doping ratios of Compound PD-1 are 6%, 8%, and 10%, respectively; Comparative Examples 7 to 9 each employ Compound 1-20 doped to Compound HT-23 to form the HIL, and the mass doping ratios of Compound 1-20 are 6%, 8%, and 10%, respectively. As can be seen from the data in Table 1, although the common first organic layers in these two sets of comparative examples exhibit low lateral conductivities per unit doping, the energy level difference between Compound PD-1 and Compound HT-11 in Comparative Examples 4 to 6 is 0.50 eV, and the energy level difference between Compound 1-20 and Compound HT-23 in Comparative Examples 7 to 9 is 0.26 eV. These relatively large energy level differences make it difficult to balance the carrier concentration within the organic layers. Compared with Comparative Examples 4 to 6 and Comparative Examples 7 to 9, Examples 1 to 3 exhibit smaller energy level differences and better-matched energy levels, which achieves appropriate hole injection and greater carrier balance in the device, thereby facilitating the improvement in device performance. As can be seen from the data in Table 4, compared with Comparative Examples 4 to 6, Examples 1 to 3 exhibit a voltage reduction of over 3.8 V and a PE improvement exceeding 58.8%, and the CE and the EQE remain at relatively high levels despite a slight decrease; compared with Comparative Examples 7 to 9, Examples 1 to 3 achieve a voltage reduction of more than 1.2 V and a PE improvement of over 17.4%, and both the CE and the EQE are maintained at high levels or show a slight increase. These results indicate that, in Examples 1 to 3, due to the suitable energy level differences, the device performance is further improved, and the device voltage is significantly reduced, thereby achieving excellent overall device performance.

Comparison of Examples 4 to 6 with Comparative Examples 1 to 3, Comparative Examples 4 to 6, and Comparative Examples 7 to 9:

Examples 4 to 6 each employ Compound 1-20 doped to Compound HT-11 to form the HIL at mass doping ratios of 6%, 8%, and 10%, respectively. As indicated by the data in Table 1, the energy level differences and the lateral conductivities per unit doping of Examples 4 to 6 all satisfy the requirements specified in the present application.

Compared with Comparative Examples 1 to 3, Examples 4 to 6 significantly suppress lateral crosstalk due to low lateral conductivities per unit doping. As can be seen from the data in Table 4, Examples 4 to 6 demonstrate voltages largely comparable to low voltages of Comparative Examples 1 to 3 and achieve more than a 9% improvement in the CE and over a 7% increase in the EQE, and although the PE shows a slight decrease, the PE remains at a relatively high level, indicating excellent overall device performance.

Compared with Comparative Examples 4 to 6 and Comparative Examples 7 to 9, Examples 4 to 6 exhibit smaller energy level differences and better-matched energy levels. As can be seen from the data in Table 4, compared with Comparative Examples 4 to 6, Examples 4 to 6 exhibit a voltage reduction of over 3.6 V and a PE improvement exceeding 47%, and the CE and the EQE remain at relatively high levels despite a slight decrease; compared with Comparative Examples 7 to 9, Examples 4 to 6 achieve a voltage reduction of more than 1.2 V, and the CE, the PE and the EQE are all improved or maintained at high levels. These results indicate that, in Examples 4 to 6, due to the suitable energy level differences, the device performance is further improved, and the device voltage is significantly reduced, thereby achieving excellent overall device performance.

Comparison of Examples 7 to 9 with Comparative Examples 1 to 3, Comparative Examples 4 to 6, and Comparative Examples 7 to 9:

Examples 7 to 9 each employ Compound 1-28 doped to Compound HT-14 to form the HIL at mass doping ratios of 6%, 8%, and 10%, respectively, and their energy level differences and lateral conductivities per unit doping all satisfy the requirements specified in the present application.

Compared with Comparative Examples 1 to 3, Examples 7 to 9 exhibit low lateral conductivities per unit doping and thus significantly suppress lateral crosstalk. As can be seen from the data in Table 4, the voltages of Examples 7 to 9 remain at low levels, comparable to the low voltages of Comparative Examples 1 to 3 and achieve more than a 12% improvement in the CE, over a 9% increase in the EQE and a slight increase in the PE, indicating excellent overall device performance.

Compared with Comparative Examples 4 to 6 and Comparative Examples 7 to 9, Examples 7 to 9 exhibit smaller energy level differences and better-matched energy levels. As can be seen from the data in Table 4, compared with Comparative Examples 4 to 6, Examples 7 to 9 exhibit a voltage reduction of over 3.8 V and a PE improvement exceeding 64.7%, and the CE and the EQE remain at relatively high levels; compared with Comparative Examples 7 to 9, Examples 7 to 9 achieve a voltage reduction of more than 1.2 V and a PE improvement of over 21.7%, and the CE and the EQE are further improved or maintained at high levels. These results indicate that, in Examples 7 to 9, due to the suitable energy level differences, the device performance is further improved, and the device voltage is significantly reduced, thereby achieving excellent overall device performance.

Comparison of Examples 10 to 12 with Comparative Examples 1 to 3, Comparative Examples 4 to 6, and Comparative Examples 7 to 9:

Examples 10 to 12 each employ Compound 2-23 doped to Compound HT-11 to form the HIL at mass doping ratios of 5%, 7%, and 9%, respectively, and their energy level differences and lateral conductivities per unit doping all the requirements specified in the present application.

Compared with Comparative Examples 1 to 3, Examples 10 to 12 exhibit low lateral conductivities per unit doping and thus significantly suppress lateral crosstalk. As can be seen from the data in Table 4, the voltages of Examples 10 to 12 remain at low levels, comparable to the low voltages of Comparative Examples 1 to 3, and the CE, PE and the EQE are further improved or maintained at high levels, indicating excellent overall device performance.

Compared with Comparative Examples 4 to 6 and Comparative Examples 7 to 9, Examples 10 to 12 exhibit smaller energy level differences and better-matched energy levels. As can be seen from the data in Table 4, compared with Comparative Examples 4 to 6, Examples 10 to 12 exhibit a voltage reduction of over 3.8 V and a PE improvement exceeding 58.8%, and the CE and the EQE still remain at relatively high levels even though with a slight reduction; compared with Comparative Examples 7 to 9, Examples 10 to 12 achieve a voltage reduction of more than 1.2 V and a PE improvement of over 17.3%, and the CE and the EQE are maintained at high levels. These results indicate that, in Examples 10 to 12, due to the suitable energy level differences, the device performance is further improved, and the device voltage is significantly reduced, thereby achieving excellent overall device performance.

In summary, the specific energy level difference between the two materials, the specifically high doping ratio and the specifically low lateral conductivity per unit doping in the common first organic layer all play crucial roles in device performance. In the common first organic layer of the active-matrix OLED display in the present application, the energy levels of the first organic layer and the second organic material are well matched, the carriers in the organic layers are well balanced, and the first organic material has a specifically high mass doping ratio. Therefore, the injection of sufficient holes can be guaranteed, thereby improving device performance in terms of operating voltage and efficiency and exhibiting excellent overall characteristics. Furthermore, the low lateral conductivity per unit doping can be achieved to enable the lateral migration of holes within the common HIL to be at a low level, thereby significantly suppressing lateral crosstalk between pixels in the display and providing distinct advantages for commercial applications.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. An active-matrix organic electroluminescent display, comprising a plurality of pixels;
wherein each pixel among the plurality of pixels comprises at least one organic electroluminescent device;
the organic electroluminescent device comprises an anode, a cathode, and an organic layer disposed between the anode and the cathode;
the organic layer comprises at least a common first organic layer, and the common first organic layer is shared by at least two pixels;
the common first organic layer comprises at least a first organic material and a second organic material;
a lowest unoccupied molecular orbital (LUMO) energy level of the first organic material is denoted as LUMO_{first_organic_material}, a highest occupied molecular orbital (HOMO) energy level of the second organic material is denoted as HOMO_{second_organic_material}, and −0.1 eV<LUMO_{first_organic_material}−HOMO_{second_organic_material}<0.25 eV;
a mass doping ratio of the first organic material in the common first organic layer is A %, and 5≤A≤15;
a lateral conductivity of the common first organic layer is B_{A}, a lateral conductivity per unit doping of the common first organic layer is σ_{A}, wherein σ_{A}=B_{A}/A, and at least one σ_{A} satisfies 0.05×10⁻⁴ S/m≤σ_{A}≤1×10⁻⁴ S/m.

2. The active-matrix organic electroluminescent display of claim 1, wherein the organic electroluminescent device is a single-layer device having a device voltage less than or equal to 4.5 V at a constant current density of 10 mA/cm²;
preferably, the device voltage is less than or equal to 4.4 V at the constant current density of 10 mA/cm²;
more preferably, the device voltage is less than or equal to 4.3 V at the constant current density of 10 mA/cm².

3. The active-matrix organic electroluminescent display of claim 1, wherein the common first organic layer is a hole injection layer or a hole transport layer;
preferably, the first organic material is a p-type conductive doping material, and the second organic material is a hole transport material.

4. The active-matrix organic electroluminescent display of claim 1, wherein −0.05 eV<LUMO_{first_organic_material}−HOMO_{second_organic_material}<0.25 eV;
preferably, 0 eV≤LUMO_{first_organic_material}−HOMO_{second_organic_material}≤0.23 eV;
more preferably, 0 eV≤LUMO_{first_organic_material}−HOMO_{second_organic_material}≤0.19 eV.

5. The active-matrix organic electroluminescent display of claim 1, wherein the mass doping ratio of the first organic material in the common first organic layer is A %, and 6≤A≤15;
preferably, 6≤A≤12;
more preferably, 6≤A≤10.

6. The active-matrix organic electroluminescent display of claim 1, wherein the lateral conductivity per unit doping of the common first organic layer is σ_{A}, wherein σ_{A}=B_{A}/A, and at least one σ_{A} satisfies 0.06×10⁻⁴ S/m≤σ_{A}<1×10⁻⁴ S/m;
preferably, at least one σ_{A} satisfies 0.08×10⁻⁴ S/m≤σ_{A}<1×10⁻⁴ S/m;
more preferably, at least one σ_{A} satisfies 0.15×10⁻⁴ S/m≤σ_{A}<1×10⁻⁴ S/m.

7. The active-matrix organic electroluminescent display of claim 1, wherein the lateral conductivity per unit doping of the common first organic layer is σ_{A}, wherein σ_{A}=B_{A}/A, and at least two σ_{A} satisfy 0.05×10⁻⁴ S/m≤σ_{A}≤1×10⁻⁴ S/m;
preferably, all of σ_{A} satisfy 0.05×10⁻⁴ S/m≤σ_{A}≤1×10⁻⁴ S/m;
more preferably, all of σ_{A} satisfy 0.1×10⁻⁴ S/m≤σ_{A}≤0.8×10⁻⁴ S/m.

8. The active-matrix organic electroluminescent display of claim 1, wherein the lateral conductivity per unit doping of the common first organic layer is σ_{A}, wherein σ_{A}=B_{A}/A, and at least σ₆, σ₈ and σ₁₀ all satisfy 0.05×10⁻⁴ S/m≤σ_{A}≤1×10⁻⁴ S/m;
preferably, at least σ₆, σ₈ and σ₁₀ all satisfy 0.08×10⁻⁴ S/m≤σ_{A}≤1×10⁻⁴ S/m;
more preferably, at least σ₆, σ₈ and σ₁₀ all satisfy 0.1×10⁻⁴ S/m≤σ_{A}≤1×10⁻⁴ S/m;
most preferably, at least σ₆, σ₈ and σ₁₀ all satisfy 0.15×10⁻⁴ S/m<σ_{A}<1×10⁻⁴ S/m.

9. The active-matrix organic electroluminescent display of claim 1, wherein −5.30 eV≤LUMO_{first_organic_material}≤−4.80 eV;
preferably, −5.20 eV≤LUMO_{first_organic_material}≤−4.90 e V.

10. The active-matrix organic electroluminescent display of claim 1, wherein −5.35 eV≤HOMO_{second_organic_material}≤−5.00 eV;
preferably, −5.30 eV≤HOMO_{second_organic_material}≤−5.00 eV;
more preferably, −5.25 eV≤HOMO_{second_organic_material}≤−5.00 eV.

11. The active-matrix organic electroluminescent display of claim 1, wherein the lateral conductivity B_{A} of the common first organic layer is tested in the following method: depositing the first organic material and the second organic material on a test substrate prepared with an aluminum electrode in advance at a certain mass ratio through co-deposition at a vacuum degree of about 10⁻⁶ Torr, forming a to-be-tested region with a thickness of 100 nm, a length of 6 mm and a width of 1 mm, obtaining an electric resistance value of the region through a method of applying a voltage to the electrode and measuring a current at room temperature, and calculating the lateral conductivity B_{A} of the layer of Ohm's law and a geometric dimension.

12. The active-matrix organic electroluminescent display of claim 1, wherein the first organic material is selected from the following compounds: quinone or quinone derivatives, radialene compounds, dehydrobenzoxazole and dehydrobenzothiazole compounds, and bisoxazole or bisthiazole compounds.

13. The active-matrix organic electroluminescent display of claim 1, wherein the second organic material comprises any one or more chemical structural units selected from the group consisting of: triarylamine, carbazole, fluorene, spirobifluorene, thiophene, furan, phenyl, oligophenylenevinylene, oligofluorene, and combinations thereof;
preferably, the second organic material is a monotriarylamine compound or a bistriarylamine compound.

14. The active-matrix organic electroluminescent display of claim 1, wherein the organic layer comprises a common second organic layer, the common second organic layer is shared by at least two pixels, and the common second organic layer is disposed between the common first organic layer and the cathode;
preferably, the common second organic layer is in direct contact with the common first organic layer;
more preferably, the common second organic layer is a hole transport layer.

15. The active-matrix organic electroluminescent display of claim 14, wherein the common second organic layer comprises a third organic material;
preferably, the third organic material is the same as or different from the second organic material;
more preferably, the third organic material is the same as the second organic material.

16. The active-matrix organic electroluminescent display of claim 14, wherein a thickness of the common second organic layer is greater than or equal to 20 nm;
preferably, the thickness of the common second organic layer is greater than or equal to 60 nm;
more preferably, the thickness of the common second organic layer is greater than or equal to 100 nm.

17. An electronic device, comprising the active-matrix organic electroluminescent display of claim 1.
